(19) United States
(12) Patent Application Publication
(10) Pub. No.: US 2017/0125715 A1
(43) Pub. Date: May 4, 2017

(54) ORGANIC ELECTROLUMINESCENT ELEMENT

(71) Applicant: Konica MinoIta, Inc., Tokyo (JP)

(72) Inventors: Ken OKAMOTO, Hachioji-shi, Tokyo (JP); Rieko TAKAHASHI, Hino-shi, Tokyo (JP); Kenji ARAI, Kunitachi-shi, Tokyo (JP)

(21) Appl. No.: 15/317,053

(22) PCT Filed: Sep. 24, 2015
(86) PCT No.: PCT/JP2015/076859

§ 371 Date: Dec. 7, 2016

(30) Foreign Application Priority Data
Sep. 26, 2014 (JP) 2014-196553

(51) Int. Cl. H01L 51/50

(52) U.S. Cl. CPC H01L 51/504; H01L 51/5016; H01L 2251/558; H01L 51/5088; H01L 2251/556; H01L 51/0059

(57) ABSTRACT

Provided is an organic EL element having less color variation. The organic EL element (1) of the invention includes, between a pair of an anode (4) and a cathode (14), a first light emitting layer (8) composed of at least one layer and a second light emitting layer (10) composed of at least one layer, the layers being laminated from the anode (4) side, in which the volume concentration of the luminescent dopant included in the second light emitting layer (10) is higher than the volume concentration of the luminescent dopant included in the first light emitting layer (8).

### TECHNICAL FIELD

The present invention relates to an organic electroluminescent element. More particularly, the invention relates to an organic electroluminescent element having little color variation.

### BACKGROUND ART

An organic electroluminescent element (organic EL element) that utilizes electroluminescence (EL) of an organic material is a thin film type all-solid element capable of emitting light at a low voltage of about several V to several tens V, and has a number of excellent features such as high brightness, high luminous efficiency, thin size, and light weight. Therefore, organic electroluminescent elements have been paid attention in recent years, as backlights for various displays, display boards such as signboards and emergency lights, and surface light emitting bodies such as illumination light sources.

In order to realize a white light emitting element having high efficiency and a long service life, it is necessary to laminate multiple light emitting layers (see, for example, Non Patent Literatures 1 and 2); however, the position of light emission varies with brightness and voltage, and thus, color variation is likely to occur.

Furthermore, in a conventional configuration having a pair of electrodes, due to the transport properties of the carrier transporting material (for example, the electron mobility is about 1×10⁻⁵ cm²/Vs, and the hole mobility is about 1×10⁻⁷ cm²/Vs), light emission occurs at the interface close to the hole transport layer within the light emitting layer (see, for example, Non Patent Literature 3).

Therefore, when multiple light emitting layers are used, a light emitting layer located on the hole transport layer side is likely to emit light. Conventionally, the position of light emission has been controlled mainly by means of the layer thickness (carrier transport layer, first light emitting layer, intermediate layer, second light emitting layer, or the like). However, there have been occasions in which, along with the change in brightness caused by voltage and the changes over time, the position of light emission varies, and color shift occurs. Furthermore, a method of controlling the position of light emission by providing a boundary line by means of an intermediate layer formed between light emitting layers, has also been used.

Particularly, in a case in which a fluorescent light emitting layer and a phosphorescent light emitting layer are present together, boundaries are used in many cases by providing an intermediate layer between the light emitting layers, or the like. Thus, organic luminescence elements have been designed so as to control the position of recombination, so that energy loss does not occur between fluorescence and phosphorescence at the boundaries. As one of such methods, organic electroluminescent elements have been designed such that the mobility of a carrier transport layer is not so high.

Generally, the mobility of a hole injection/transport layer that is located between an anode and a first light emitting layer is lower than the mobility of an electron injection/transport layer that is located between a second light emitting layer and a cathode, and as the temperature is lower, the difference between the mobility values becomes more noticeable. As a result, color may be easily shifted to the color of the light emitted on the first light emitting layer side.

Furthermore, there are generally three cases of material systems that are introduced into a hole injection layer, and they include: (i) a simple organic compound, (ii) a simple metal oxide, and (iii) an organic compound and a p-type doping material such as a metal, a metal oxide, or biferrocene-F-TCNQ. From the viewpoint of stability (mass production) of the material itself, a simple organic compound is most desirable as the material for a hole injection layer. However, in the case of a simple organic compound, there is a disadvantage that particularly in the hole injection layer part, the hole transportability is lowered compared to the hole transport layer material. Furthermore, as the temperature is lowered, hole transportability becomes more significantly effective as a rate-determining process than electron transportability, even in view of the rule of hopping conduction (μ=eR²v/k_{B}T×exp(−2αR)). Thus, the luminescent color is shifted to the color of the first light emitting layer side.

As described above, in regard to an element having, between a pair of an anode and a cathode, a layer in which multiple light emitting layers (particularly, in a case in which a fluorescent light emitting layer and a phosphorescent light emitting layer are co-present) are laminated, the region of recombination between holes and electrons vary due to the differences in brightness and voltage, changes over time, and changes in the environmental temperature. As a result, the voltage varies, or the color varies to a large extent.

Particularly, in order to achieve light emission at low voltage, it is required that the electron mobility and the hole mobility at the carrier transport layers be high. Therefore, control of the light emitting region becomes more difficult, and color variation increases.

### CITATION LIST

### Non Patent Literature

Non Patent Literature 1: Chem. Mater., 2013, 25, 4454-4459
Non Patent Literature 2: Adv. Mater., 2007, 19, 3672-3676

### Non Patent Literature 3: Organic EL Display, Ohmsha, Ltd., p. 51

### SUMMARY OF INVENTION

### Technical Problem

The present invention has been achieved in view of the problems and circumstances described above, and an object of the invention is to provide an organic electroluminescent element having little color variation.

### Solution to Problem

The present inventors conducted an investigation on the causes of the problems described above in order to solve the problems, and in the course of the investigation, the inventors found that when the volume concentration of the luminescent dopant included in a second light emitting layer is made higher than the volume concentration of the luminescent dopant included in a first light emitting layer, an organic electroluminescent element having little color variation can be provided. Thus, the inventors completed the present invention.

That is, the problems according to the present invention are solved by the following means.

1. An organic electroluminescent element including, between a pair of an anode and a cathode, a first light emitting layer composed of at least one layer and a second light emitting layer composed of at least one layer, the light emitting layers being laminated in this order from the anode side, wherein the volume concentration of the luminescent dopant included in the second light emitting layer is higher than the volume concentration of the luminescent dopant included in the first light emitting layer.

2. The organic electroluminescent element according to Item. 1, wherein the volume concentration of the luminescent dopant included in the second light emitting layer is 10.0 vol % or higher.

3. The organic electroluminescent element according to Item. 1 or 2, wherein the volume concentration of the luminescent dopant included in the first light emitting layer is 3.0 vol % or less.

4. The organic electroluminescent element according to anyone of Items. 1 to 3, wherein the light emitted by the second light emitting layer is phosphorescent light.

5. The organic electroluminescent element according to any one of Items. 1 to 4, wherein an intermediate layer is formed between the first light emitting layer and the second light emitting layer.

6. The organic electroluminescent element according to Item. 5, wherein the layer thickness of the intermediate layer is in the range of 1 to 7 nm.

7. The organic electroluminescent element according to Item. 5 or 6, wherein the intermediate layer is formed from a single kind of compound.

8. The organic electroluminescent element according to Item. 7, wherein a host compound is included in at least one of the first light emitting layer and the second light emitting layer, and the host compound and the single kind of compound in the intermediate layer are the same.

9. The organic electroluminescent element according to any one of Items. 1 to 8, wherein the organic electroluminescent element includes, between the anode and the first light emitting layer, a hole injection/transport layer including at least a hole injection layer in the interior, and the layer thickness of the hole injection/transport layer (d_{HITL}) and the layer thickness of the hole injection layer (d_{HIL}) satisfy the following conditional expression:

d_{HIL}/d_{HITL}≦0.20

10. The organic electroluminescent element according to Item. 9, wherein the layer thickness of the hole injection/transport layer (d_{HITL}) and the layer thickness of the hole injection layer (d_{HIL}) satisfy the following conditional expression:

d_{HIL}/d_{HITL}≦0.10

11. The organic electroluminescent element according to Item. 9 or 10, wherein the layer thickness of the hole injection layer is in the range of 1 to 15 nm.

12. The organic electroluminescent element according to Item. 11, wherein the layer thickness of the hole injection layer is in the range of 1 to 10 nm.

13. The organic electroluminescent element according to any one of Items. 9 to 12, wherein the hole injection layer is formed from a single kind of compound.

14. The organic electroluminescent element according to any one of Items. 9 to 13, wherein the hole injection layer contains a compound having a structure represented by the following General Formula (1):

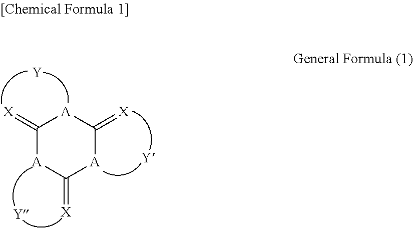

in General Formula (1), A represents a carbon atom (C) or a nitrogen atom (N); X represents a nitrogen atom (N) or a carbon atom (CR⁰); R⁰ represents any one group selected from a hydrogen atom, a halogen atom, a cyano group, a nitro group, a formyl group, an acetyl group, a benzoyl group, an amide group (—CONHR¹ or —CONR¹R²), a styryl group, an ethynyl group, a quinolyl group, a quinazolyl group, a phenanthrolyl group, a biquinolyl group, an anthraquinonyl group, a benzoquinonyl group, a quinonyl group, an acridinyl group, and a group, being substituted or unsubstituted, selected from an alkyl group, an aryl group, an aralkyl group, an alkylamino group, an arylamino group, an aralkylamino group and a heterocyclic group; R¹ and R² each independently represent an alkyl group having 1 to 60 carbon atoms, an aryl group, or a 5-membered to 7-membered heterocyclic group, all of these groups being substituted or unsubstituted; Y, Y′ and Y″ each represent a 5-membered aromatic heterocyclic ring containing A and X as ring members, or a 6-membered aromatic heterocyclic ring containing A and X as ring members, all of these heterocyclic rings being substituted or unsubstituted; and Y, Y′ and Y″ may be identical or different from each other.

15. The organic electroluminescent element according to Item. 14, wherein the compound having a structure represented by General Formula (1) is a compound having a structure represented by the following General Formula (2):

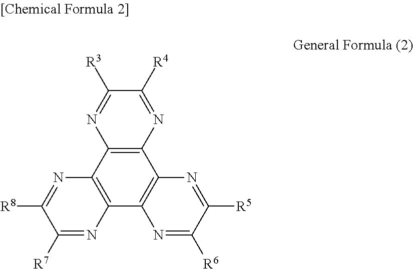

in General Formula (2), R³ to R⁸ each independently represent a hydrogen atom, a halogen atom, a cyano group, a nitro group, a sulfonyl group (—SO₂R⁹), a sulfinyl group (—SOR⁹), a sulfonamide group (—SO₂NR⁹R¹⁰), a sulfonato group (—SO₃R⁹), a trifluoromethyl group, an ester group (—COOR⁹), an amide group (—CONHR⁹ or —CONR⁹R¹⁰), and a group, being substituted or unsubstituted, selected from a linear or branched alkyl group having 1 to 12 carbon atoms, a linear or branched alkoxy group having 1 to 12 carbon atoms, an aromatic hydrocarbon ring group, an arylamino group, a non-aromatic heterocyclic group, an aromatic heterocyclic group, and an aralkylamino group; and R⁹ and R¹⁰ each independently represent an alkyl group having 1 to 60 carbon atoms, an aryl group, or a 5-membered to 7-membered heterocyclic group, all of these groups being substituted or unsubstituted.

16. The organic electroluminescent element according to Item. 14, wherein the compound having a structure represented by General Formula (1) is a compound having a structure represented by the following General Formula (3):

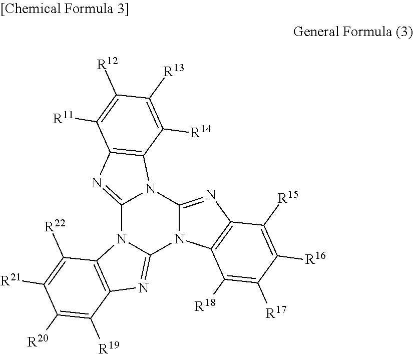

in General Formula (3), R¹¹ to R²² each independently represent any one group selected from a halogen atom, an amino group, a cyano group, a nitro group, an alkoxy group, an aryloxy group, an alkylthio group, an arylthio group, an acyl group, an alkoxycarbonyl group, an aryloxycarbonyl group, an alkylsulfonyl group, an arylsulfonyl group, and a group, being substituted or unsubstituted, selected from an aliphatic hydrocarbon group, an aromatic hydrocarbon ring group, an aliphatic heterocyclic group and an aromatic heterocyclic group; and R¹¹ to R²² may respectively form a ring together with adjacent substituents.

17. The organic electroluminescent element according to anyone of Items. 9 to 13, wherein the hole injection layer contains a compound having a structure represented by the following General Formula (4):

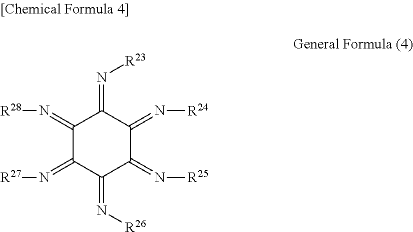

in General Formula (4), R²³ to R²⁸ each independently represent an alkyl group, an aryl group, an aralkyl group, or a heterocyclic group, all of these groups being substituted or unsubstituted; R²³ to R²⁸ may be identical or different; and R²³ with R²⁴, R²⁵ with R²⁶, and R²⁷ with R²⁸, or R²³ with R²⁸, R²⁴ with R²⁵, and R²⁶ with R²⁷ may form a fused ring.

18. The organic electroluminescent element according to any one of Items. 1 to 17, wherein the driving voltage is 4.0 V or less under the conditions of a temperature of 25° C. and an emission luminance of 1,000 cd/m².

### Advantageous Effects of Invention

An organic electroluminescent element having little color variation can be provided by the above-described means of the present invention.

The manifestation mechanism and operating mechanism for the effects of the present invention are not clearly understood; however, the mechanisms are speculated to be as follows.

Since electron mobility is conventionally higher than hole mobility, the position of recombination between holes and electrons is shifted toward the hole injection/transport layer side, and therefore, a light emitting layer that is closer to the anode can emit light more easily, and this has become a cause of color shift.

According to the present invention, it is speculated that when the volume concentration of the luminescent dopant included in a second light emitting layer (hereinafter, also simply referred to as dope concentration) is made higher than the volume concentration of the luminescent dopant included in a first light emitting layer, and thereby holes and electrons are recombined stably between the first light emitting layer and the second light emitting layer, color variation can be reduced.

### BRIEF DESCRIPTION OF DRAWINGS

FIG. 1 is a schematic cross-sectional diagram illustrating an example of an organic EL element according to the present invention.

FIG. 2 is a schematic cross-sectional diagram illustrating an example of the organic EL element according to the present invention.

FIG. 3 is a graph showing the relations between d_{HIL}/d_{HITL} and the voltage variation as well as color variation.

### DESCRIPTION OF EMBODIMENTS

The organic EL element of the present invention has a feature that the volume concentration of the luminescent dopant included in a second light emitting layer is higher than the volume concentration of the luminescent dopant included in a first light emitting layer. This feature is a technical feature common to the inventions according to claims 1 to 18.

According to an embodiment of the present invention, it is preferable that the volume concentration of the luminescent dopant included in the second light emitting layer is 10.0 vol % or more, and the volume concentration of the luminescent dopant included in the first light emitting layer is 3.0 vol % or less, from the viewpoint that the probability of carrier recombination in the first light emitting layer can be reduced, and the light emitting state in a state in which the probability of carrier recombination in the second light emitting layer has been increased can be stabilized.

Furthermore, from the viewpoints of the luminous efficiency and the balance of service life between the first light emitting layer and the second light emitting layer, it is preferable that the light emitting from the second light emitting layer is phosphorescent light.

Furthermore, it is preferable that an intermediate layer is formed between the first light emitting layer and the second light emitting layer, and the layer thickness of the intermediate layer is in the range of 1 to 7 nm, because the energy movement loss between T₁ and S₁ among various light emitting layers can be reduced. Meanwhile, when the element is designed so as to exploit the energy movement between T₁ and S₁, the intermediate layer may be omitted.

From the viewpoint of production efficiency, it is preferable that the intermediate layer is formed from a single kind of compound.

Furthermore, from the viewpoint of production efficiency and the viewpoint of removing any barrier against hole transport from the first light emitting layer to the intermediate layer, it is preferable that the host compound included in at least one of the first light emitting layer or the second light emitting layer, and the single kind of compound in the intermediate layer are the same.

It is also preferable that the layer thickness ratio (d_{HIL}/d_{HITL}) between the layer thickness of the hole injection/transport layer (d_{HITL}) and the layer thickness of the hole injection layer (d_{HIL}) is adjusted to 0.20 or less, and preferably 0.10 or less, and that the layer thickness of the hole injection layer is adjusted to be in the range of 1 to 15 nm, and preferably in the range of 1 to 10 nm, from the viewpoint that the conspicuous decrease in hole transportability in the hole injection layer is minimized even under low voltage driving and in a low temperature environment, and thus carrier recombination is stably induced between light emitting layers.

From the viewpoint of production efficiency, it is preferable that the hole injection layer is formed from a single kind of compound.

Furthermore, from the viewpoint of material stability and hole injectability, it is preferable that compounds having structures represented by General Formulae (1) to (4) are included in the hole injection layer.

Hereinafter, the present invention, constituent elements of the invention, and embodiments/aspects for carrying out the present invention will be described in detail. According to the present application, to that expresses a numerical value range is used to mean that the numerical values described before and after to are included in the range as the lower limit and the upper limit.

<<Configuration of Organic EL Element>>

The organic EL element of the present invention has a feature that a first light emitting layer composed of at least one layer and a second light emitting layer composed of at least one layer are laminated between a pair of an anode and a cathode, the first light emitting layer being laminated closer to the anode side, and the volume concentration of the luminescent dopant included in the second light emitting layer is higher than the volume concentration of the luminescent dopant included in the first light emitting layer.

The present invention will be described in detail below, using the drawings.

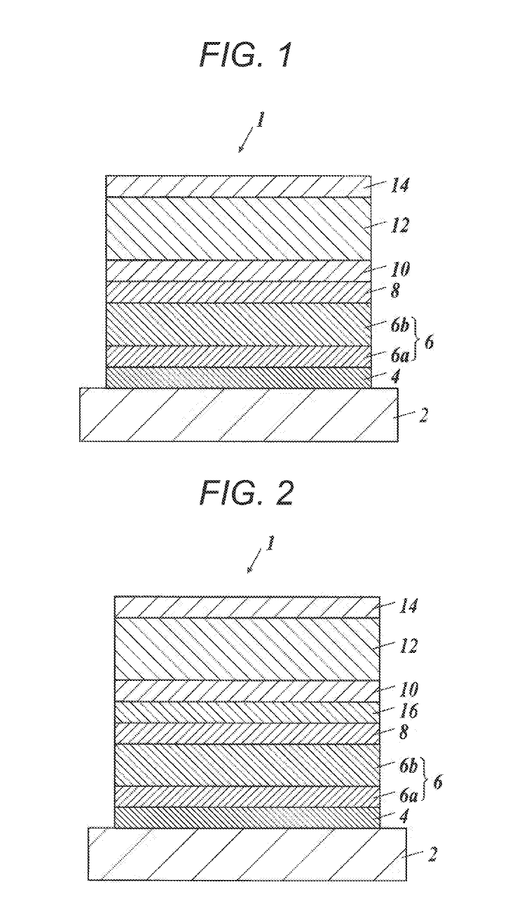

FIG. 1 is a schematic cross-sectional diagram illustrating an example of the organic EL element of the present invention.

As illustrated in FIG. 1, an organic EL element 1 includes, on a substrate 2, an anode 4, a hole injection/transport layer 6, a first light emitting layer 8, a second light emitting layer 10, an electron injection/transport layer 12, and a cathode 14, in this order.

The organic EL element 1 has a so-called bottom emission type configuration, in which the anode 4 is constructed from a transparent electrode, the cathode 14 is configured to function as a reflective electrode, and light is extracted through the substrate 2 side.

It is preferable that the hole injection/transport layer 6 has a hole injection layer 6a, and examples of another layer 6b include a hole transport layer and an electron blocking layer.

The electron injection/transport layer 12 is composed of, for example, an electron injection layer, an electron transport layer, or a hole blocking layer.

Furthermore, the organic EL element 1 is a white luminescent element in which at least organic luminescent materials, for example, luminescent dopants of various colors such as blue (B), green (G) and red (R), are included in the first light emitting layer 8 and the second light emitting layer 10.

In order to increase the luminous efficiency of the organic EL element, it is preferable to provide a light emitting layer that emits light having a short wavelength, on the side of light extraction. Therefore, in regard to the organic EL element 1, it is preferable that a luminescent dopant that emits blue light having a short wavelength is incorporated into the first light emitting layer 8, and luminescent dopants that emit green (G) and red (R) light are incorporated into the second light emitting layer 10.

That is, in the organic EL element, the first light emitting layer 8 is a blue light emitting layer containing a blue luminescent dopant, and the second light emitting layer 10 is a green and red (yellow) light emitting layer containing a green luminescent dopant and a red luminescent dopant.

The first light emitting layer 8 and the second light emitting layer 10 are each composed of at least one layer; however, the light emitting layers may have, for example, a two-layer configuration, or the first light emitting layer 8 may be constructed as a blue light emitting layer, while the second light emitting layer 10 may be configured to include a green light emitting layer and a red light emitting layer. In this case, it is necessary that all the layers that constitute the second light emitting layer 10 have larger volume concentrations of the luminescent dopants than the volume concentration of the luminescent dopants of all the layers that constitute the first light emitting layer 8.

The first light emitting layer 8 and the second light emitting layer 10 may emit any of fluorescent light or phosphorescent light.

Furthermore, the organic EL element 1 may have, as illustrated in FIG. 2, an intermediate layer 16 between the first light emitting layer 8 and the second light emitting layer 10.

It is preferable that the organic EL element 1 of the present invention has a driving voltage of 4.0 V or less under the conditions of a temperature of 25° C. and an emission luminance of 1,000 cd/m².

In the following, the respective configurations of the anode, hole injection/transport layer, first light emitting layer, intermediate layer, second light emitting layer, electron injection/transport layer, and cathode that constitute the organic EL element of the present invention, and the details of the configuration of the substrate on which the organic EL element of the present invention is provided, will be described. Meanwhile, the various configurations of the organic EL element described below are only examples intended for illustrating the embodiments, and other configurations can also be adopted as appropriate to the extent that the organic EL element described above can be constructed.

<Light Emitting Layers>

The first light emitting layer and the second light emitting layer according to the present invention are respectively composed of at least one layer, and it is characterized in that the volume concentration of the luminescent dopant included in the second light emitting layer is higher than the volume concentration of the luminescent dopant included in the first light emitting layer.

The volume concentration of the luminescent dopant included in the second light emitting layer is preferably 10.0 vol % or more, and the volume concentration of the luminescent dopant included in the first light emitting layer is preferably 3.0 vol % or less.

The first light emitting layer and the second light emitting layer are layers including luminescent organic semiconductor thin films that provide a place where electrons and holes injected from electrodes or adjacent layers recombine, and light is emitted via excitons. The part that emits light may be the interior of the light emitting layer, or may be an interface between the light emitting layer and an adjacent layer.

The first light emitting layer and the second light emitting layer may include other layers between the light emitting layer and the anode, the intermediate layer, or the cathode.

It is preferable that the first light emitting layer and the second light emitting layer each contain at least one or more luminescent materials including organic materials that exhibit luminosity.

In each of the light emitting layers, a phosphorescent light emitting material and a fluorescent light emitting material may be co-present; however, it is preferable that each light emitting layer is constructed from a phosphorescent light emitting material only or a fluorescent light emitting material only.

The fluorescent light emitting layer and the phosphorescent light emitting layer are preferably host-dopant type light emitting layers.

The light emitted by the second light emitting layer is preferably phosphorescent light.

Furthermore, in a case in which it is intended to obtain white luminescence by laminating light emitting layers exhibiting different luminescent colors, it is preferable that these light emitting layers are in the relationship of being complementary colors for each other. For example, when a blue light emitting layer and a light emitting layer that exhibits a luminescent color such as yellow-green, yellow, or orange, all of which are complementary to blue, are provided, an organic EL element exhibiting white luminescence can be obtained. The relationship of being “complementary colors” refers to a relationship of colors in which when the relevant colors are mixed, an achromatic color is obtained. That is, when lights emitted by substances that emit light of colors that are in the relationship of being complementary colors are mixed, white luminescence can be obtained.

The layers that constitute each light emitting layer may be any layers, and there may be multiple layers having the same luminescence spectrum or the same maximum emission wavelength.

The sum of the layer thicknesses of the various light emitting layers is not particularly limited. However, from the viewpoint of homogeneity of the films thus formed, or from the viewpoint of preventing application of an unnecessarily high voltage at the time of light emission and increasing the stability of the luminescent color with respect to the driving current, it is preferable to adjust the sum of the layer thicknesses in the range of 5 to 200 nm, and more preferably in the range of 10 to 150 nm. Furthermore, regarding the layer thickness of individual light emitting layers, it is preferable to adjust the layer thickness in the range of 5 to 200 nm, and more preferably in the range of 10 to 40 nm.

(1) Luminescent Dopant

As the luminescent dopant, a fluorescent light emitting dopant (also referred to as fluorescent dopant or fluorescent compound) and a phosphorescent light emitting dopant (also referred to as phosphorescent dopant or phosphorescent compound) are preferably used. The concentration of the luminescent dopant in the light emitting layer can be arbitrarily determined based on the necessary conditions for the particular dopant used and the device; however, according to the present invention, at least the volume concentration of the luminescent dopant included in the second light emitting layer is higher than the volume concentration of the luminescent dopant included in the first light emitting layer. Regarding the concentration of the luminescent dopant, the luminescent dopant may be included at a uniform concentration along the layer thickness direction of the light emitting layer, or the luminescent dopant may have an arbitrary concentration distribution.

Furthermore, each light emitting layer may include multiple kinds of luminescent dopants. For example, a combination of the same kind of dopants having different structures, or a combination of a fluorescent light emitting dopant and a phosphorescent light emitting dopant may be used. Thereby, an arbitrary luminescent color can be obtained.

It is preferable for the organic EL element of the present invention that a light emitting layer composed of a single layer or multiple layers contains a plurality of luminescent dopants having different luminescent colors and thereby exhibits white luminescence. The combination of luminescent dopants exhibiting white color is not particularly limited, and examples thereof include a combination of blue and orange, and a combination of blue, green and red. Regarding the white color for an organic EL element, it is preferable that when the 2-degree viewing angle front luminance is measured by the method described above, the chromaticity according to the CIE1931 Color System at 1,000 cd/m² is in the region of x=0.39±0.09 and y=0.38±0.08.

(1.1) Phosphorescent Light Emitting Dopant

A phosphorescent light emitting dopant is a compound in which luminescence from an excited triplet is observed, and specifically, the dopant is a compound which emits phosphorescent light at room temperature (25° C.) and has a phosphorescence quantum yield at 25° C. of 0.01 or higher. In regard to the phosphorescent light emitting dopant used in the light emitting layer, a preferred phosphorescence quantum yield is 0.1 or higher.

The phosphorescence quantum yield can be measured by the method described in Lectures on Experimental Chemistry, 4th Edition, Vol. 7, Spectroscopy II, p. 398 (published in 1992, Maruzen Publishing Co., Ltd.). The phosphorescence quantum yield in a solution can be measured using various solvents. It is desirable that the phosphorescent light emitting dopant used in the light emitting layer achieves the aforementioned phosphorescence quantum yield (0.01 or higher) in any one of arbitrary solvents.

Light emission of a phosphorescent light emitting dopant may be based on two principles.

One of the principles is energy transfer type in which, on a host compound in which carriers are transported, an excited state of the host compound caused by recombination of carriers is produced, and by transferring this energy to a phosphorescent light emitting dopant, luminescence from the phosphorescent light emitting dopant is obtained. Another principle is carrier trapping type in which the phosphorescent light emitting dopant serves as a carrier trap, recombination of carriers occurs on the phosphorescent light emitting dopant, and luminescence from the phosphorescent light emitting dopant is obtained. In both cases, it is a prerequisite that the energy of the excited state of the phosphorescent light emitting dopant is lower than the energy of the excited state of the host compound.

The phosphorescent light emitting dopant can be appropriately selected for use from known materials that are used for a light emitting layer of an organic EL element.

Specific examples of known phosphorescent light emitting dopants include the compounds described in Nature, 395, 151 (1998); Appl. Phys. Lett., 78, 1622 (2001); Adv. Mater., 19, 739 (2007); Chem. Mater., 17, 3532 (2005); Adv. Mater., 17, 1059 (2005); WO 2009/100991 A, WO 2008/101842 A, WO 2003/040257 A, US 2006/835469 A, US 2006/0,202,194 A1, US 2007/0,087,321 A1, US 2005/0,244,673 A1; Inorg. Chem., 40, 1704 (2001); Chem. Mater., 16, 2480 (2004); Adv. Mater., 16, 2003 (2004); Angew. Chem. Int. Ed., 2006, 45, 7800; Appl. Phys. Lett., 86, 153505 (2005); Chem. Lett., 34, 592 (2005); Chem. Commun., 2906 (2005); Inorg. Chem., 42, 1248 (2003); WO 2009/050290 A, WO 2002/015645 A, WO 2009/000673 A, US 2002/0,034,656 A1, U.S. Pat. No. 7,332,232, US 2009/0,108,737 A1, US 2009/0,039,776 A1, U.S. Pat. No. 6,921,915, U.S. Pat. No. 6,687,266, US 2007/0,190,359 A1, US 2006/0,008,670 A1, US 2009/0,165,846 A1, US 2008/0,015,355 A1, U.S. Pat. No. 7,250,226, U.S. Pat. No. 7,396,598, US 2006/0,263,635 A1, US 2003/0,138,657 A1, US 2003/0,152,802 A1, U.S. Pat. No. 7,090,928; Angew. Chem. Int. Ed., 47, 1 (2008); Chem. Mater., 18, 5119 (2006); Inorg. Chem., 46, 4308 (2007); Organometallics 23, 3745 (2004); Appl. Phys. Lett., 74, 1361 (1999); WO 2002/002714 A, WO 2006/009024 A, WO 2006/056418 A, WO 2005/019373 A, WO 2005/123873 A, WO 2005/123873 A, WO 2007/004380 A, WO 2006/082742 A, US 2006/0,251,923 A1, US 2005/0,260,441 A1, U.S. Pat. No. 7,393,599, U.S. Pat. No. 7,534,505, U.S. Pat. No. 7,445,855, US 2007/0,190,359 A1, US 2008/0,297,033 A1, U.S. Pat. No. 7,338,722, US 2002/0,134,984 A1, U.S. Pat. No. 7,279,704, US 2006/098120 A, US 2006/103874 A, WO 2005/076380 A, WO 2010/032663 A, WO 2008/140115 A, WO 2007/052431 A, WO 2011/134013 A, WO 2011/157339 A, WO 2010/086089 A, WO 2009/113646 A, WO 2012/020327 A, WO 2011/051404 A, WO 2011/004639 A, WO 2011/073149 A, US 2012/228583 A, US 2012/212126 A, JP 2012-069737A, JP 2012-195554 A, JP 2009-114086 A, JP 2003-81988 A, JP 2002-302671 A, and JP 2002-363552 A.

Particularly, preferred examples of the phosphorescent light emitting dopant include the compounds having structures represented by General Formula (4), General Formula (5), and General Formula (6) described in paragraphs [0185] to [0235] of JP 2013-4245 A; and exemplary compounds (Pt-1 to Pt-3, Os-1, and Ir-1 to Ir-45).

Among them, preferred examples of the phosphorescent light emitting dopant include organometallic complexes having Ir as the central metal. More preferably, a complex containing at least one coordination modes selected from a metal-carbon bond, a metal-nitrogen bond, a metal-oxygen bond, and a metal-sulfur bond is preferred.

(1.2) Fluorescent Light Emitting Dopant

A fluorescent light emitting dopant is a compound capable of luminescence from an excited singlet, and the compound is not particularly limited as long as luminescence from an excited single is observed.

Examples of the fluorescent light emitting dopant include an anthracene derivative, a pyrene derivative, a chrysene derivative, a fluoranthene derivative, a perylene derivative, a fluorene derivative, an arylacetylene derivative, a styrylarylene derivative, a styrylamine derivative, an arylamine derivative, a boron complex, a coumarin derivative, a pyran derivative, a cyanine derivative, a croconium derivative, a squarium derivative, an oxobenzanthracene derivative, a fluorescein derivative, a rhodamine derivative, a pyrylium derivative, a perylene derivative, a polythiophene derivative, and a rare earth complex-based compound.

Furthermore, as the fluorescent light emitting dopant, a luminescent dopant utilizing delayed fluorescence, or the like may also be used. Specific examples of the luminescent dopant utilizing delayed fluorescence include, for example, the compounds described in WO 2011/156793 A, JP 2011-213643 A, and JP 2010-93181 A.

(2) Host Compound

A host compound is a compound that is responsible mainly for the injection and transport of charges in the light emitting layer, and light emission of the host compound itself in an organic EL element is substantially not observed.

Preferably, the host compound is a compound having a phosphorescence quantum yield of phosphorescent light emission at room temperature (25° C.) of less than 0.1, and more preferably a compound having a phosphorescence quantum yield of less than 0.01. Furthermore, it is preferable that among the compounds included in the light emitting layer, the mass ratio in that layer is 20% or more.

It is preferable that the energy of the excited state of the host compound is higher than the energy of the excited state of the luminescent dopant included in the same layer.

The host compound may be used singly, or multiple kinds of compounds may be used in combination. When multiple kinds of the host compounds are used, transfer of charges can be regulated, and the efficiency of the organic EL element can be increased.

There are no particular limitations on the host compound used in the light emitting layer, and any compound that is conventionally used in organic EL elements can be used. For example, the host compound may be a low molecular weight compound or a polymer compound having repeating units, or may also be a compound having a reactive group such as a vinyl group or an epoxy group.

As a known host compound, from a view of having a hole transporting ability or electron transporting ability, while preventing increase in the wavelength of emitted light, and having stability against heat generation at the time of high temperature driving of an organic EL element or during driving of the element, a compound having a high glass transition temperature (Tg) is preferred. Regarding the host compound, a compound having a Tg of 90° C. or higher is preferred, and a compound having a Tg of 120° C. or higher is more preferred.

Here, the glass transition point (Tg) is a value that can be determined by a method according to JIS K 7121 using DSC (Differential Scanning calorimetry).

Furthermore, it is preferable for the host compound in the light emitting layer containing a phosphorescent light emitting dopant that the lowest excited triplet energy (T₁) is larger than 2.1 eV. When T₁ is larger than 2.1 eV, high luminous efficiency is obtained. The lowest excited triplet energy (T₁) refers to the peak energy of an emission band corresponding to the transition between the lowest vibrational bands of the phosphorescence light emission spectrum obtained by dissolving a host compound in a solvent and making an observation at the liquid nitrogen temperature or the liquid helium temperature.

Specific examples of known host compounds that are used in organic EL elements include the compounds described in JP 2001-257076 A, JP 2002-308855 A, JP 2001-313179 A, JP 2002-319491 A, JP 2001-357977 A, JP 2002-334786 A, JP 2002-8860 A, JP 2002-334787 A, JP 2002-15871 A, JP 2002-334788 A, JP 2002-43056 A, JP 2002-334789 A, JP 2002-75645 A, JP 2002-338579 A, JP 2002-105445 A, JP 2002-343568 A, JP 2002-141173 A, JP 2002-352957 A, JP 2002-203683 A, JP 2002-363227 A, JP 2002-231453 A, JP 2003-3165 A, JP 2002-234888 A, JP 2003-27048 A, JP 2002-255934 A, JP 2002-260861 A, JP 2002-280183 A, JP 2002-299060 A, JP 2002-302516 A, JP 2002-305083 A, JP 2002-305084 A, JP 2002-308837 A, US 2003/0,175,553 A1, US 2006/0,280,965 A1, US 2005/0,112,407 A1, US 2009/0,017,330 A1, US 2009/0,030,202 A1, US 2005/0,238,919 A1, WO 2001/039234 A, WO 2009/021126 A, WO 2008/056746 A, WO 2004/093207 A, WO 2005/089025 A, WO 2007/063796 A, WO 2007/063754 A, WO 2004/107822 A, WO 2005/030900 A, WO 2006/114966 A, WO 2009/086028 A, WO 2009/003898 A, WO 2012/023947 A, JP 2008-074939 A, JP 2007-254297 A, and EP 2034538 B. However, the examples are not limited to these.

<Intermediate Layer>

In regard to the organic EL element of the present invention, it is preferable to provide a non-luminescent intermediate layer between the first light emitting layer and the second light emitting layer. The intermediate layer is a layer having an interface contacting an organic compound layer that electrically connects the first light emitting layer and the second light emitting layer in series in an electric field. As such, the intermediate layer can be configured to have a function of transporting electrons to one of the light emitting layers, and to have a function of transporting holes to the other light emitting layer.

For the intermediate layer, an organic compound or an inorganic compound can be used alone, or multiple kinds of compounds may be used as a mixture; however, it is preferable to use an organic compound or an inorganic compound alone. Furthermore, it is preferable that the compound used alone in the intermediate layer is the same as the host compound included in the first light emitting layer or the second light emitting layer.

The intermediate layer is composed of at least one or more layers; however, the intermediate layer is preferably composed of two layers. Furthermore, it is particularly preferable that the intermediate layer includes any one or both of a p-type semiconductor layer and an n-type semiconductor layer.

Furthermore, it is preferable to use the intermediate layer as a bipolar layer that can generate and transport holes or electrons within the layer under the effect of an external electric field.

Furthermore, the intermediate layer can be formed using the same material as the material of the anode or the cathode, or can be formed using a material having lower electrical conductivity than that of the anode and the cathode.

Examples of the organic compound used for the intermediate layer include a nanocarbon material, an organometallic complex compound functioning as an organic semiconductor material (an organic acceptor or an organic donor), an organic salt, an aromatic hydrocarbon compound and derivatives thereof, and a heteroaromatic hydrocarbon compound and derivatives thereof.

Examples of the inorganic compound include a metal, an inorganic oxide, and an inorganic salt.

Examples of a substance having high electron transportability that can be used include metal complexes having a quinoline skeleton or a benzoquinoline skeleton, such as tris(8-quinolinolato)aluminum (Alq₃), tris(4-methyl-8-quinolinolato)aluminum (Almq₃), bis(10-hydroxybenzo[h]quinolinato) beryllium (BeBq₂), and bis(2-methyl-8-quinolinolato) (4-phenylphenolato)aluminum (BAlq).

In addition to these, metal complexes having an oxazole-based or thiazole-based ligand, such as bis[2-(2-hydroxyphenyl)benzoxazolato]zinc (Zn(BOX)₂) and bis[2-(2-hydroxyphenyl)benzothiazolato]zinc (Zn(BTZ)₂) can also be used.

In addition to metal complexes,
2-(4-biphenylyl)-5-(4-tert-butylphenyl)-1, 3, 4-oxadiazole (PBD),
1, 3-bis[5-(p-tert-butylphenyl)-1, 3, 4-oxadiazol-2-yl]benzene (OXD-7),
3-(4-biphenylyl)-4-phenyl-5-(4-tert-butylphenyl)-1, 2, 4-triazole (TAZ), basophenanthroline (BPhen), and basocuproine (BCP), and the like can also be used.

The substance having high electron transportability as described above is primarily a substance having an electron mobility of 1×10⁻⁶ cm²/Vs or higher. Substances other than the above-mentioned substances can also be used as long as they have higher transportability for electrons than that for holes.

Regarding a substance having high hole transportability, for example, aromatic amine compounds such as 4, 4′-bis[N-(1-naphthyl)-N-phenylamino]biphenyl (NPB or α-NPD),
N,N′-bis(3-methylphenyl)-N,N′-diphenyl-[1, 1′-biphenyl]-4,4′-diamine (TPD),
4, 4′,4″-tris(N,N-diphenylamino)triphenylamine (TDATA), and
4, 4′,4″-tris[N-(3-methylphenyl)-N-phenylamino]triphenylamine (MTDATA) can be used.

The substance having high hole transportability as described above is primarily a substance having a hole mobility of 1×10⁻⁶ cm²/Vs or higher. Substances other than the above-mentioned substances can also be used as long as they have higher transportability for holes than that for electrons. Furthermore, the host compounds mentioned above may also be used.

The layer thickness of the intermediate layer is not particularly limited; however, the layer thickness is preferably in the range of 1 to 7 nm.

<Hole Injection/Transport Layer>

The hole injection/transport layer according to the present invention is configured to include, for example, a hole injection layer, a hole transport layer, or an electron blocking layer.

According to the present invention, it is preferable that the layer thickness of the hole injection/transport layer (d_{HITL}) and the layer thickness of the hole injection layer (d_{HIL}) satisfy the conditional expression: d_{HIL}/d_{HITL}≦0.20, and it is more preferable that the layer thicknesses satisfy the conditional expression: d_{HIL}/d_{HITL}≦0.10.

(Hole Injection Layer)

A hole injection layer (also referred to as “anode buffer layer”) is a layer provided between the anode and the light emitting layer for the purpose of reducing the driving voltage or enhancing the emission luminance. An example of the hole injection layer is described in “Organic EL elements and Frontiers of Industrialization Thereof (published on Nov. 30, 1998, by NTS Publishing, Ltd.)”, Vol. 2, Chapter 2, “Electrode Materials” (pp. 123-166).

The hole injection layer is provided as necessary, and as described above, the hole injection layer is provided between the anode and the light emitting layer, or between the anode and the hole transport layer.

The details of the hole injection layer are also described in JP 9-45479 A, JP 9-260062 A, JP 8-288069 A, and the like.

(1) Compound Having Structure Represented by General Formula (1)

Regarding the material that constitutes the hole injection layer, a compound having a structure represented by the following General Formula (1) can be suitably used.

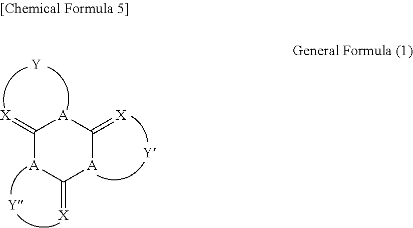

in General Formula (1), A represents C or N; X represents N or CR⁰; R⁰ represents any one group selected from a hydrogen atom, a halogen atom, a cyano group, a nitro group, a formyl group, an acetyl group, a benzoyl group, an amide group (—CONHR¹ or —CONR¹R²), a styryl group, an ethynyl group, a quinolyl group, a quinazolyl group, a phenanthrolyl group, a biquinolyl group, an anthraquinonyl group, a benzoquinonyl group, a quinonyl group, an acridinyl group, and a group, being substituted or unsubstituted, selected from an alkyl group, an aryl group, an aralkyl group, an alkylamino group, an arylamino group, an aralkylamino group and a heterocyclic group; R¹ and R² each independently represent an alkyl group having 1 to 60 carbon atoms, an aryl group, or a 5-membered to 7-membered heterocyclic group, all of these groups being substituted or unsubstituted; Y, Y′ and Y″ each represent a 5-membered aromatic heterocyclic ring containing A and X as ring members, or a 6-membered aromatic heterocyclic ring containing A and X as ring members, all of these heterocyclic rings being substituted or unsubstituted; and Y, Y′ and Y″ may be identical or different from each other.

The alkyl group for R⁰ in General Formula (1) is preferably an alkyl group having 1 to 20 carbon atoms, and examples thereof include a linear alkyl group such as a methyl group, an ethyl group, a propyl group, or a hexyl group; and a branched alkyl group such as an isopropyl group or a t-butyl group.

Examples of the aryl group include a monocyclic aromatic hydrocarbon ring group such as a phenyl group; and a polycyclic aromatic hydrocarbon ring group such as a naphthyl group, an anthracenyl group, a pyrenyl group, or a perylenyl group.

Examples of the aralkyl group include an alkyl group which has 1 to 20 carbon atoms and is substituted with an aromatic hydrocarbon ring group such as a phenyl group, a biphenyl group, a naphthyl group, a terphenyl group, an anthracenyl group, a pyrenyl group, or a perylenyl group.

Examples of the alkylamino group include an amino group substituted with an aliphatic hydrocarbon having 1 to 20 carbon atoms.

Examples of the arylamino group include an amino group substituted with an aromatic hydrocarbon ring group such as a phenyl group, a biphenyl group, a naphthyl group, a terphenyl group, an anthracenyl group, a pyrenyl group, or a perylenyl group.

Examples of the aralkylamino group include an amino group substituted with an aromatic hydrocarbon ring group such as a phenyl group, a biphenyl group, a naphthyl group, a terphenyl group, an anthracenyl group, a pyrenyl group or a perylenyl group, and an aliphatic hydrocarbon having 1 to 20 carbon atoms.

Examples of the heterocyclic group include a pyrrolyl group, a thienyl group, an indolyl group, an oxazolyl group, an imidazolyl group, a thiazolyl group, a pyridyl group, a pyrimidinyl group, a piperazinyl group, a thiophenyl group, a furanyl group, and a pyridazinyl group.

Examples of the alkyl group having 1 to 60 carbon atoms for R¹ and R² in General Formula (1) include a linear alkyl group such as a methyl group, an ethyl group, a propyl group or a hexyl group; and a branched alkyl group such as an isopropyl group or a t-butyl group.

Examples of the aryl group include a monocyclic aromatic hydrocarbon ring group such as a phenyl group; and a polycyclic aromatic hydrocarbon ring group such as a naphthyl group, an anthracenyl group, a pyrenyl group or a perylenyl group.

Examples of the 5-membered to 7-membered heterocyclic group include a pyrrolyl group, a thienyl group, an indolyl group, an oxazolyl group, an imidazolyl group, a thiazolyl group, a pyridyl group, a pyrimidinyl group, a piperazinyl group, a thiophenyl group, a furanyl group, and a pyridazinyl group.

Examples of the 5-membered aromatic heterocyclic ring for Y, Y′ and Y″ in General Formula (1) include a pyrazole ring, an imidazole ring, a thiazole ring, an oxazole ring, an isoxazole ring, an indole ring, a triazole ring, a benzimidazole ring, a benzopyrazole ring, a benzothiazole ring, a benzoxazole ring, and a benzisoxazole ring.

Examples of the 6-membered aromatic heterocyclic ring include a pyridine ring, a pyridazine ring, a pyrimidine ring, a pyrazine ring, and a triazine ring.

R⁰ to R² and Y, Y′ and Y″ in General Formula (1) may be substituted, and examples of the substituent include a linear or branched alkyl group (for example, a methyl group, an ethyl group, a propyl group, an isopropyl group, a t-butyl group, a pentyl group, a hexyl group, an octyl group, a dodecyl group, a tridecyl group, a tetradecyl group, or a pentadecyl group), an alkenyl group (for example, a vinyl group or an allyl group), an alkynyl group (for example, an ethynyl group or a propargyl group), an aromatic hydrocarbon ring group (also referred to as an aromatic carbon ring group, an aryl group or the like; for example, a group derived from a benzene ring, a biphenyl, a naphthalene ring, an azulene ring, an anthracene ring, a phenanthrene ring, a pyrene ring, a chrysene ring, a naphthacene ring, a triphenylene ring, an o-terphenyl ring, a m-terphenyl ring, a p-terphenyl ring, an acenaphthene ring, a coronene ring, an indene ring, a fluorene ring, a fluoranthrene ring, a naphthacene ring, a pentacene ring, a perylene ring, a pentaphene ring, a picene ring, a pyrene ring, a pyranthrene ring, an anthranthrene ring, or a tetraline ring), an aromatic heterocyclic group (for example, a furan ring, a dibenzofuran ring, a thiophene ring, a dibenzothiophene ring, an oxazole ring, a pyrrole ring, a pyridine ring, a pyridazine ring, a pyrimidine ring, a pyrazine ring, a triazine ring, a benzimidazole ring, an oxadiazole ring, a triazole ring, an imidazole ring, a pyrazole ring, a thiazole ring, an indole ring, an indazole ring, a benzimidazole ring, a benzothiazole ring, a benzoxazole ring, a quinoxaline ring, a quinazoline ring, a cinnoline ring, a quinoline ring, an isoquinoline ring, a phthalazine ring, a naphthyridine ring, a carbazole ring, a carboline ring, a diazacarbazole ring (a group derived from a ring in which one of the carbon atoms of the hydrocarbon ring that constitutes a carboline ring is further substituted by a nitrogen atom; a carboline ring and a diazacarbazole ring may be together referred to as “azacarbazole ring”), a non-aromatic hydrocarbon ring group (for example, a cyclopentyl group or a cyclohexyl group), a non-aromatic heterocyclic group (for example, a pyrrolidyl group, an imidazolidyl group, a morpholyl group, or an oxazolidyl group), an alkoxy group (for example, a methoxy group, an ethoxy group, a propyloxy group, a pentyloxy group, a hexyloxy group, an octyloxy group, or a dodecyloxy group), a cycloalkoxy group (for example, a cyclopentyloxy group or a cyclohexyloxy group), an aryloxy group (for example, a phenoxy group or a naphthyloxy group), an alkylthio group (for example, a methylthio group, an ethylthio group, a propylthio group, a pentylthio group, a hexylthio group, an octylthio group, or a dodecylthio group), a cycloalkylthio group (for example, a cyclopentylthio group or a cyclohexylthio group), an arylthio group (for example, a phenylthio group or a naphthylthio group), an alkoxycarbonyl group (for example, a methyloxycarbonyl group, an ethyloxycarbonyl group, a butyloxycarbonyl group, an octyloxycarbonyl group, or a dodecyloxycarbonyl group), an aryloxycarbonyl group (for example, a phenyloxycarbonyl group or a naphthyloxycarbonyl group), a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, or a 2-pyridylaminosulfonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, or a pyridylcarbonyl group), an acyloxy group (for example, an acetyloxy group, an ethylcarbonyloxy group, a butylcarbonyloxy group, an octylcarbonyloxy group, a dodecylcarbonyloxy group, or a phenylcarbonyloxy group), an amide group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, or a naphthylcarbonylamino group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, or a 2-pyridylaminocarbonyl group), a ureido group (for example, a methylureido group, an ethylureido group, a pentylureido group, a cyclohexylureido group, an octylureido group, a dodecylureido group, a phenylureido group, a naphthylureido group, or a 2-pyridylaminoureido group), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, or a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, or a dodecylsulfonyl group), an arylsulfonyl group or a heteroarylsulfonyl group (for example, a phenylsulfonyl group, a naphthylsulfonyl group, or a 2-pyridylsulfonyl group), an amino group (for example, an amino group, an ethylamino group, a dimethylamino group, a butylamino group, a cyclopentylamino group, a 2-ethylhexylamino group, a dodecylamino group, an anilino group, a naphthylamino group, or a 2-pyridylamino group), a halogen atom (for example, a fluorine atom, a chlorine atom, or a bromine atom), a fluorinated hydrocarbon group (for example, a fluoromethyl group, a trifluoromethyl group, a pentafluoroethyl group, or a pentafluorophenyl group), a cyano group, a nitro group, a hydroxyl group, a thiol group, a silyl group (for example, a trimethylsilyl group, a triisopropylsilyl group, a triphenylsilyl group, or a phenyldiethylsilyl group), and a deuterium atom.

The compound having a structure represented by General Formula (1) is preferably a compound having a structure represented by the following General Formula (2).

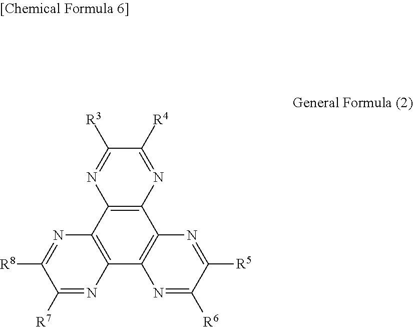

in General Formula (2), R³ to R⁸ each independently represent any one group selected from a hydrogen atom, a halogen atom, a cyano group, a nitro group, a sulfonyl group (—SO₂R⁹), a sulfinyl group (—SOR⁹), a sulfonamide group (—SO₂NR⁹R¹⁰), a sulfonato group (—SO₃R⁹), a trifluoromethyl group, an ester group (—COOR⁹), an amide group (—CONHR⁹ or —CONR⁹R¹⁰), and a group, being substituted or unsubstituted, selected from a linear or branched alkyl group having 1 to 12 carbon atoms, a linear or branched alkoxy group having 1 to 12 carbon atoms, an aromatic hydrocarbon ring group, an arylamino group, a non-aromatic heterocyclic group, an aromatic heterocyclic group, and an aralkylamino group; and R⁹ and R¹⁰ each independently represent an alkyl group having 1 to 60 carbon atoms, an aryl group, or a 5-membered to 7-membered heterocyclic group, all of these groups being substituted or unsubstituted.

R⁹ and R¹⁰ in General Formula (2) have the same meanings as R¹ and R² in General Formula (1), respectively.

R³ to R¹⁰ in General Formula (2) may be substituted, and examples of a substituent thereof include the same substituents as the substituents for General Formula (1).

The compound having a structure represented by General Formula (1) is preferably a compound having a structure represented by the following General Formula (3).

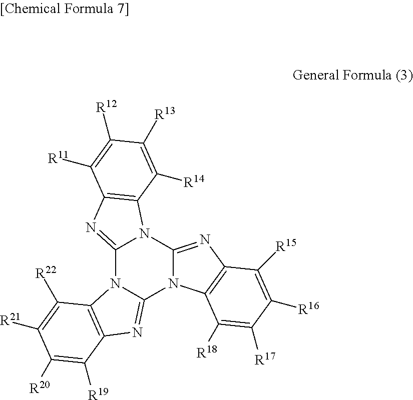

in General Formula (3), R¹¹ to R²² each independently represent any one group selected from a halogen atom, an amino group, a cyano group, a nitro group, an alkoxy group, an aryloxy group, an alkylthio group, an arylthio group, an acyl group, an alkoxycarbonyl group, an aryloxycarbonyl group, an alkylsulfonyl group, an arylsulfonyl group, and a group, being substituted or unsubstituted, selected from an aliphatic hydrocarbon group, an aromatic hydrocarbon ring group, an aliphatic heterocyclic group and an aromatic heterocyclic group; and R¹¹ to R²² may respectively form a ring together with adjacent substituents.

Examples of the alkoxy group for R¹¹ to R²² in General Formula (3) include an alkoxy group having 1 to 18 carbon atoms, such as a methoxy group, an ethoxy group, a propoxy group, an isopropoxy group, a butoxy group, an isobutoxy group, a tert-butoxy group, a pentyloxy group, a hexyloxy group, an octyloxy group, a tert-octyloxy group, a 2-bornyloxy group, a 2-isobornyloxy group, or 1-adamantyloxy group.

Examples of the aryloxy group include an aryloxy group having 6 to 30 carbon atoms, such as a phenoxy group, a 4-tert-butylphenoxy group, a 1-naphthyloxy group, a 2-naphthyloxy group, a 9-anthryloxy group, a 2-phenanthryloxy group, a 1-naphthacenyl group, a 1-pyrenyl group, a 2-chrysenyl group, a 3-perylenyl group, or a 1-pentacenyl group.

Examples of the alkylthio group include an alkylthio group having 1 to 18 carbon atoms, such as a methylthio group, an ethylthio group, a propylthio group, a butylthio group, an isobutylthio group, a tert-butylthio group, a pentylthio group, an isopentylthio group, a hexylthio group, an isohexylthio group, a heptyl group, or an octylthio group.

Examples of the arylthio group include an arylthio group having 6 to 30 carbon atoms, such as a phenylthio group, a 4-methylphenylthio group, a 4-tert-butylphenylthio group, or a 1-naphthylthio group.

Examples of the acyl group include an acyl group having 2 to 18 carbon atoms, such as an acetyl group, a propionyl group, a pivaloyl group, a cyclohexylcarbonyl group, a benzoyl group, a toluoyl group, an anisoyl group, or a cinnamoyl group.

Examples of the alkoxycarbonyl group include an alkoxycarbonyl group having 2 to 18 carbon atoms, such as a methoxycarbonyl group, an ethoxycarbonyl group, a propoxycarbonyl group, a butoxycarbinyl group, a pentyloxycarbonyl group, a hexyloxycarbonyl group, a heptyloxycarbonyl group, an octyloxycarbonyl group, or a benzyloxycarbonyl group.

Examples of the aryloxycarbonyl group include an aryloxycarbonyl group having 7 to 30 carbon atoms, such as a phenoxycarbonyl group, a 1-naphthyloxycarbonyl group, or a 2-phenanthryloxycarbonyl group.

Examples of the alkylsulfonyl group include an alkylsulfonyl group having 1 to 18 carbon atoms, such as a mesyl group, an ethylsulfonyl group, a propylsulfonyl group, a butylsulfonyl group, a pentylsulfonyl group, a hexylsulfonyl group, a heptylsulfonyl group, an octylsulfonyl group, or a nonylsulfonyl group.

Examples of the arylsulfonyl group include an arylsulfonyl group having 6 to 30 carbon atoms, such as a benzenesulfonyl group, a p-toluenesulfonyl group, or a 1-naphthylsulfonyl group.

Examples of the aliphatic hydrocarbon group include monovalent aliphatic hydrocarbon groups each having 1 to 18 carbon atoms, including an alkyl group (for example, an alkyl group having 1 to 18 carbon atoms, such as a methyl group, an ethyl group, a propyl group, an isopropyl group, a butyl group, a sec-butyl group, a tert-butyl group, a pentyl group, an isopentyl group, a hexyl group, an isohexyl group, a heptyl group, an octyl group, a nonyl group, a decyl group, a dodecyl group, a pentadecyl group, or an octadecyl group), an alkenyl group (for example, an alkenyl group having 2 to 18 carbon atoms, such as a vinyl group, a 1-propenyl group, a 2-propenyl group, an isopropenyl group, a 1-butenyl group, a 2-butenyl group, a 3-butenyl group, a 1-octenyl group, a 1-decenyl group, or a 1-octadecenyl group), an alkynyl group (for example, an alkynyl group having 2 to 18 carbon atoms, such as an ethynyl group, a 1-propynyl group, a 2-propynyl group, a 1-butynyl group, a 2-butynyl group, a 3-butynyl group, a 1-octynyl group, a 1-decynyl group, or a 1-octadecynyl group), and a cycloalkyl group (for example, a cycloalkyl group having 3 to 18 carbon atoms, such as a cyclopropyl group, a cyclobutyl group, a cyclopentyl group, a cyclohexyl group, a cycloheptyl group, a cyclooctyl group, a cyclooctadecyl group, a 2-bornyl group, a 2-isobornyl group, or a 1-adamantyl group).

Examples of the aromatic hydrocarbon ring group include a fused ring hydrocarbon group having 10 to 30 carbon atoms, such as a 1-naphthyl group, a 2-naphthyl group, a 1-anthryl group, a 2-anthryl group, a 5-anthryl group, a 1-phenanthryl group, a 9-phenanthryl group, a 1-acenaphthyl group, a 2-triphenylenyl group, a 1-chrysenyl group, a 2-azulenyl group, a 1-pyrenyl group, a 2-triphenylel group, a 1-pyrenyl group, a 2-pyrenyl group, a 1-perylenyl group, a 2-perylenyl group, a 3-perylenyl group, a 2-indenyl group, a 1-acenaphthylenyl group, a 2-naphthacenyl group, or a 2-pentacenyl group; and a ring-aggregated hydrocarbon group having 12 to 30 carbon atoms, such as an o-biphenylyl group, a m-biphenylyl group, a p-biphenylyl group, a terphenylyl group, or a 7-(2-naphthyl)-2-naphthyl group.

Examples of the aliphatic heterocyclic group include a monovalent aliphatic heterocyclic group having 3 to 18 carbon atoms, such as a 3-isochromanyl group, a 7-chromanyl group, a 3-coumarinyl group, a piperidino group, a morpholino group, or a 2-morpholinyl group.

Examples of the aromatic heterocyclic group include an aromatic heterocyclic group having 3 to 30 carbon atoms, such as a 2-furyl group, a 3-furyl group, a 2-thienyl group, a 3-thienyl group, a 2-benzofuryl group, a 2-benzothienyl group, a 2-pyridyl group, a 3-pyridyl group, a 4-pyridyl group, a 2-quinolyl, or a 5-isoquinolyl group.

R¹¹ to R²² in General Formula (3) may be substituted, and examples of the substituent thereof include the same substituents as the substituents for General Formula (1).

(2) Compound Having Structure Represented by General Formula (4)

Regarding the material that constitutes the hole injection layer, a compound having a structure represented by the following General Formula (4) can be suitably used.

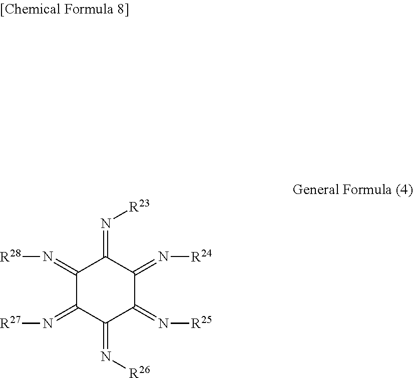

in General Formula (4), R²³ to R²⁸ each independently represent an alkyl group, an aryl group, an aralkyl group, or a heterocyclic group, all of these groups being substituted or unsubstituted; R²³ to R²⁸ may be identical or different; and R²³ with R²⁴, R²⁵ with R²⁶, and R²⁷ with R²⁸, or R²³ with R²⁸, R²⁴ with R²⁵, and R²⁶ with R²⁷ may form a fused ring.

Examples of the alkyl group for R²³ to R²⁸ in General Formula (4) include a linear alkyl group such as a methyl group, an ethyl group, a propyl group, or a hexyl group; and a branched alkyl group such as an isopropyl group or a t-butyl group.

Examples of the aryl group include a monocyclic aromatic hydrocarbon ring group such as a phenyl group; and a polycyclic aromatic hydrocarbon ring group such as a naphthyl group or an anthracenyl group.

Examples of the aralkyl group include a benzyl group, a phenylpropyl group, and a naphthylmethyl group.

Examples of the heterocyclic group include a heterocyclic monocyclic ring and a heterocyclic fused ring, such as a pyrrolyl group, a thienyl group, a pyridyl group, a phenazyl group, a pyridazyl group, or an acridyl group.

Examples of the substituent for R²³ to R²⁸ in General Formula (4) include a halogen atom, a cyano group, a nitro group, a formyl group, an acetyl group, a benzoyl group, an amide group, a styryl group, an ethynyl group; a monocyclic aromatic ring or a polycyclic fused ring, such as a phenyl group, a naphthyl group, or an anthranyl group; a pyridyl group, a pyridazyl group, a phenazyl group, a pyrrolyl group, an imidazolyl group; and a polycyclic heterocyclic fused ring such as a quinolyl group or an acridyl group.

Examples of the fused ring formed between R²³ with R²⁴, R²⁵ with R²⁶, and R²⁷ with R²⁸, or R²³ with R²⁸, R²⁴ with R²⁵, and R²⁶ with R²⁷ include a benzo group, a naphtho group, and a pyrido group.

(3) Other Materials

According to the present invention, compounds having structures represented by the following General Formulae (5) to (12) are also suitably used.

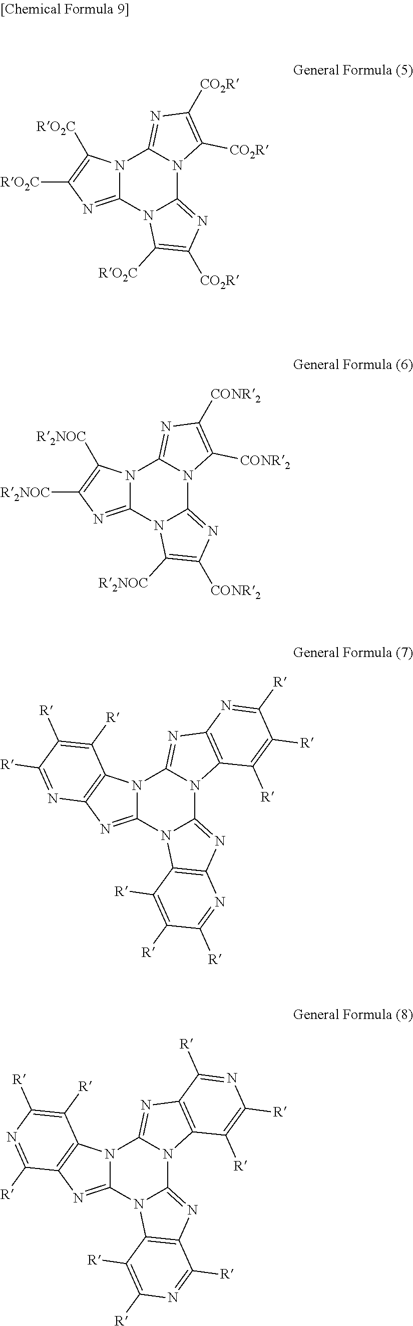

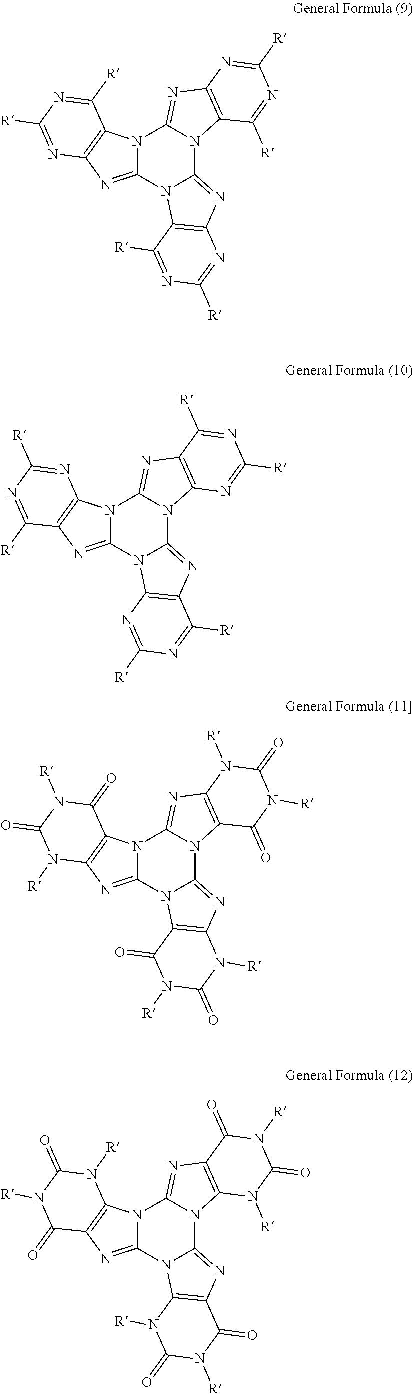

in General Formulae (5) to (12), the units of R′ each independently represent a hydrogen atom, an aryl group having 5 to 60 core atoms, or an alkyl group having 1 to 50 core atoms, the aryl group and the alkyl group being substituted or unsubstituted.

Examples of the aryl group having 5 to 60 core atoms for R′ in General Formulae (5) to (12) include a phenyl group, a naphthyl group, a biphenylyl group, an anthranyl group, a phenanthryl group, a pyrenyl group, a chrysenyl group, a fluoranthenyl group, a fluorenyl group, a pyridinyl group, a quinolyl group, an isoquinolyl group, and a phenanthryl group.

Examples of the alkyl group having 1 to 50 core atoms include a methyl group, an ethyl group, a butyl group, a pentyl group, a hexyl group, a trifluoromethyl group, and a trifluoroethyl group.

R′ in General Formulae (5) to (12) may be substituted, and examples of the substituent thereof include the same substituents as the substituents for General Formula (1).

Specific examples of the compounds having structures represented by General Formulae (1) to (12) will be described below. Meanwhile, the term “Tol” used for the following exemplary compounds represents any one of o-, m-, and p-methylphenyl groups.

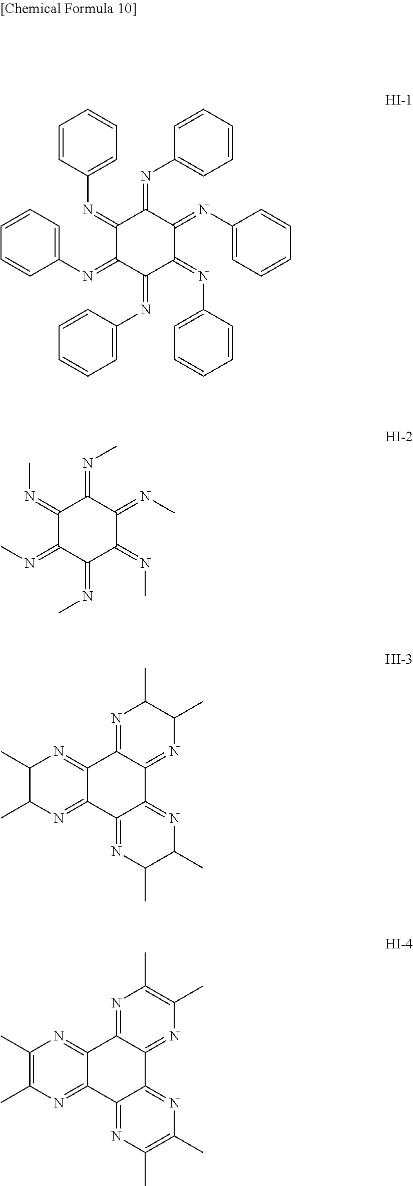

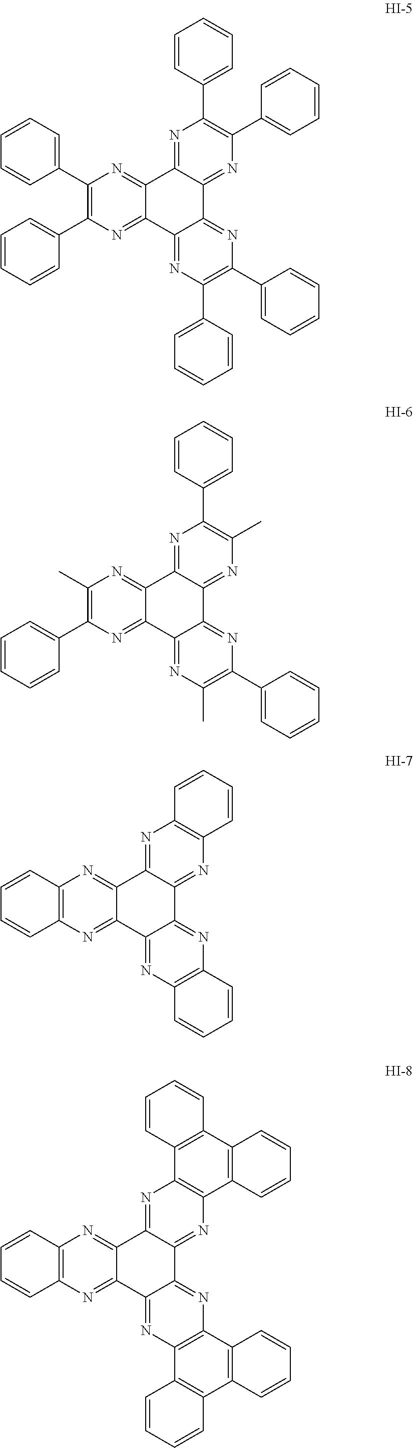

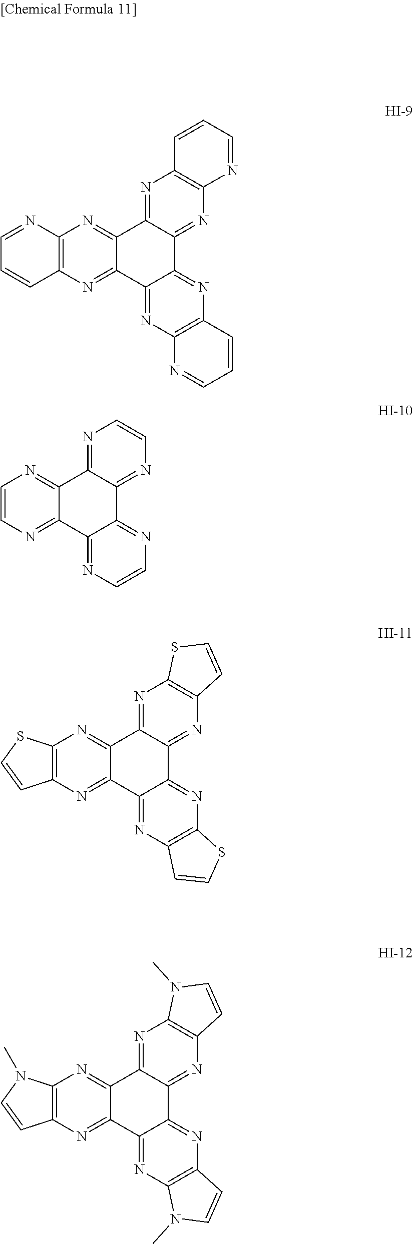

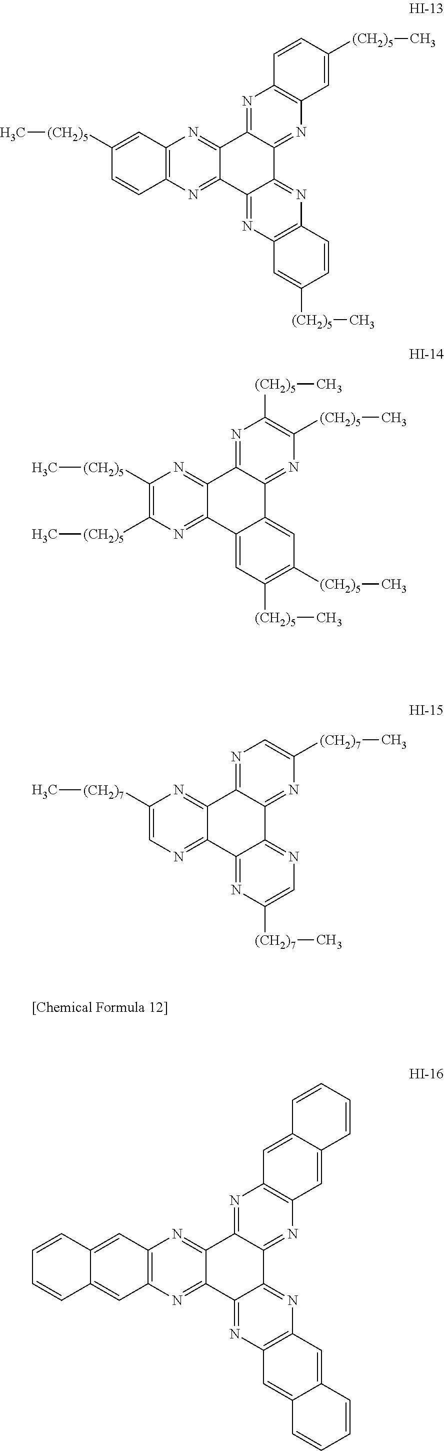

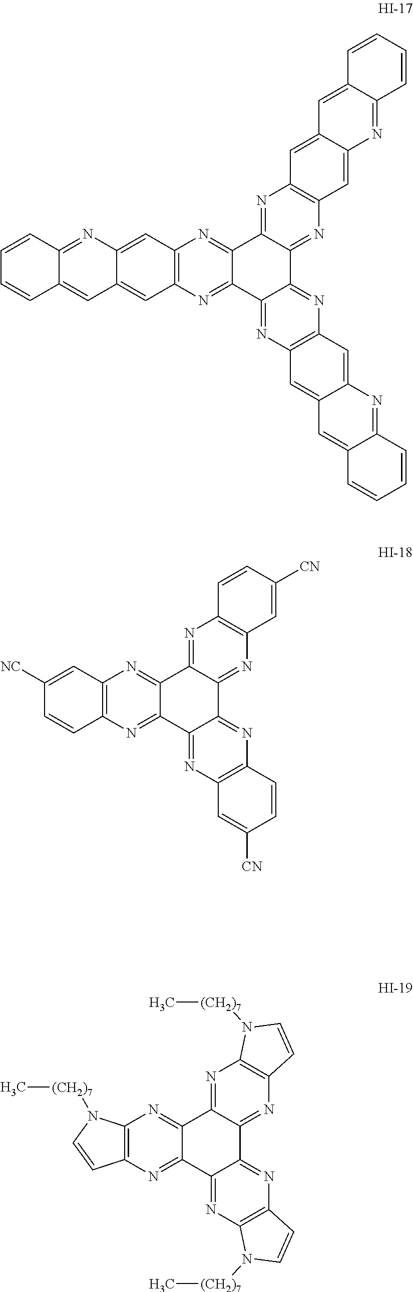

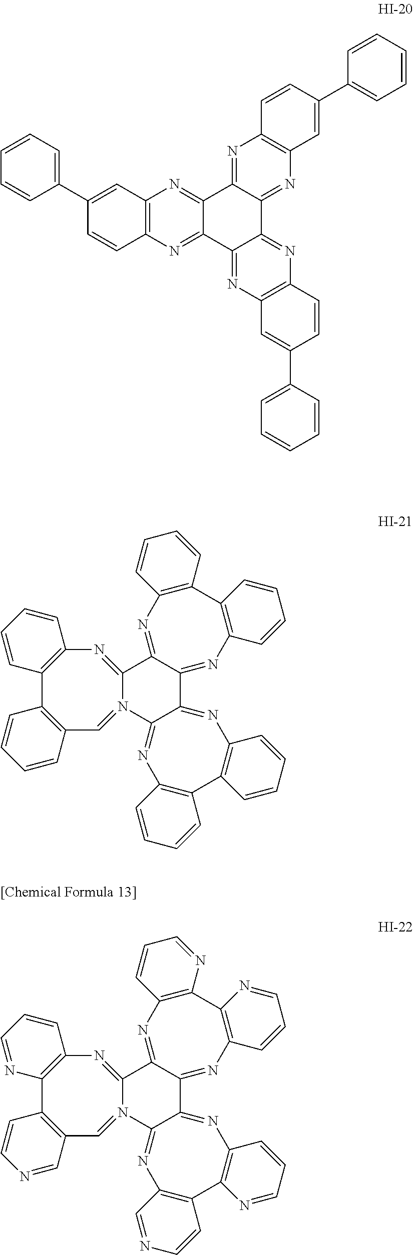

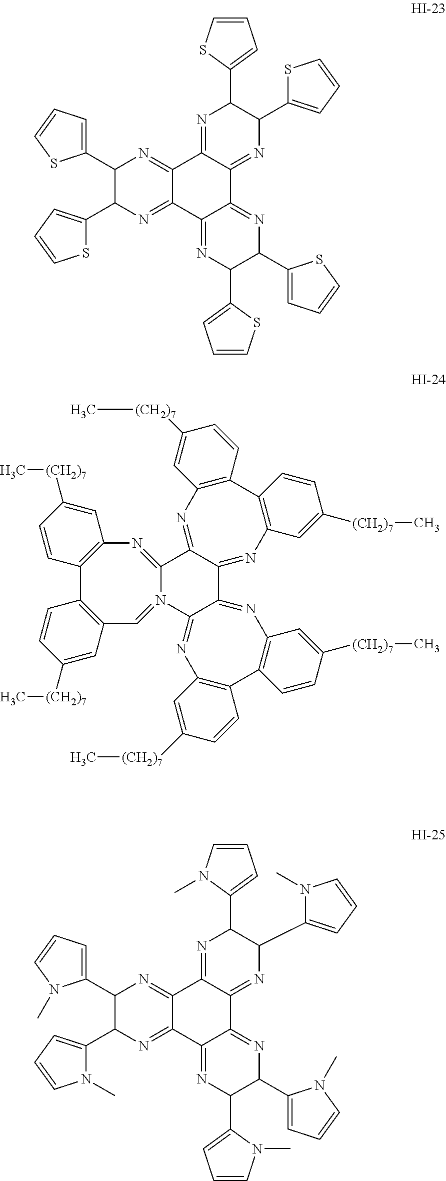

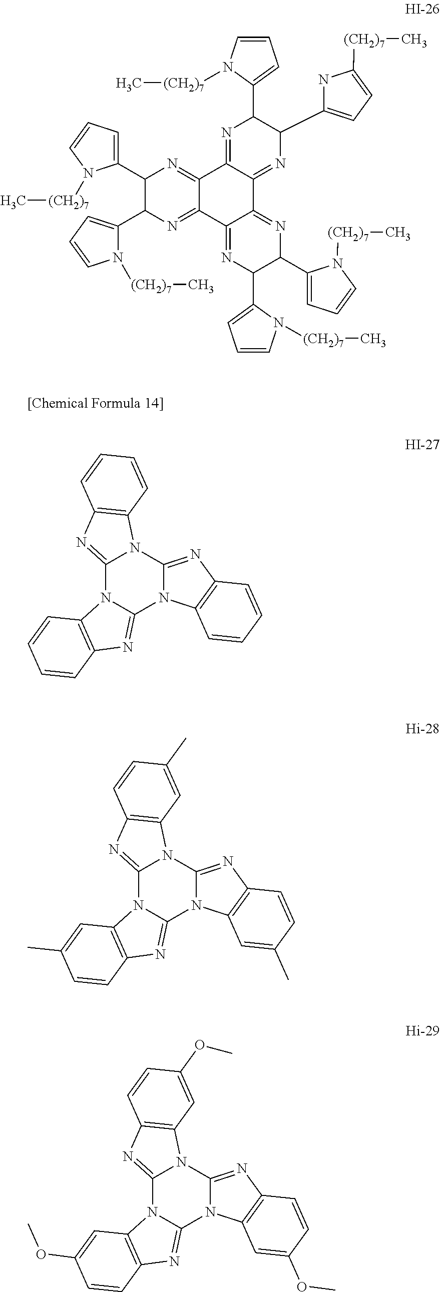

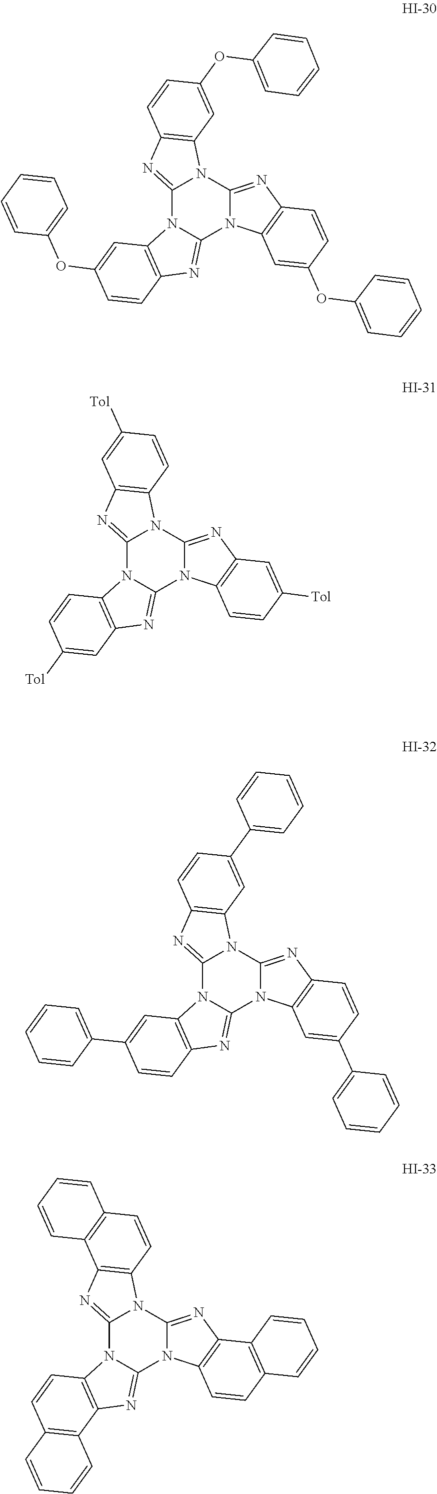

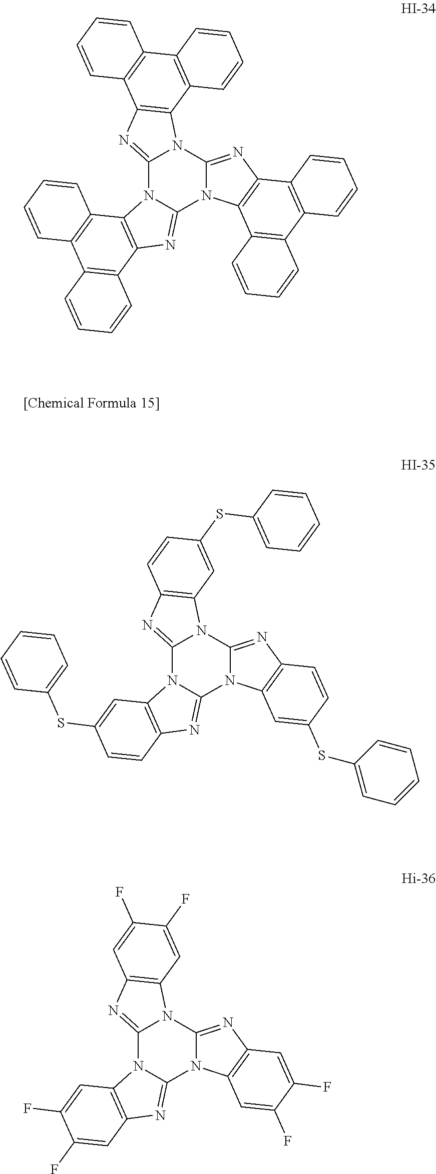

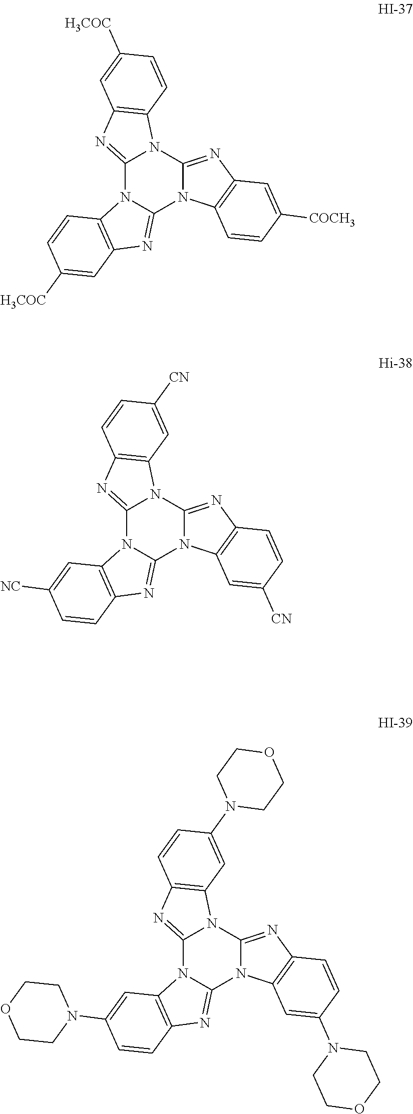

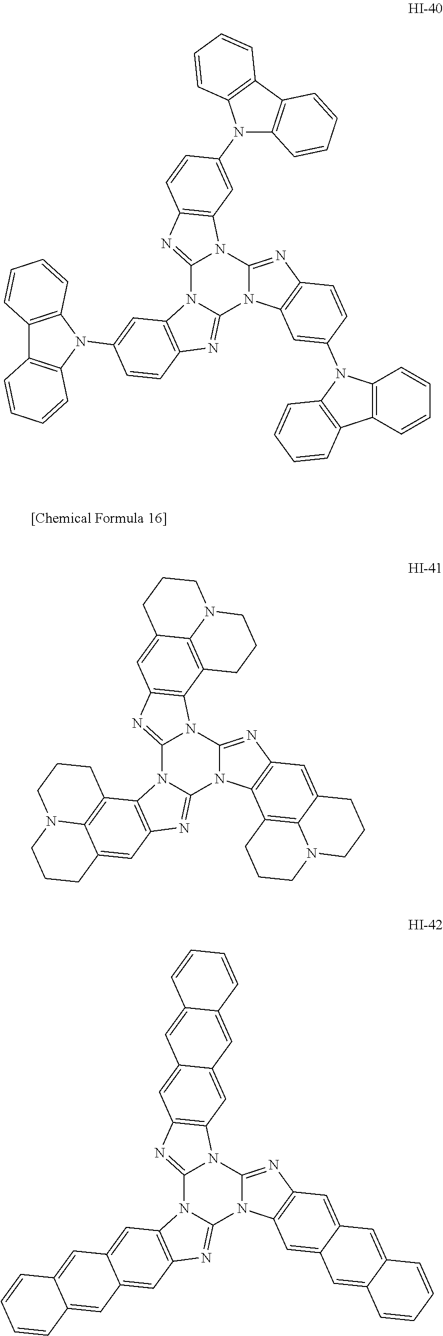

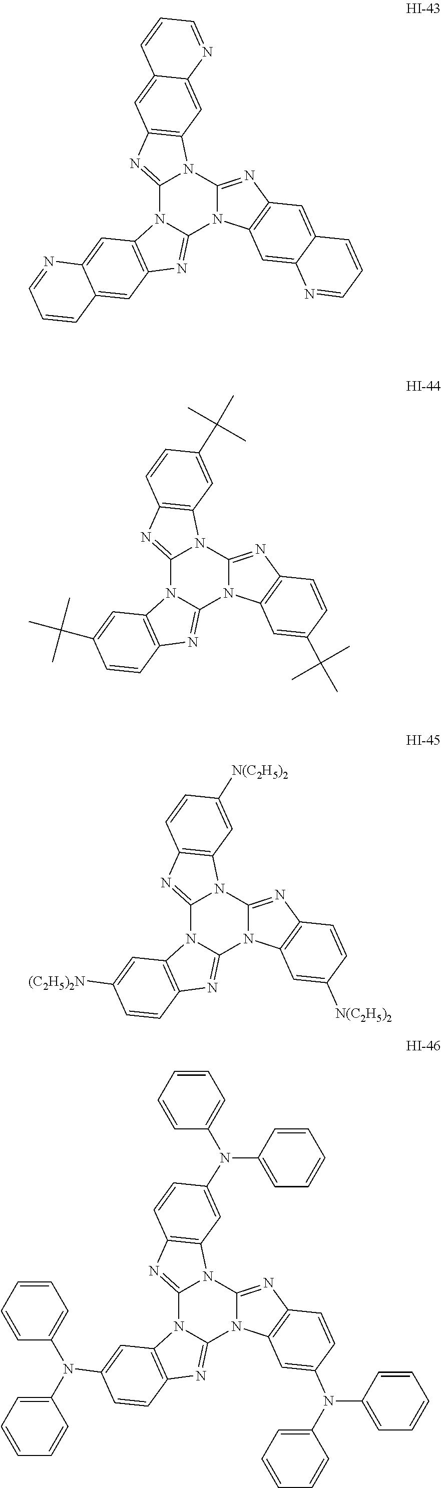

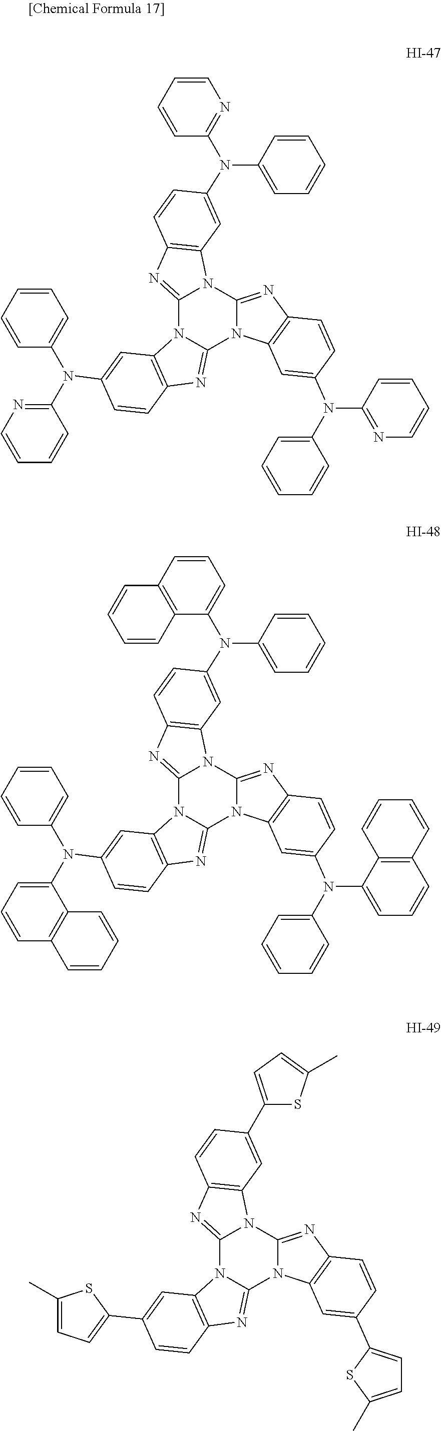

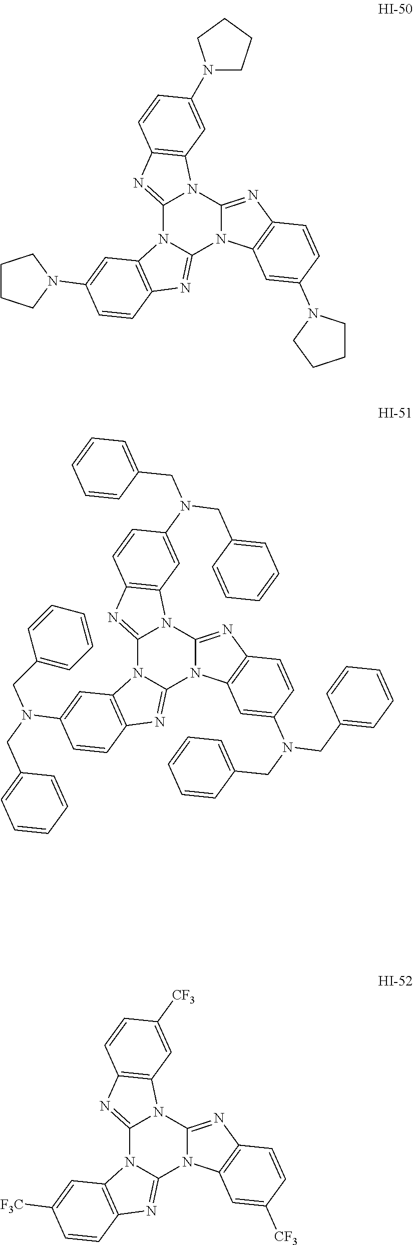

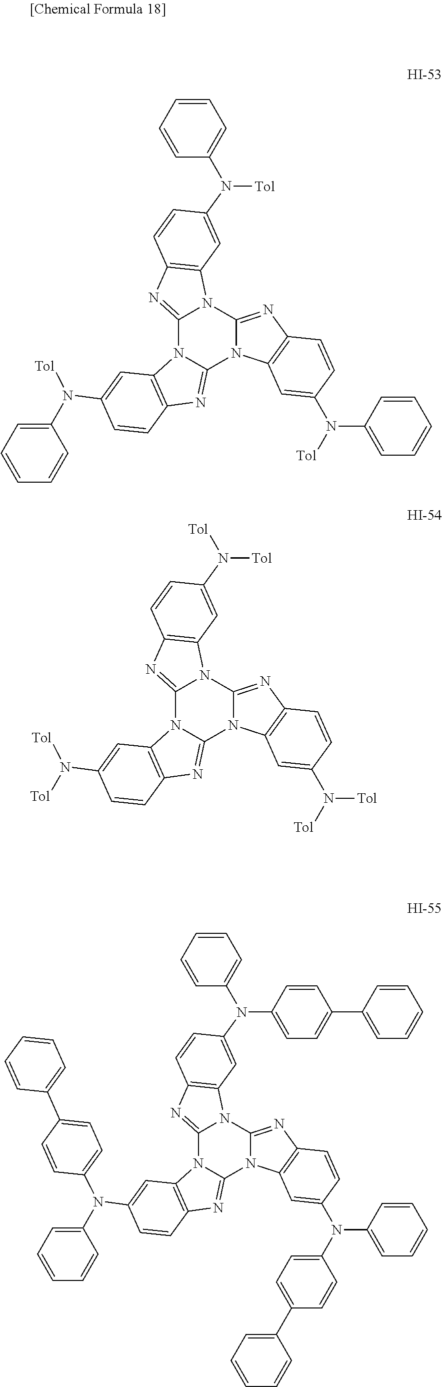

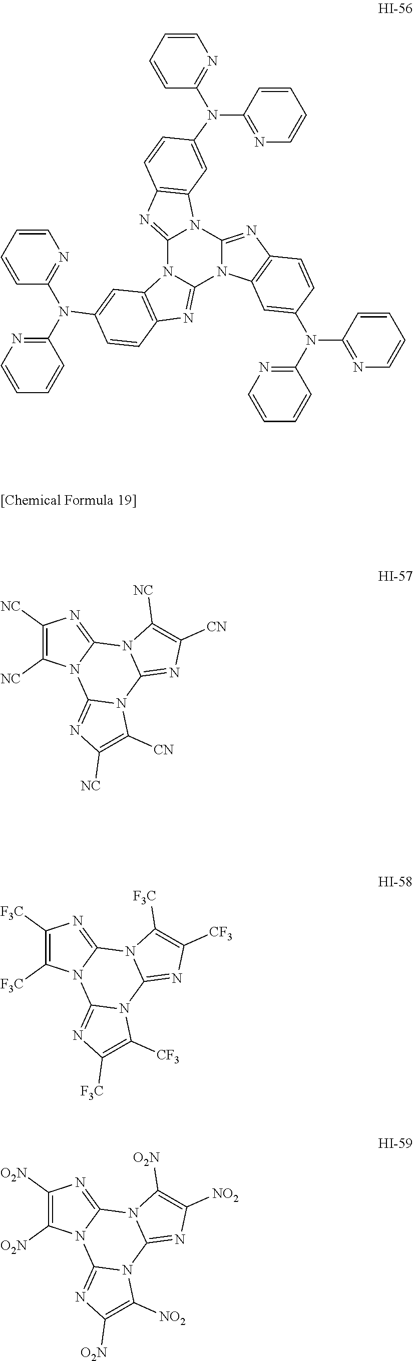

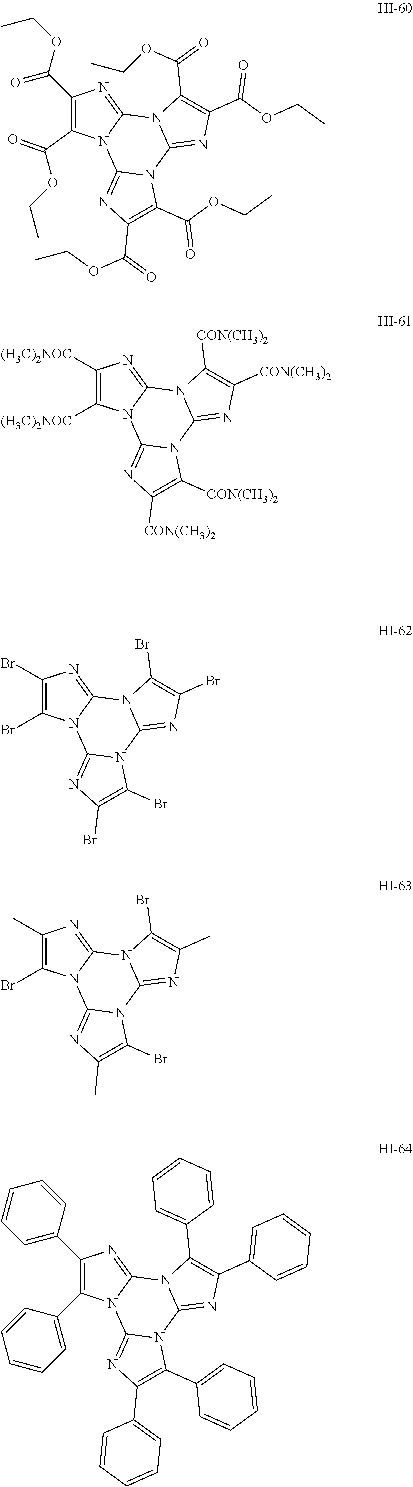

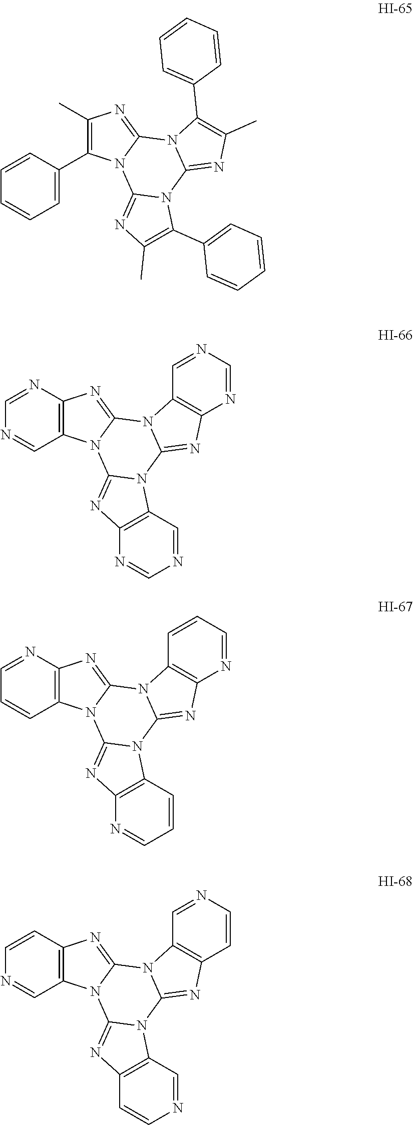

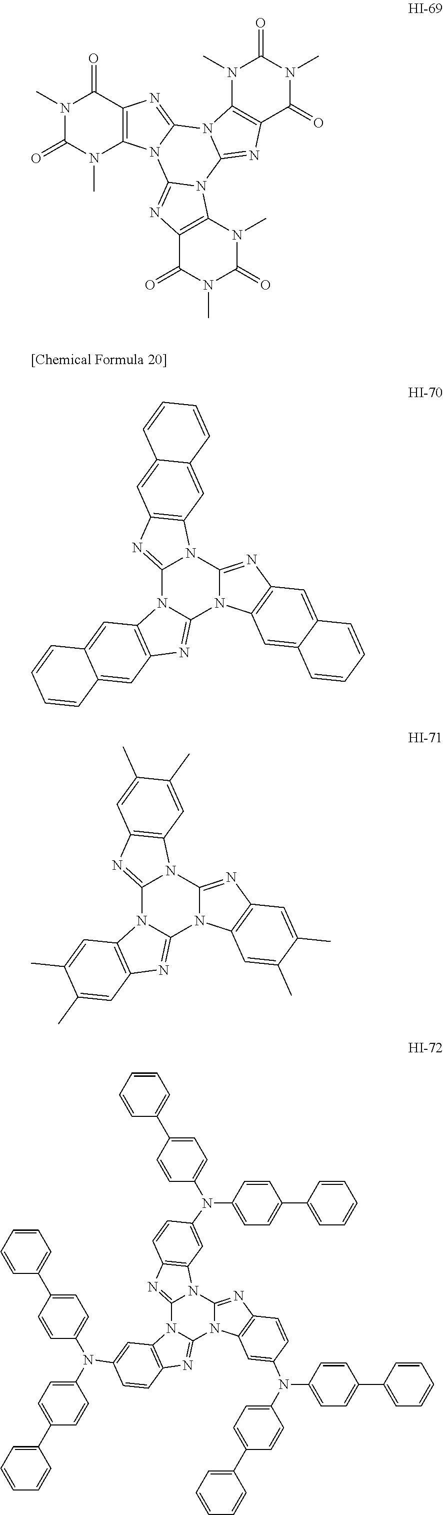

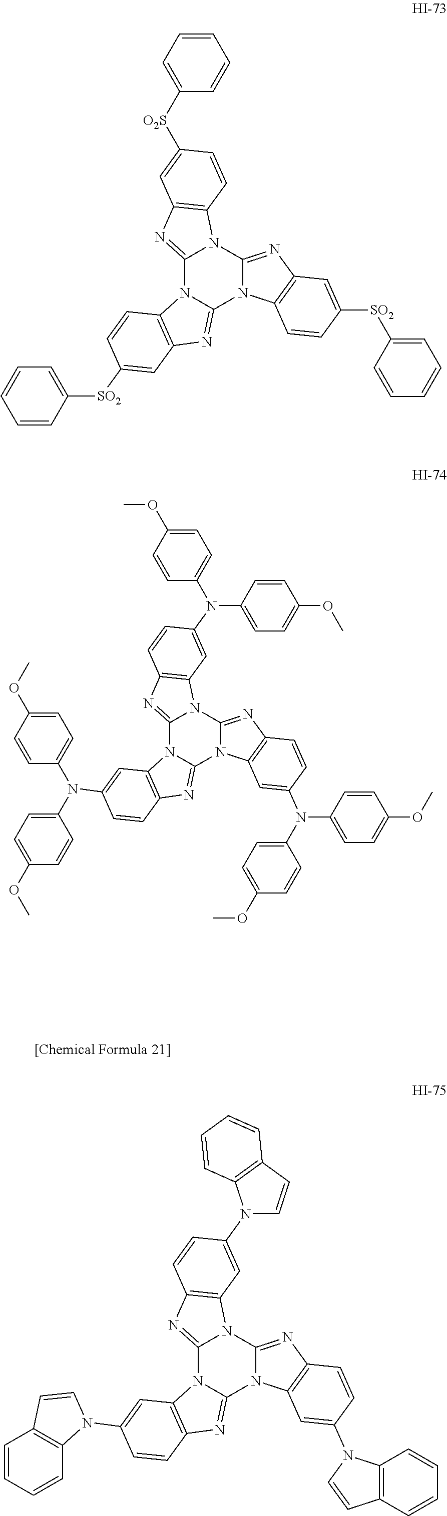

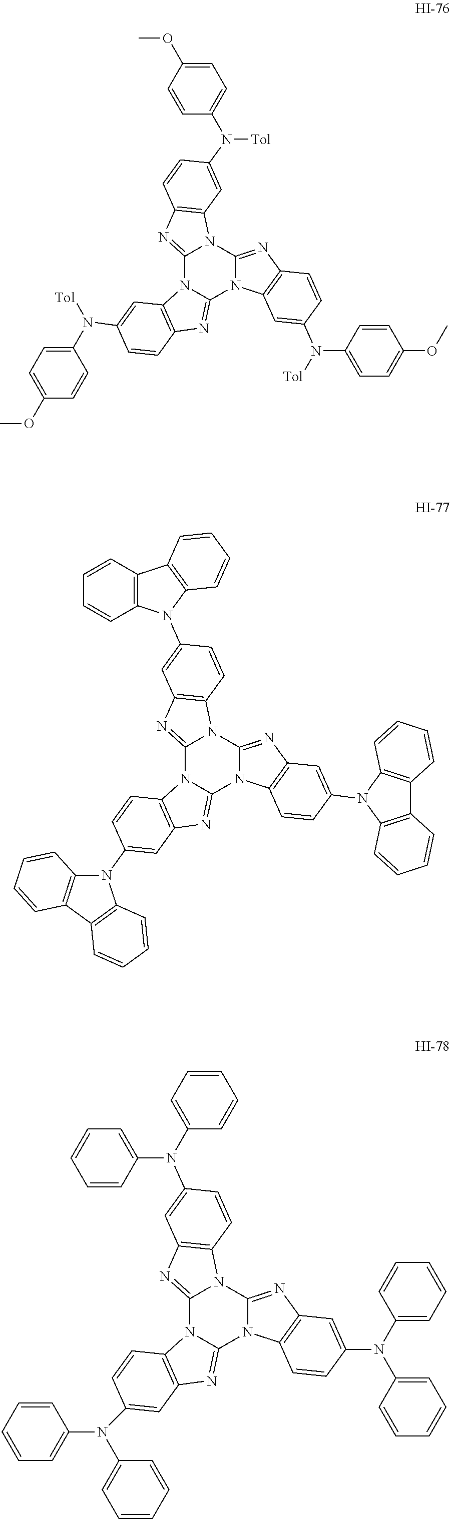

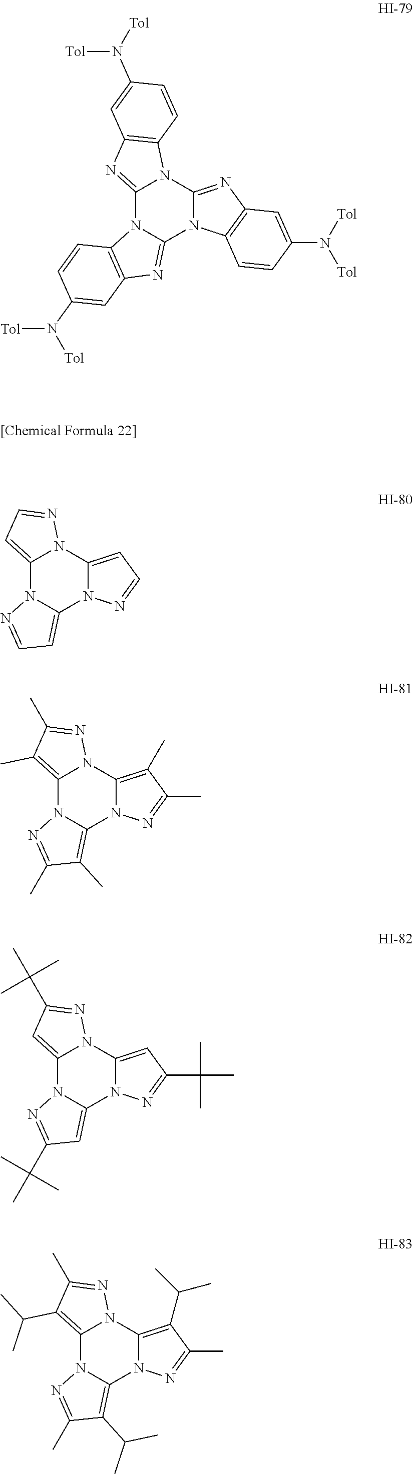

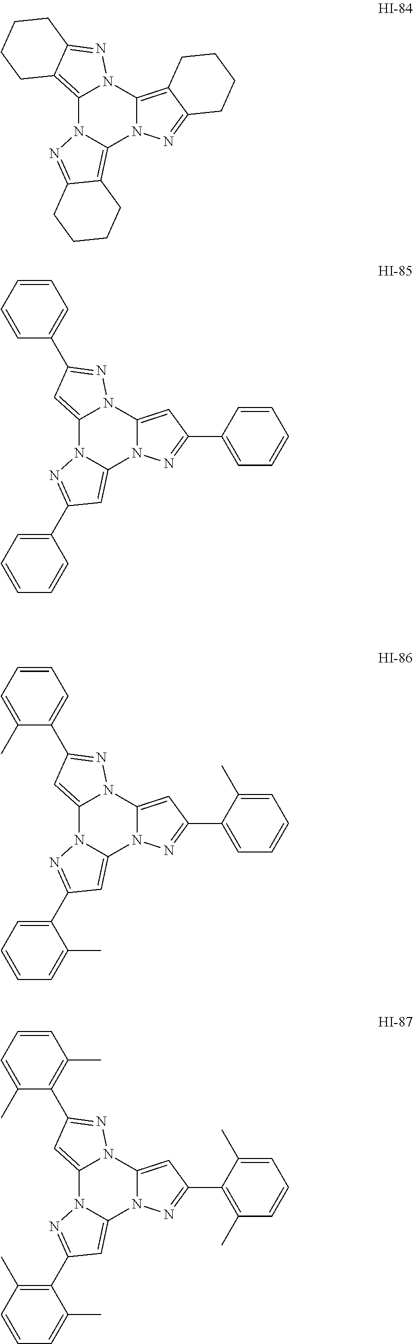

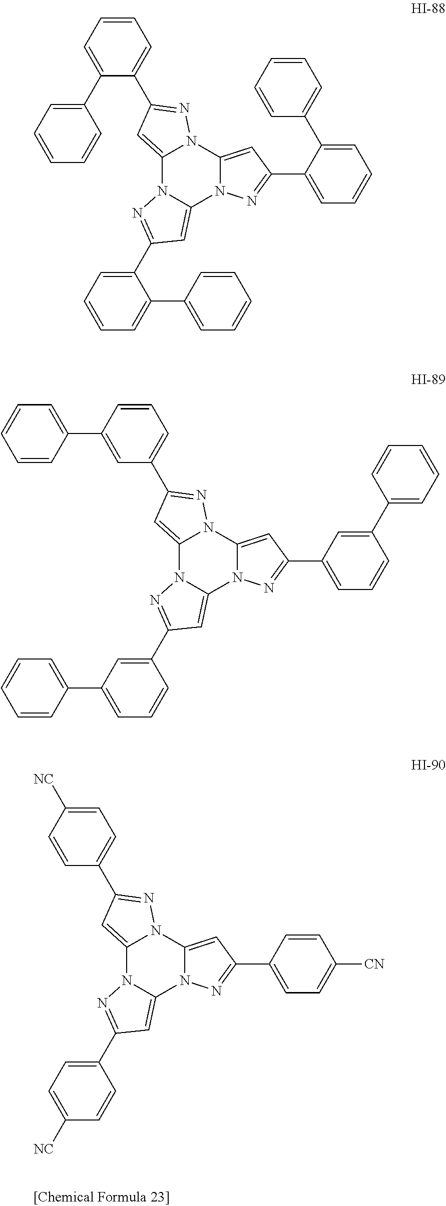

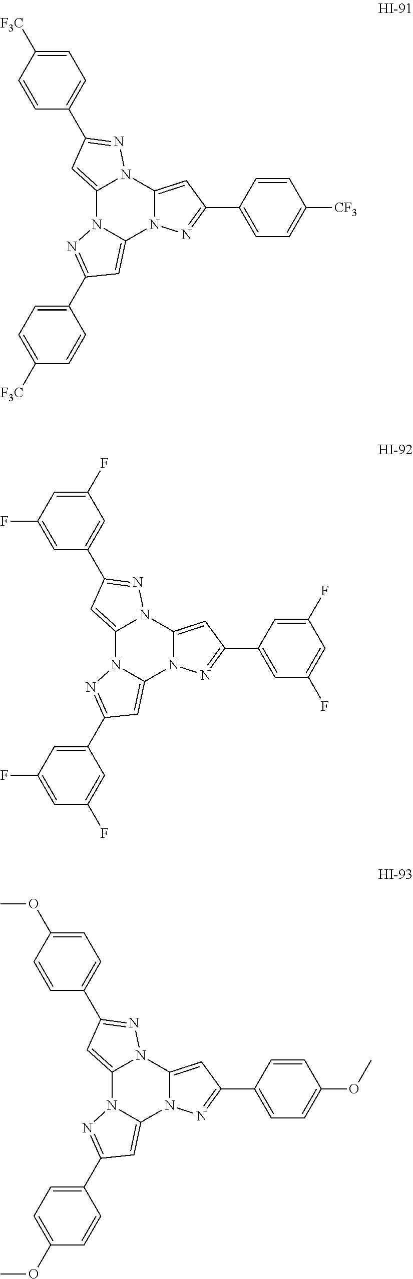

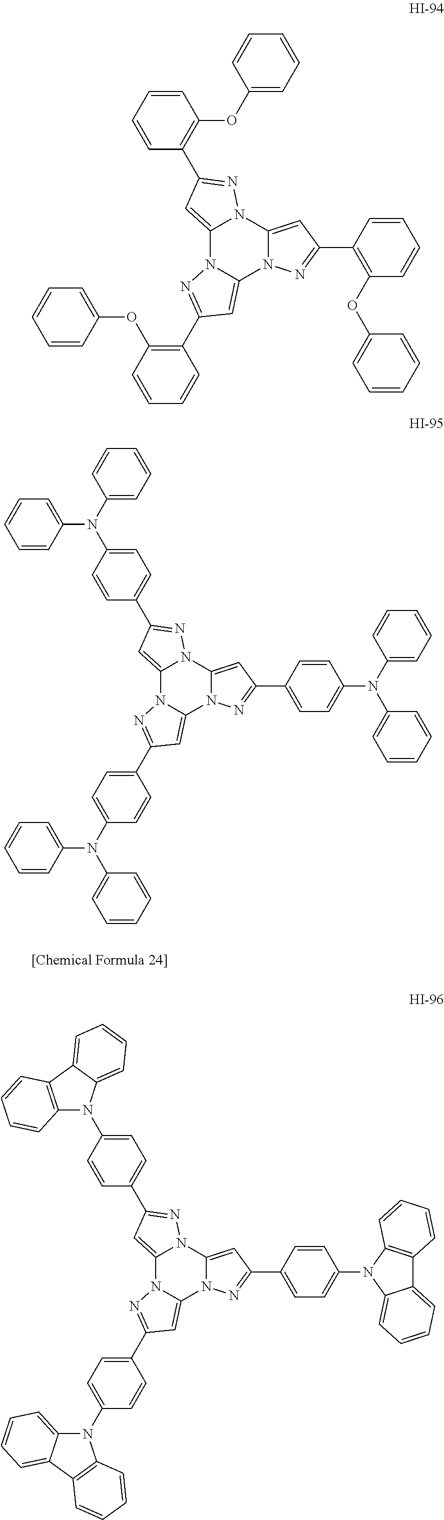

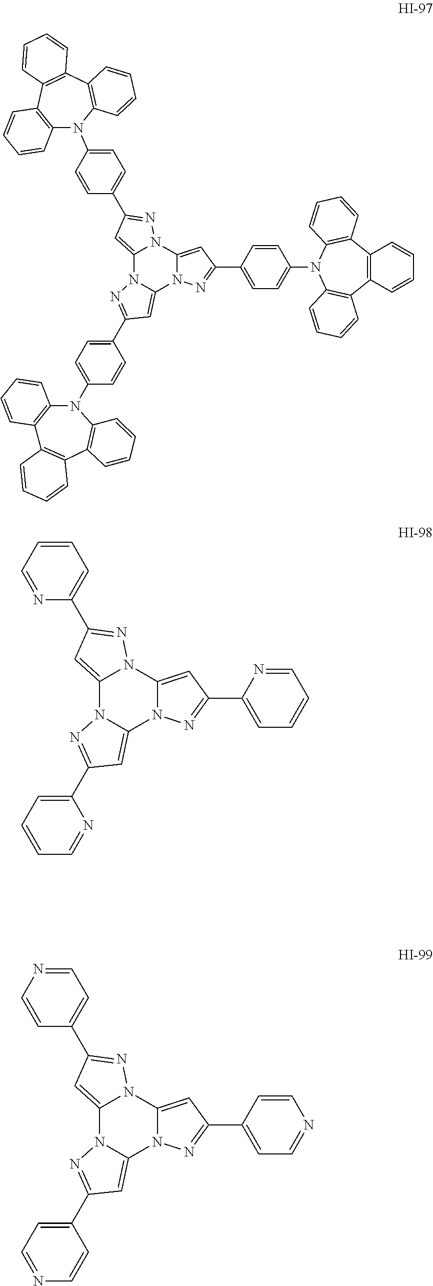

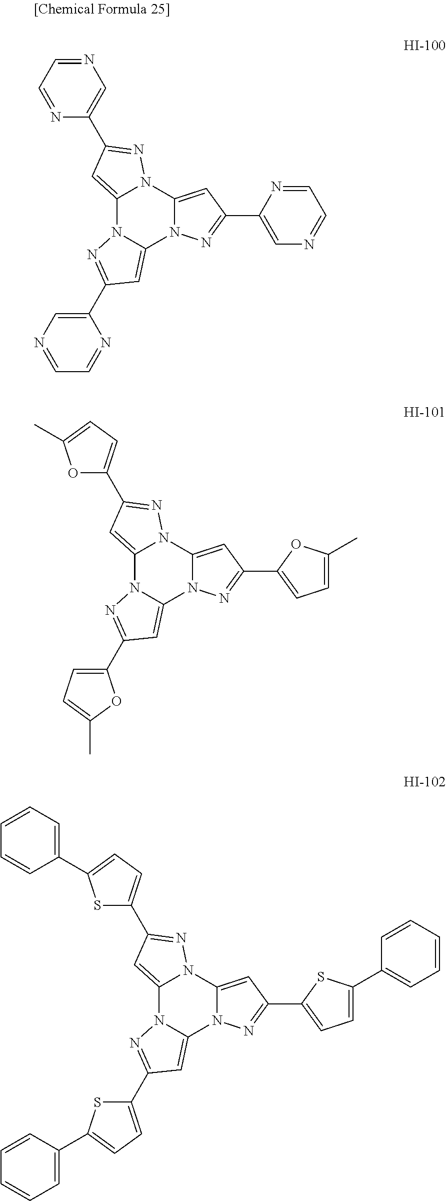

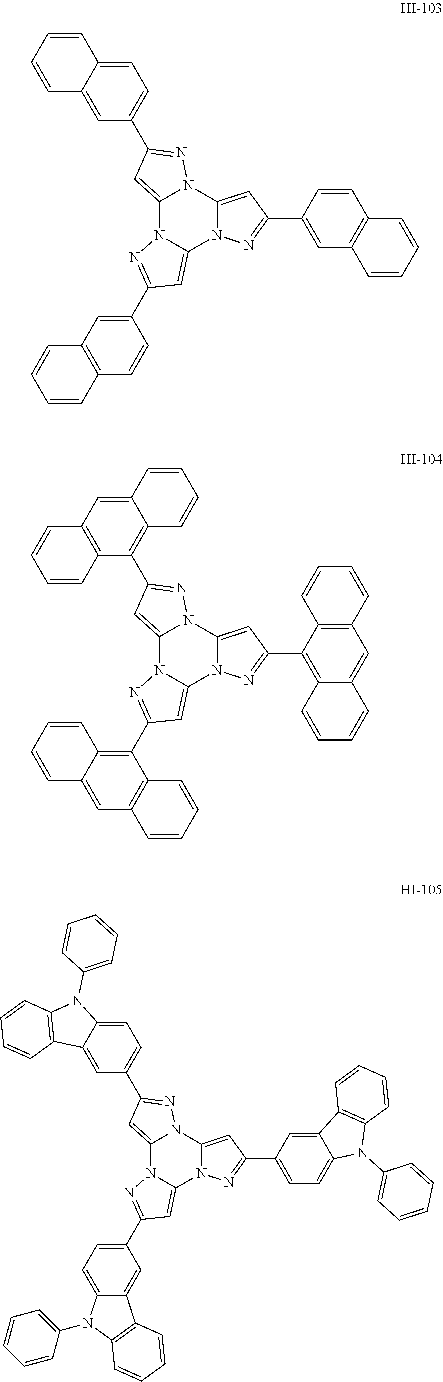

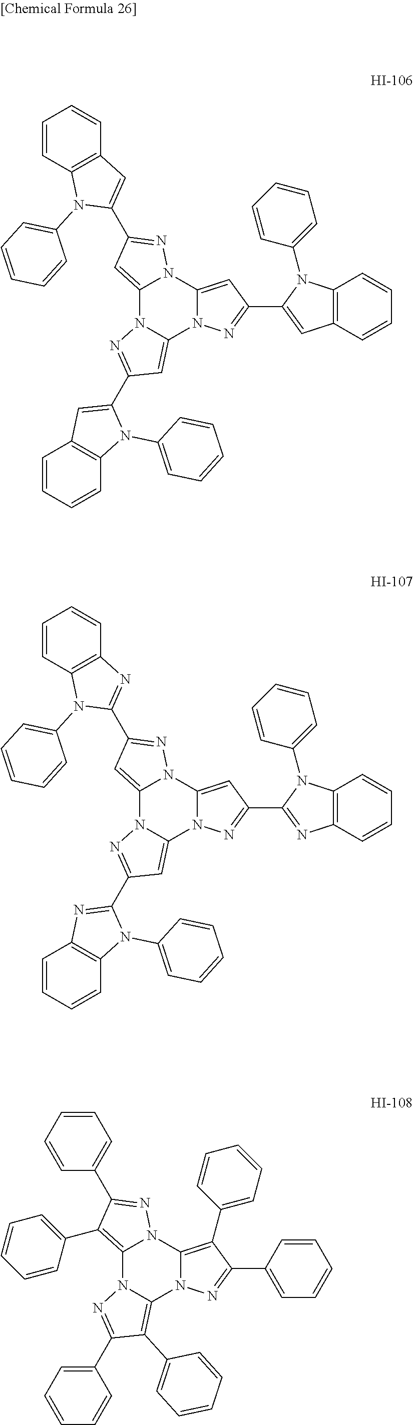

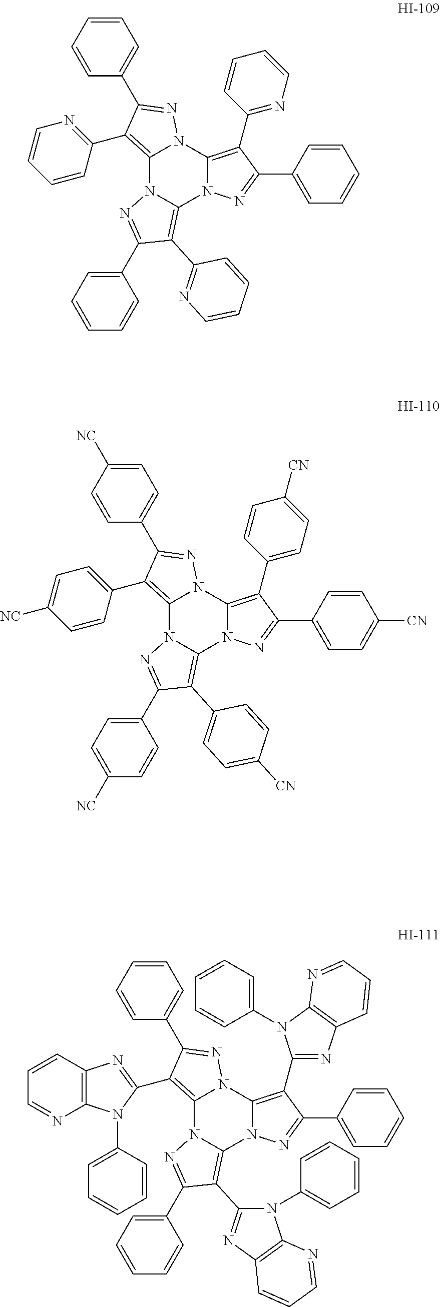

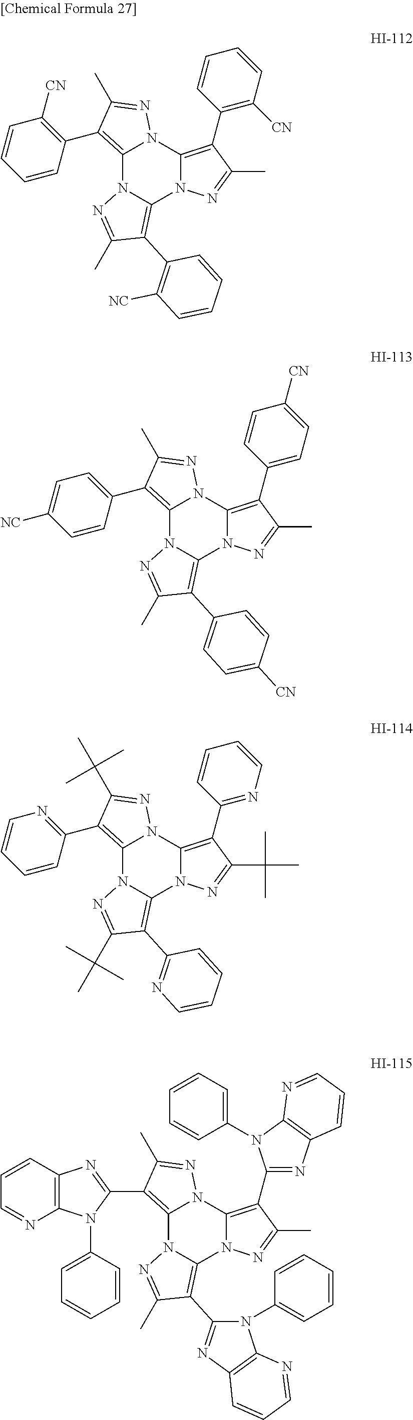

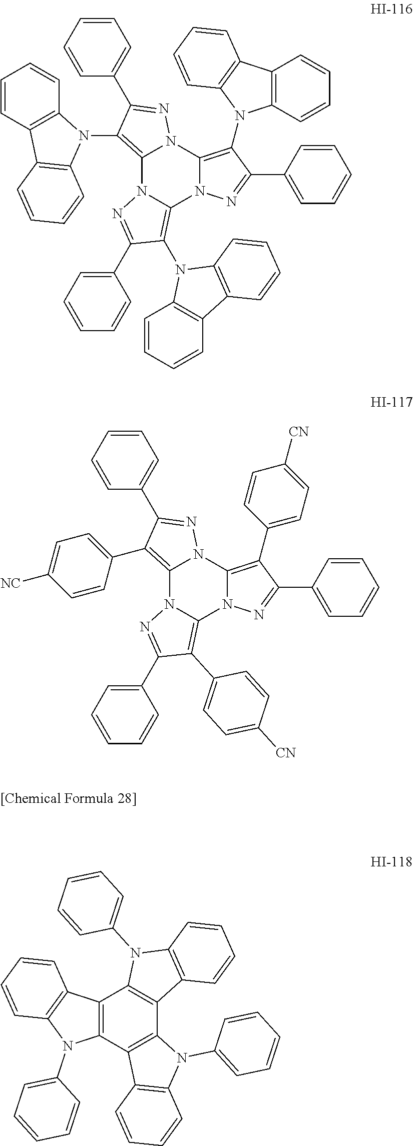

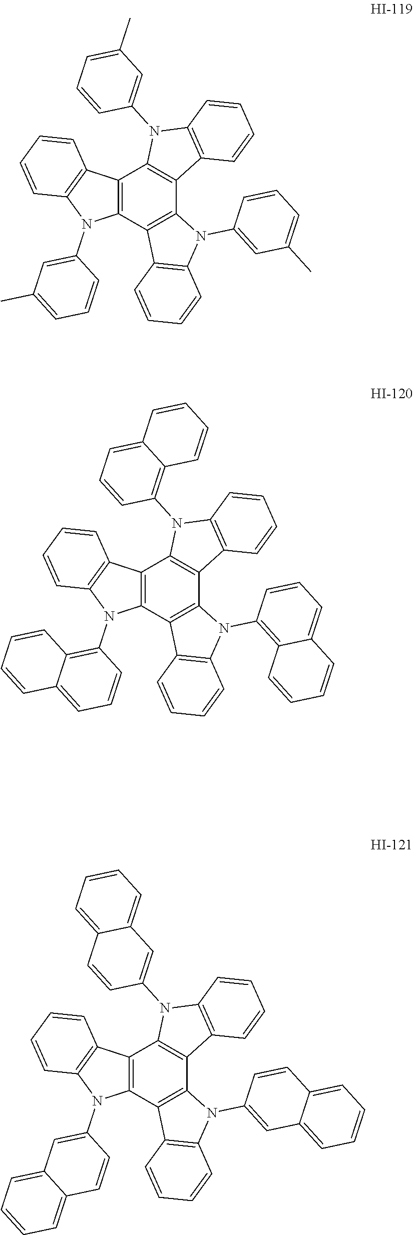

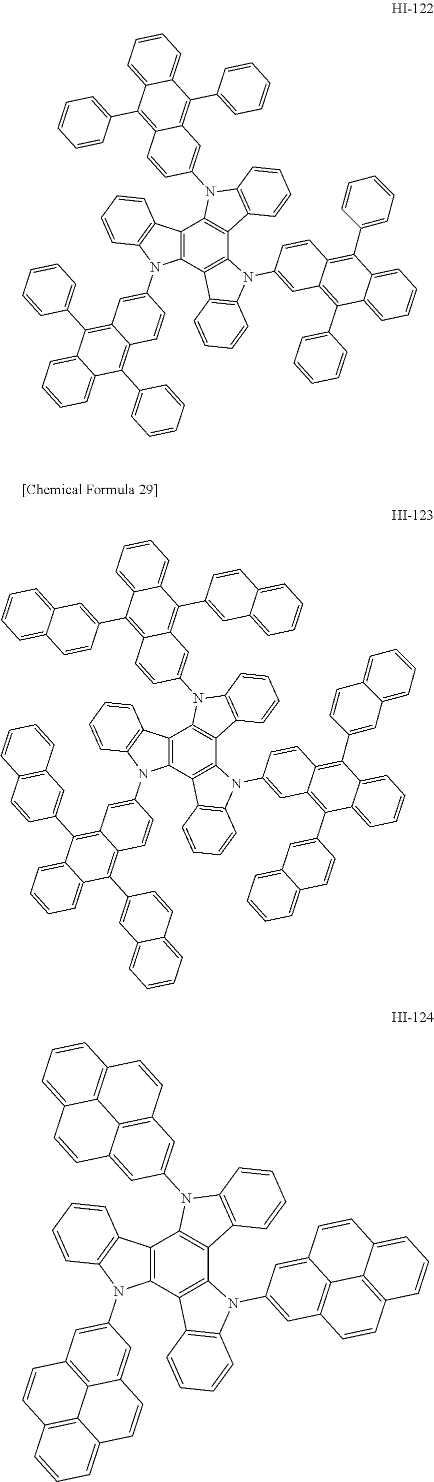

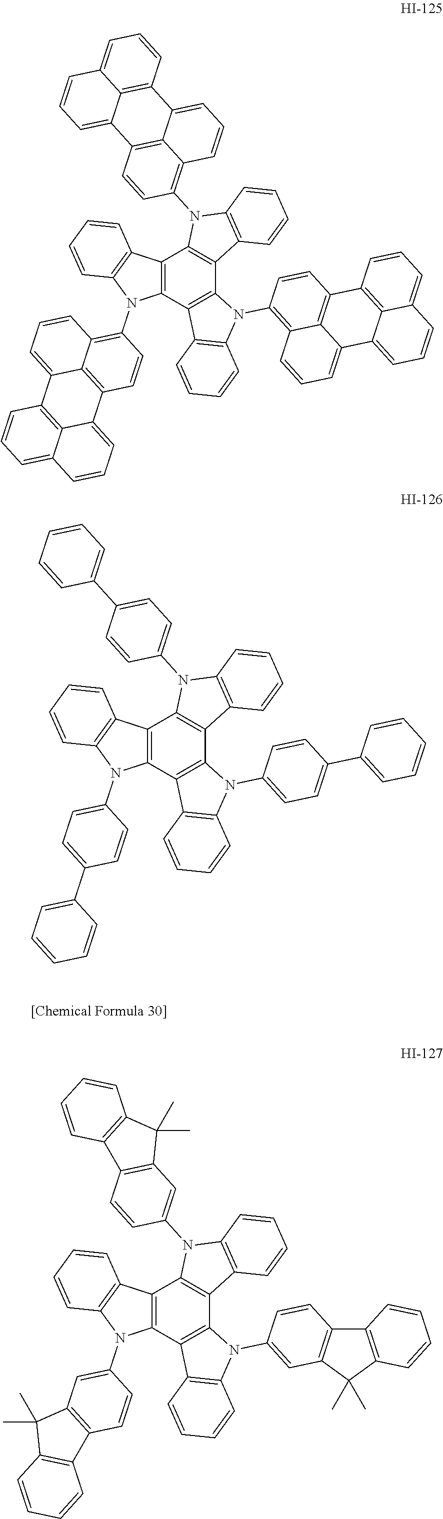

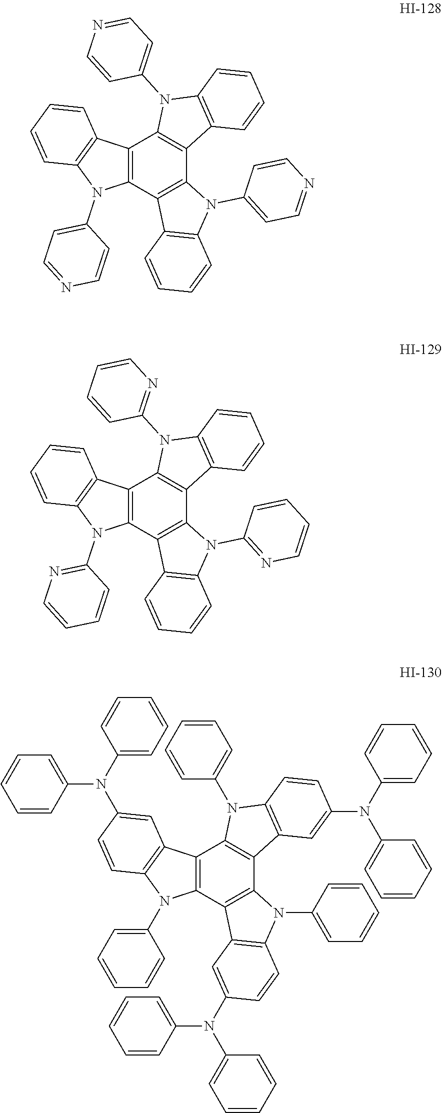

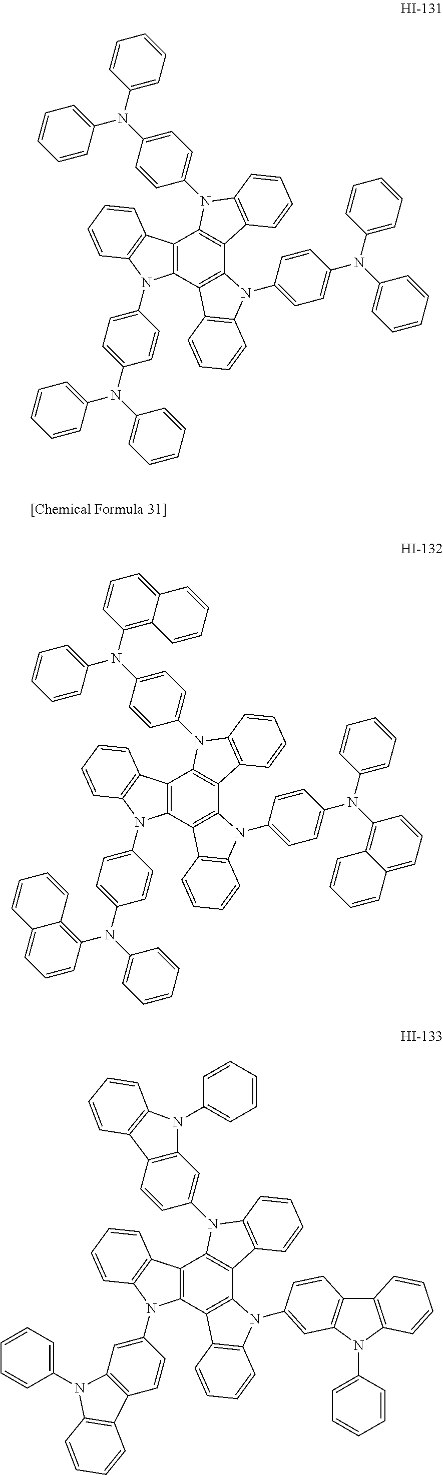

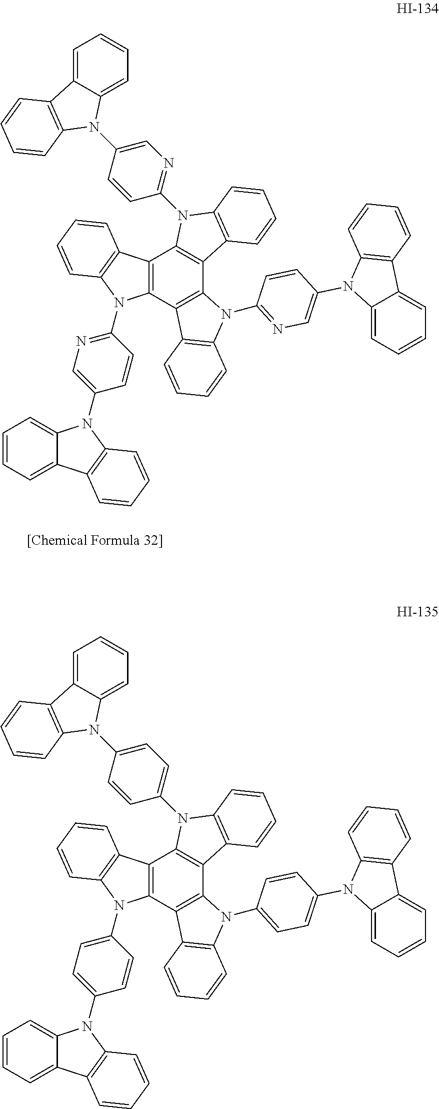

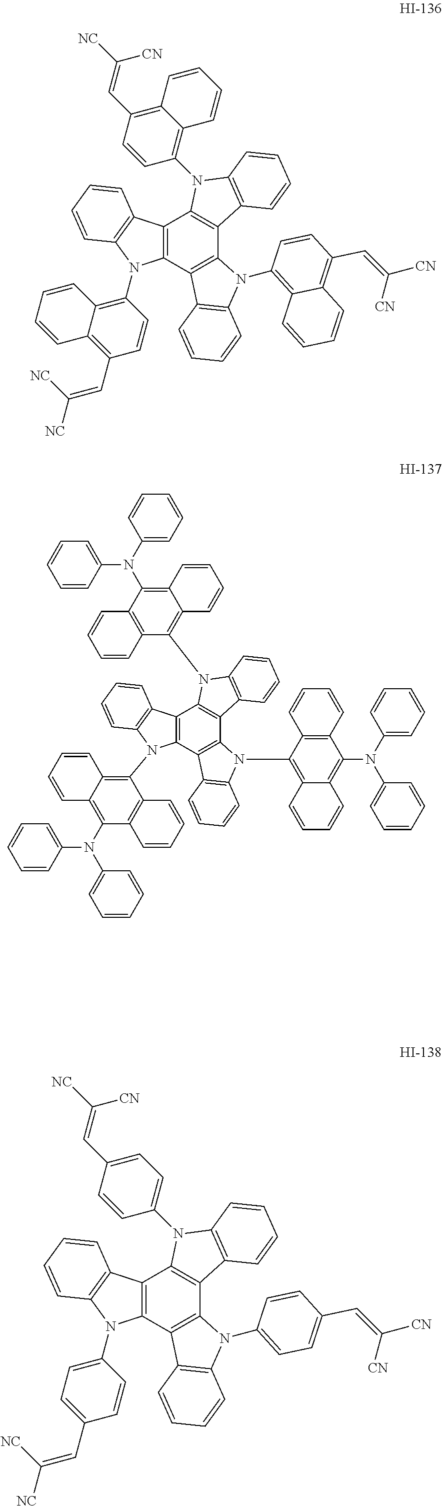

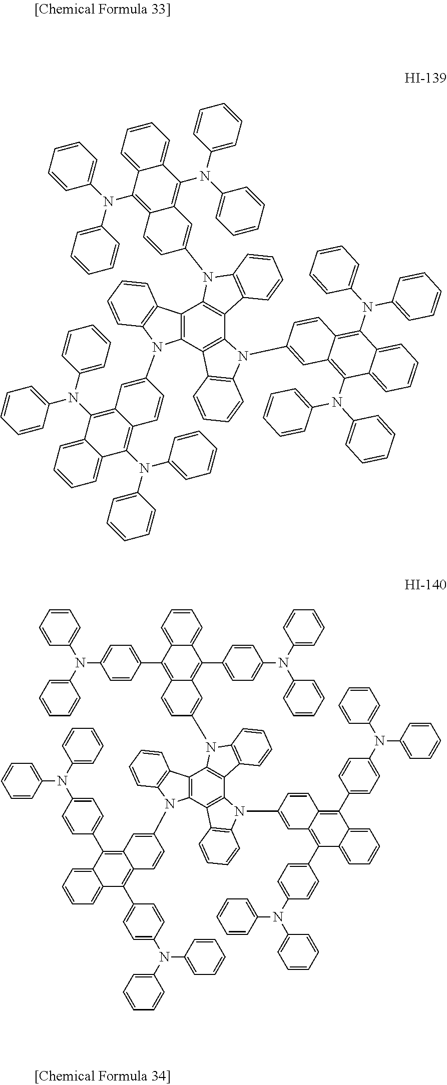

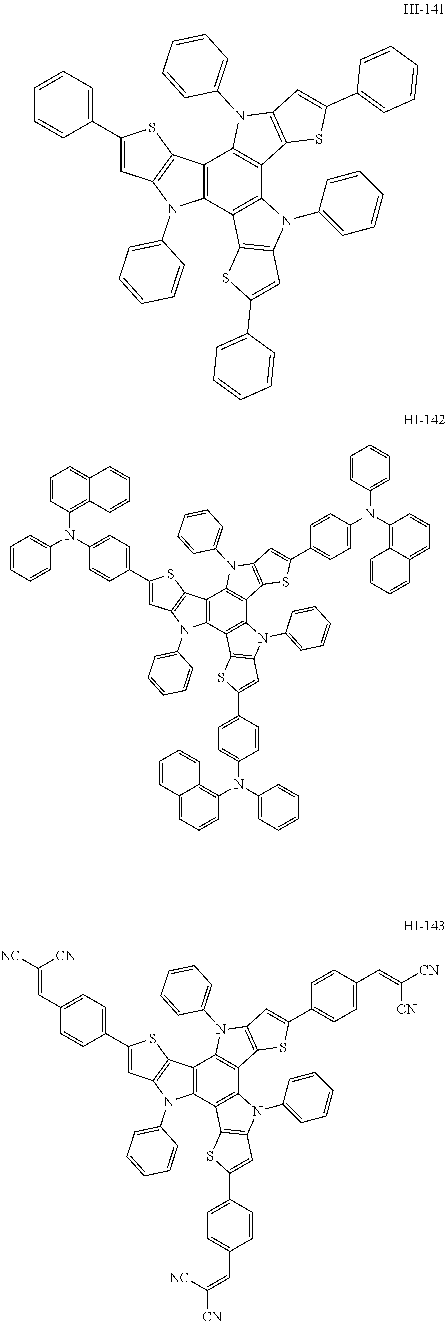

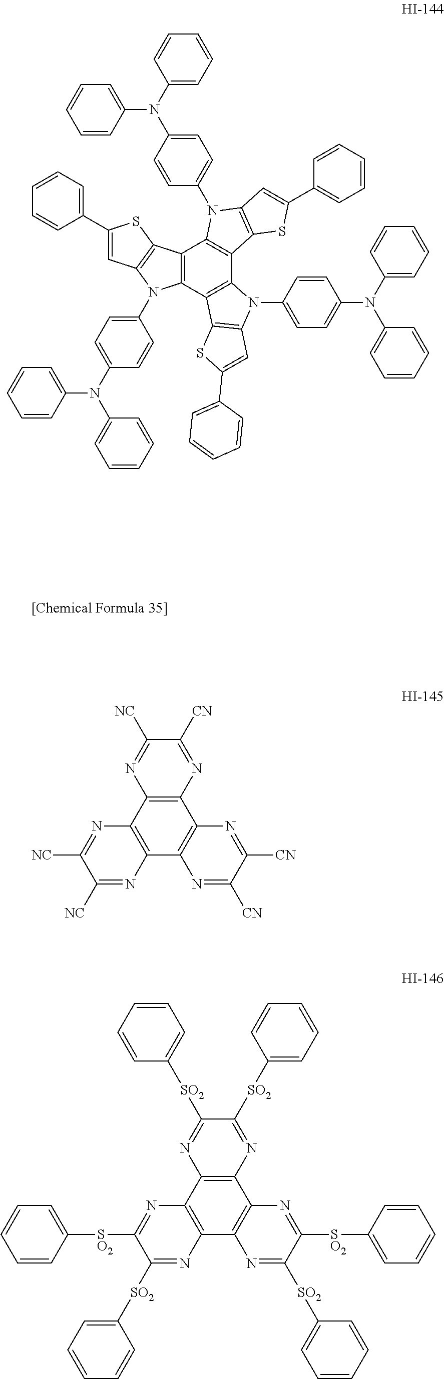

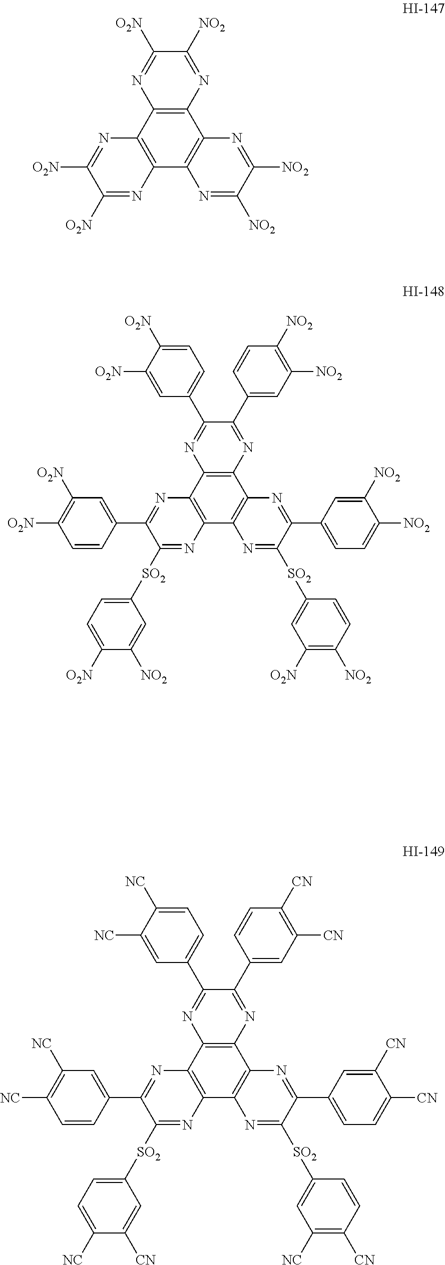

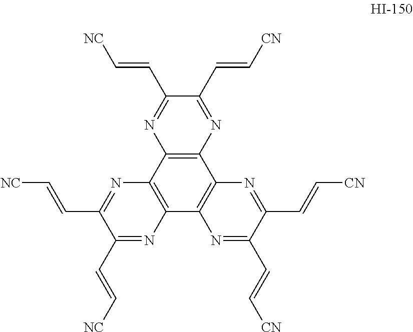

Other examples of the material used for the hole injection layer include the materials used for the hole transport layer that will be described below, for example. Among them, phthalocyanine derivatives represented by copper phthalocyanine; hexaazatriphenylene derivatives described in JP 2003-519432 A, JP 2006-135145 A, and the like; metal oxides represented by vanadium oxide; electrically conductive polymers such as amorphous carbon, polyaniline (emeraldine), and polythiophene; ortho-metalated complexes represented by a tris(2-phenylpyridine) iridium complex; triarylamine derivatives, and the like are preferred.

The above-mentioned materials used for the hole injection layer may be used singly, or multiple kinds may be used in combination; however, it is preferable that the hole injection layer according to the present invention is formed from a single kind of compound.

The layer thickness of the hole injection layer is preferably in the range of 1 to 15 nm, and more preferably in the range of 1 to 10 nm.

(Hole Transport Layer)

A hole transport layer is formed from a material having a function of transporting holes. A hole transport layer is a layer having a function of transferring the holes injected from the anode to the light emitting layer.

In regard to the organic EL element, the total layer thickness of the hole transport layer is not particularly limited; however, the total layer thickness is usually in the range of 5 nm to 5 μm, more preferably in the range of 2 to 500 nm, and even more preferably in the range of 5 to 200 nm.

The material used for the hole transport layer (hereinafter, referred to as hole transporting material) may have any one of hole injectability or transportability, and electron barrier properties. For the hole transporting material, any arbitrary material can be selected from conventionally known compounds and used. The hole transporting material may be used alone, or multiple kinds of materials may be used in combination.

Examples of the hole transporting material include a porphyrin derivative, a phthalocyanine derivative, an oxazole derivative, an oxadiazole derivative, a triazole derivative, an imidazole derivative, a pyrazoline derivative, a pyrazolone derivative, a phenylenediamine derivative, a hydrazone derivative, a stilbene derivative, a polyarylalkane derivative, a triarylamine derivative, a carbazole derivative, an indole carbazole derivative, an isoindole derivative, an acene-based derivative such as anthracene or naphthalene, a fluorene derivative, a fluorenone derivative, a polyvinylcarbazole derivative, a polymer material or oligomer having an aromatic amine introduced into the main chain or a side chain, a polysilane, and an electrically conductive polymer or oligomer (for example, PEDOT:PSS, an aniline-based copolymer, polyaniline, or polythiophene).

Examples of the triarylamine derivative include benzidine type compounds represented by α-NPD; starburst type compounds represented by MTDATA; and compounds having fluorene or anthracene in the triarylamine-linked core portion.

Furthermore, the hexaazatriphenylene derivatives described in JP 2003-519432 A, JP 2006-135145 A, and the like can also be used as the hole transporting material.

Furthermore, a hole transport layer having high p-type characteristics with doped impurities can also be used. For example, the configurations described in JP 4-297076 A, JP 2000-196140 A, JP 2001-102175 A, J. Appl. Phys., 95, 5773 (2004), and the like can also be applied to the hole transport layer.

Furthermore, the so-called p-type hole transporting materials, or inorganic compounds such as p-type Si and p-type SiC, as described in JP 11-251067 A, and Literature written by J. Huang et al. (Applied Physics Letters, 80 (2002), p. 139) can also be used. In addition, ortho-metalated organometallic complexes having Ir or Pt as the central metal, which are represented by Ir(ppy)₃, are also preferably used.

Regarding the hole transporting material, the materials described above can be used, and a triarylamine derivative, a carbazole derivative, an indole carbazole derivative, an azatriphenylene derivative, an organometallic complex, a polymer material or oligomer having an aromatic amine introduced into the main chain or a side chain, and the like are preferably used.

Specific examples of the hole transporting material include the compounds described in, in addition to Literatures mentioned above, Appl. Phys. Lett., 69, 2160 (1996); J. Lumin., 72-74, 985 (1997); Appl. Phys. Lett., 78, 673 (2001); Appl. Phys. Lett., 90, 183503 (2007); Appl. Phys. Lett., 90, 183503 (2007); Appl. Phys. Lett., 51, 913 (1987); Synth. Met., 87, 171 (1997); Synth. Met., 91, 209 (1997); Synth. Met., 111, 421 (2000); SID Symposium Digest, 37, 923 (2006); J. Mater. Chem., 3, 319 (1993); Adv. Mater., 6, 677 (1994); Chem. Mater., 15, 3148 (2003); US 2003/0,162,053 A1, US 2002/0,158,242 A1, US 2006/0,240,279 A, US 2008/0,220,265 A, U.S. Pat. No. 5,061,569, WO 2007/002683A, WO 2009/018009 A, EP 650955 B, US 2008/0,124,572 A, US 2007/0,278,938A, US 2008/0,106,190 A, US 2008/0,018,221 A, WO 2012/115034 A, JP 2003-519432 W, JP 2006-135145 A, and U.S. Ser. No. 13/585,981; however, examples of the hole transporting material are not limited to these.

(Electron Blocking Layer)

An electron blocking layer is a layer having the function of a hole transport layer in a broad sense. Preferably, the electron blocking layer is formed from a material having a function of transporting holes while having a low ability for transporting electrons. The probability for recombination of electrons and holes can be increased, as the electron blocking layer blocks electrons while transporting holes.

Furthermore, the configuration of the hole transport layer as described above can be used, if necessary, as the electron blocking layer for the organic EL element. It is preferable that the electron blocking layer provided in the organic EL element is provided to be adjacent to the anode side of the light emitting layer.

The layer thickness of the electron blocking layer is preferably in the range of 3 to 100 nm, and more preferably in the range of 5 to 30 nm.

Regarding the material used for the electron blocking layer, the above-mentioned materials used for the hole transport layer can be preferably used. Furthermore, the above-mentioned materials used as the host compound can also be preferably used for the electron blocking layer.

<Electron Injection/Transport Layer>

An electron injection/transport layer is configured to include, for example, an electron injection layer, an electron transport layer, or a hole blocking layer.

(Electron Transport Layer)

The electron transport layer used for the organic EL element is formed from a material having a function of transporting electrons, and has a function of transferring the electrons injected from the cathode to the light emitting layer.

The electron transporting material may be used singly, or multiple kinds of compounds may be used in combination.

The total thickness of the electron transport layer is not particularly limited; however, the total thickness is usually in the range of 2 nm to 5 μm, more preferably in the range of 2 to 500 nm, and even more preferably in the range of 5 to 200 nm.

In regard to the organic EL element, it is known that when the light generated in the light emitting layer is extracted, the light that is extracted directly from the light emitting layer through the anode, and the light that is extracted after being reflected at the cathode located as an opposite electrode of the anode, cause interference.

Therefore, it is preferable that in the organic EL element, the adjustment of the layer thickness of the light emitting layer is performed by appropriately adjusting the layer thicknesses of the hole transport layer and the electron transport layer to be between several nanometers (nm) and several micrometers (μm).

On the other hand, when the layer thickness of the electron transport layer is made large, voltage tends to increase. Therefore, particularly in a case in which the layer thickness is large, it is preferable that the electron mobility of the electron transport layer is 1×10⁻⁵ cm²/Vs or higher.

Regarding the material used for the electron transport layer (hereinafter, referred to as electron transporting material), it is desirable that the material has any one of electron injectability or transportability, or hole barrier properties, and any compound can be selected from conventionally known compounds and used. Examples thereof include a nitrogen-containing aromatic heterocyclic ring derivative, an aromatic hydrocarbon ring derivative, a dibenzofuran derivative, a dibenzothiophene derivative, and a silol derivative.

Examples of the nitrogen-containing aromatic heterocyclic derivative include a carbazole derivative, an azacarbazole derivative (a compound in which one or more carbon atoms that constitute a carbazole ring have been substituted by nitrogen atoms), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, and a benzothiazole derivative.

Examples of the aromatic hydrocarbon ring derivative include a naphthalene derivative, an anthracene derivative, and triphenylene.

Furthermore, metal complexes having a quinolinol skeleton or a dibenzoquinolinol skeleton in the ligand, for example, tris(8-quinolinol)aluminum (Alq3), tris(5, 7-dichloro-8-quinolinol)aluminum, tris(5, 7-dibromo-8-quinolinol)aluminum, tris(2-methyl-8-quinolinol)aluminum, tris(5-methyl-8-quinolinol)aluminum, and bis(8-quinolinol)zinc (Znq), as well as metal complexes in which the central metals of the above-mentioned metal complexes have been replaced with In, Mg, Cu, Ca, Sn, Ga or Pb, can also be used as the electron transporting material.

In addition, metal-free or metal phthalocyanines, or those compounds having their terminals substituted by alkyl groups, sulfonic acid groups or the like, can also be preferably used as the electron transporting materials. A distyrylpyrazine derivative used as a material for a light emitting layer can also be used as the electron transporting material, and similarly to the hole injection layer and the hole transport layer, inorganic semiconductors such as n-type Si and n-type SiC can also be used as the electron transporting materials.

Furthermore, polymer materials having these materials introduced into the polymer chain, or polymer materials in which these materials are used as the main chain of the polymer may also be used.

In the organic EL element, an electron transport layer having high n-type characteristics (electron-rich) may be formed by doping a dopant material as a guest material into the electron transport layer. Examples of the dopant material include metal compounds such as metal complexes and metal halides; and other n-type dopants. Specific examples of an electron transport layer having such a configuration include, for example, the electron transport layers described in JP 4-297076 A, JP 10-270172 A, JP 2000-196140 A, JP 2001-102175 A, and J. Appl. Phys., 95, 5773 (2004).

Specific examples of known preferred electron transporting material include the compounds described in U.S. Pat. No. 6,528,187, U.S. Pat. No. 7,230,107, US 2005/0,025,993 A1, US 2004/0,036,077 A1, US 2009/0,115,316 A1, US 2009/0,101,870 A1, US 2009/0,179,554 A1, WO 2003/060956 A, WO 2008/132085 A; Appl. Phys. Lett., 75, 4 (1999); Appl. Phys. Lett., 79, 449 (2001); Appl. Phys. Lett., 81, 162 (2002); Appl. Phys. Lett., 81, 162 (2002); Appl. Phys. Lett., 79, 156 (2001); U.S. Pat. No. 7,964,293, US 2009/030202, WO 2004/080975 A, WO 2004/063159 A, WO 2005/085387 A, WO 2006/067931 A, WO 2007/086552 A, WO 2008/114690 A, WO 2009/069442 A, WO 2009/066779 A, WO 2009/054253 A, WO 2011/086935 A, WO 2010/150593 A, WO 2010/047707 A, EP 2311826 B, JP 2010-251675 A, JP 2009-209133 A, JP 2009-124114 A, JP 2008-277810A, JP 2006-156445 A, JP 2005-340122 A, JP 2003-45662 A, JP 2003-31367 A, JP 2003-282270 A, and WO 2012/115034 A. However, the examples are not limited to these.

More preferred examples of the electron transporting material include a pyridine derivative, a pyrimidine derivative, a pyrazine derivative, a triazine derivative, a dibenzofuran derivative, a dibenzothiophene derivative, a carbazole derivative, an azacarbazole derivative, and a benzimidazole derivative.

(Hole Blocking Layer)

A hole blocking layer is a layer having the function of the electron transport layer in abroad sense. Preferably, the hole blocking layer is formed from a material having a function of transporting electrons while having a low ability of transporting holes. The probability for recombination of electrons and holes can be increased, as the hole blocking layer blocks holes while transporting electrons.

It is more effective if the hole blocking layer has the function as a layer that blocks triplet energy.

Furthermore, the configuration of the hole transport layer as described above can be used, if necessary, as the hole blocking layer.

It is preferable that the hole blocking layer provided in the organic EL element is provided to be adjacent to the cathode side of the light emitting layer.

In regard to the organic EL element, the layer thickness of the hole blocking layer is preferably in the range of 3 to 100 nm, and more preferably in the range of 5 to 30 nm.

Regarding the material used for the hole blocking layer, the above-mentioned materials used for the electron transport layer are preferably used, and the above-mentioned materials used for the host compound are also preferably used for the hole blocking layer.

(Electron Injection Layer)

An electron injection layer (also referred to as “cathode buffer layer”) is a layer provided between the cathode and the light emitting layer for the purpose of decreasing the driving voltage or increasing the emission luminance. An example of the electron injection layer is described in “Organic EL elements and Frontiers of Industrialization Thereof (published on Nov. 30, 1998, by NTS Publishing, Ltd.)”, Vol. 2, Chapter 2, “Electrode Materials” (pp. 123-166).

In the organic EL element, the electron injection layer is provided as necessary, and as described above, the electron injection layer is provided between the cathode and the light emitting layer, or between the cathode and the electron transport layer.

It is preferable that the electron injection layer is a very thin film, and although the layer thickness may vary depending on the material, the layer thickness is preferably in the range of 0.1 to 5 nm. Furthermore, the electron injection layer may also be a non-uniform film in which the constituting material exists intermittently.

The electron injection layer is also described in detail in JP 6-325871 A, JP 9-17574 A, JP 10-74586 A, and the like. Specific examples of the material that is preferably used for the electron injection layer include metals represented by strontium and aluminum; alkali metal compound represented by lithium fluoride, sodium fluoride, potassium fluoride and the like; alkaline earth metal compounds represented by magnesium fluoride and calcium fluoride; metal oxides represented by aluminum oxide; and metal complexes represented by lithium 8-hydroxyquinolate (Liq) and the like. It is also possible to use the electron transporting materials mentioned above.

Furthermore, the material used for the electron injection layer may be used singly, or multiple kinds of materials may be used in combination.

<Other Additives>

The various light emitting layers constituting the organic EL element may further include other additives.

Example of the additives include halogen elements such as bromine, iodine and chlorine, or halide compounds; alkali metals or alkaline earth metals, such as Pd, Ca, and Na; and compounds, complexes, and salts of transition metals.

The content of the additives may be arbitrarily determined; however, the content is preferably 1,000 ppm or less, more preferably 500 ppm or less, and even more preferably 50 ppm or less, with respect to the total mass % of the layer in which the additives are included.

However, depending on the purpose of enhancing the transportability for electrons or holes, or the purpose for facilitating the energy movement of excitons, the content is not fixed to this range.

<Anode>

Regarding the anode for the organic EL element, an electrode material formed from a metal, an alloy, an electrically conductive compound, or a mixture thereof, all of which have high work functions (4 eV or higher, and preferably 4.3 eV or higher), is used. Specific examples of such an electrode material include metals such as Au and Ag, and alloys thereof; and conductive transparent materials such as CuI, indium tin oxide (ITO), SnO₂, and ZnO. Furthermore, amorphous materials with which transparent conductive films can be produced, such as IDIXO (In₂O₃—ZnO), may also be used.

In regard to the anode, a thin film of an electrode material is formed using methods such as vapor deposition or sputtering, and a pattern having a desired shape may be formed by a photolithographic method. Furthermore, in a case in which pattern precision is not much needed (about 100 μm or higher), the pattern may be formed by means of a mask having a desired shape at the time of vapor deposition or sputtering of the electrode material described above.

In the case of using a material that can be coated, such as an organic electroconductive compound, a wet film-forming method such as a printing system or a coating system can also be used.

In a case in which the luminescent light is extracted through the anode side, it is desirable to adjust the transmittance to be higher than 10%. Furthermore, the sheet resistance as the anode is preferably several hundred Ω/sq. or less. The thickness of the anode may vary depending on the material; however, the thickness is usually selected to be in the range of 10 nm to 1 μm, and preferably in the range of 10 to 200 nm.

<Cathode>

Regarding the cathode, an electrode material formed from a metal (referred to as electron injectable metal), an alloy, an electrically conductive compound, or a mixture thereof, all of which have low work functions (4 eV or lower), is used. Specific examples of such an electrode material include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, silver, an alloy containing silver as a main component, an aluminum/silver mixture, and rare earth metals.

The cathode can be produced using methods such as vapor deposition or sputtering of the electrode material described above. The sheet resistance of the cathode is preferably several hundred Q/sq. or less. Furthermore, the thickness of the cathode is usually selected to be in the range of 10 nm to 5 μm, and preferably in the range of 50 to 200 nm.

<Substrate>

Regarding the substrate used for the organic EL element, there are no particular limitations on the type of glass, plastics or the like, and the substrate may be transparent or opaque. In a case in which light is extracted through the substrate side, it is preferable that the substrate is transparent.

Preferred examples of a transparent substrate include glass, quartz, and a transparent resin film. A particularly preferred example is a resin film capable of imparting flexibility to the organic EL element.

Examples of the resin film include films of polyesters such as polyethylene terephthalate (PET) and polyethylene naphthalate (PEN); polyethylene, polypropylene; cellulose esters such as Cellophane, cellulose diacetate, cellulose triacetate (TAC), cellulose acetate butyrate, cellulose acetate propionate (CAP), cellulose acetate phthalate, and cellulose nitrate, or derivatives thereof; polyvinylidene chloride, polyvinyl alcohol, polyethylene vinyl alcohol, syndiotactic polystyrene, polycarbonate, norbornene resins, polymethylpentene, polyether ketone, polyimide, polyether sulfone (PES), polyphenylene sulfide, polysulfones, polyetherimide, polyether ketone imide, polyamide, fluororesins, nylon, polymethyl methacrylate, acrylics or polyallylates, and cycloolefin-based resins such as ARTON (trade name, manufactured by JSR Corp.) or APEL (trade name, manufactured by Mitsui Chemicals, Inc.

On the surface of the resin film, a gas barrier membrane based on a coating film of an inorganic substance or an organic substance, a hybrid coating film of the two substances, or the like may be formed. The gas barrier membrane is preferably a film having gas barrier properties with a water vapor permeability (25±0.5° C., relative humidity (90±2)% RH)) of 0.01 g/(m²·24 h) or less as measured by the method according to JIS K 7129-1992. Furthermore, the gas barrier membrane is preferably a film having high gas barrier properties with an oxygen permeability of 1×10⁻³ ml/(m²·24 h·atm) or less as measured by the method according to JIS K 7126-1987 and a water vapor permeability of 1×10⁻⁵ g/(m²·24 h) or less.

The material that forms the gas barrier membrane may be any material having a function of suppressing the infiltration of any substance that causes deterioration of the element, such as moisture or oxygen. For example, silicon oxide, silicon dioxide, silicon nitride, or the like can be used. Furthermore, in order to ameliorate brittleness of the gas barrier membrane, it is more preferable to produce the gas barrier membrane to have a laminated structure of inorganic layers of those substances and layers formed from organic materials. There are no particular limitations on the order of lamination of inorganic layers and organic layers; however, it is preferable to alternately laminate the two several times.

The method for forming the gas barrier membrane is not particularly limited, and for example, a vacuum deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a laser CVD method, a thermal CVD method, or a coating method can be used. For example, it is preferable to follow the atmospheric pressure plasma polymerization method described in JP 2004-68143 A.

Examples of an opaque supporting substrate include metal plates or films of aluminum, stainless steel and the like; opaque resin substrates, and substrates made of ceramics.

<Encapsulation>

Regarding the means for encapsulation used for encapsulation of the organic EL element, for example, a method of adhering an encapsulating member, the electrodes, and the substrate with an adhesive.

It is desirable that the encapsulating member is disposed so as to cover the display region of the organic EL element, and the encapsulating member may have a recessed plate shape, or a flat plate shape. Furthermore, there are no particular limitations on the transparency and the electrical insulation properties.

Specific examples include a glass plate, a polymer plate, a polymer film, a metal plate/film.

Particularly, examples of the glass plate include plates of soda-lime glass, barium/strontium-containing glass, lead glass, aluminosilicate glass, borosilicate glass, barium borosilicate glass, and quartz.

Examples of the polymer plate and polymer film include plates and films of polycarbonate, acrylics, polyethylene terephthalate, polyether sulfide, and polysulfone.

Examples of the metal plate include plates of metals including one or more selected from the group consisting of stainless steel, iron, copper, aluminum, magnesium, nickel, zinc, chromium, titanium, molybdenum, silicon, germanium and tantalum, and alloys.

Since the organic EL element can be made into a thin film, a polymer film or a metal film can be preferably used. It is preferable that the polymer film has an oxygen permeability of 1×10⁻³ ml/(m²·24 h·atm) or less, and a water vapor permeability of 1×10⁻³ g/(m²·24 h) or less. It is more preferable that the polymer film has a water vapor permeability of 1×10⁻⁵ g/(m²·24 h) or less and an oxygen permeability of 1×10⁻⁵ ml/(m²·24 h·atm) or less.

In order to process the encapsulating member into a recessed shape, sand blast processing, chemical etching processing and the like are used. Specific examples of the adhesive include photocurable and thermosetting type adhesives having the reactive vinyl groups of acrylic acid-based oligomers and methacrylic acid-based oligomers; and moisture-curable type adhesives such as 2-cyanoacrylic acid esters. Further examples include thermally and chemically curable type adhesives (mixture of two liquids), such as an epoxy-based adhesive. Further examples include hot melt type polyamide, polyester and polyolefin adhesives. Other examples include cationically curable type ultraviolet-curable epoxy resin adhesives.

Meanwhile, since there are occasions in which the organic EL element is deteriorated by a heat treatment, it is preferable that an adhesive capable of adhering and curing at a temperature of from room temperature (25° C.) to 80° C. Furthermore, a desiccant may be dispersed in the adhesive. Application of the adhesive on the encapsulation part may be performed using a commercially available dispenser, or may be printed as in the case of screen printing.

In the gap between the encapsulating member and the display region of the organic EL element, it is preferable to inject, in the gas phase and the liquid phase, an inert gas such as nitrogen or argon, or an inert liquid such as a fluorinated hydrocarbon or a silicone oil. It is also possible to make a vacuum. It is also possible to enclose a hygroscopic compound inside the gap.

Examples of the hygroscopic compound include metal oxides (for example, sodium oxide, potassium oxide, calcium oxide, barium oxide, magnesium oxide, and aluminum oxide), sulfuric acid salts (for example, sodium sulfate, calcium sulfate, magnesium sulfate, and cobalt sulfate), metal halides (for example, calcium chloride, magnesium chloride, cesium fluoride, tantalum fluoride, cerium bromide, magnesium bromide, barium iodide, and magnesium iodide), and perchloric acids (for example, barium perchlorate and magnesium perchlorate). In regard to the sulfuric acid salts, metal halides and perchloric acids, anhydrous salts are suitably used.

<Protective Film and Protective Plate>

In order to increase the mechanical strength of the organic EL element, a protective film or a protective plate may be provided on the outer side of the encapsulating film. Particularly, in a case in which encapsulation is achieved by means of the encapsulating film, since the mechanical strength of the encapsulating film is not necessarily high, it is preferable to provide such a protective film or a protective plate. Regarding the material that can be used for this, a glass plate, a polymer plate or film, a metal plate or film, or the like, all of these being the same as those used for encapsulation as described above, can be used. However, from the viewpoint of achieving a light weight and thickness reduction, it is preferable to use a polymer film.

<Light Extraction Enhancing Technology>

It is generally said that in an organic EL element, light is emitted in the interior of a layer having a higher refractive index than air (refractive index in the range of about 1.6 to 2.1), and only about 15% to 20% of light from the light generated in the light emitting layer can be extracted. This is because the light incident to the interface (interface between a transparent substrate and air) at an angle θ equal to or larger than the critical angle, undergoes total reflection and cannot be extracted to the outside of the element; however, light undergoes total reflection between a transparent electrode or a light emitting layer and a transparent substrate, the light is transmitted through the transparent electrode or the light emitting layer, and consequently, the light escapes in the lateral directions of the element.

Regarding the technique for increasing the efficiency of this light extraction, for example, a method of forming surface unevenness on a transparent substrate surface, and preventing total reflection at the interface between the transparent substrate and air (for example, U.S. Pat. No. 4,774,435); a method of increasing the efficiency by imparting light-condensing properties to the substrate (for example, JP 63-314795 A), a method of forming a reflective surface on the lateral surfaces or the like of the element (for example, JP 1-220394 A), a method of introducing a flat layer having an intermediate refractive index between a substrate and a light emitting body, and forming a reflection preventing film (for example, JP 62-172691 A), a method of introducing, between a substrate and a light emitting body, a flat layer having a refractive index lower than that of the substrate (for example, JP 2001-202827 A), and a method of forming diffraction lattices between any layers of a substrate, a transparent electrode layer, and a light emitting layer (including between a substrate and the outside) (JP 11-283751 A).

<<Method for Producing Organic EL Element>>

Next, an example of the method for producing an organic EL element composed of anode/hole transport layer/first light emitting layer/intermediate layer/second light emitting layer/electron transport layer/cathode will be described.

First, an anode is produced by forming a thin film formed from a desired electrode material, for example, a material for anode, on an appropriate substrate by a method such as vapor deposition or sputtering such that a film thickness of 1 μm or less, and preferably 10 to 200 nm, is obtained.

Next, a hole transport layer, a first light emitting layer, an intermediate layer, a second light emitting layer, and an electron transport layer, which are materials of an organic EL element, are formed on this anode.

Regarding the method for reducing the thickness of these organic compound thin films, a vapor deposition method, a wet process (a spin coating method, a casting method, an inkjet method, a printing method, a LB (Langmuir-Blodgett) method, a spraying method, a printing method, or a slot type coating method), and the like are available; however, from the viewpoint that a homogeneous film can be easily obtained, and pinholes are not easily produced, a vacuum deposition method, a spin coating method, an inkjet method, a printing method, and a slot type coating method are particularly preferred. It is acceptable to apply different film-forming methods to different layers.

In a case in which a vapor deposition method is employed for film forming, the conditions for vapor deposition may vary depending on the type of the compounds used or the like; however, generally, it is desirable to appropriately select the boat heating temperature to be in the range of 50° C. to 450° C., the degree of vacuum to be in the range of 1×10⁻⁶ to 1×10⁻² Pa, the rate of vapor deposition to be in the range of 0.01 to 50 nm/sec, the substrate temperature to be in the range of −50° C. to 300° C., and the layer thickness to be in the range of 0.1 nm to 5 μm, and preferably in the range of 5 to 200 nm.

Regarding the method for forming an intermediate layer, as described above, there are no particular limitations as long as a method enabling the formation of a thin film is used, and examples thereof include a vapor deposition method, a sputtering method, and a wet process (a spin coating method, a casting method, an inkjet method, a LB method, a spraying method, a printing method, or a slot type coating method).

After these layers are formed, a thin film formed from a material for cathode is formed thereon by, for example, a method such as vapor deposition or sputtering such that a film thickness of 1 μm or less, and preferably in the range of 50 to 200 nm, and thus a cathode is provided.

Thereby, a desired organic EL element is obtained.

In regard to the production of this organic EL element, it is preferable to produce from the hole transport layer to the cathode throughout by one time of vacuum drawing; however, it is also acceptable to take out the product in the middle of the process and apply other film-forming methods. At that time, it is necessary to take care by, for example, performing the operation in a dry inert gas atmosphere.

Thereafter, the organic EL element may be encapsulated or protected.

For example, the organic EL element is encapsulated by coating the organic EL element with a thermosetting resin in a state in which a portion or the entirety of the anode and the cathode is exposed, and heating and curing this thermosetting resin.

Subsequently, the encapsulated body of the organic EL element and the portion or entirety of the anode and the cathode of the organic EL element exposed therein are coated with a protective member, and the overlapping portion of the protective member is heated and pressed at a predetermined temperature. It is acceptable to process the resultant by stacking two sheets of the protective member, coating the encapsulated body of the organic EL element and the like, and heating and pressing the lateral edge parts of the protective members. It is also acceptable to process the resultant by folding one sheet of the protective member, coating the encapsulated body of the organic EL element and the like, and heating and pressing the lateral edge parts (particularly the open end) of the protective member.

As a result of the treatment described above, an organic EL module having the organic EL element encapsulated and protected is produced.

<<Other Configurations>>

In the embodiment described above, a bottom emission type organic EL element in which, from the substrate side, an anode serving as a transparent electrode, a hole transport layer, a first light emitting layer, an intermediate layer, a second light emitting layer, an electron transport layer, and a cathode serving as a reflective electrode are laminated in this order, has been described as an example; however, the invention is not limited to this configuration. For example, the order of lamination of the various layers may be reversed, or the organic EL element may also be configured to have the anode and the cathode on the opposite sides.

It is desirable that the organic EL element has at least two light emitting layers.

Therefore, as long as the conditions of the layer configuration described above are satisfied, the layer configuration and the number of laminations of the light emitting layers are not particularly limited, and a configuration capable of realizing a desired organic EL element can be adopted. Furthermore, the luminescent material in the light emitting layer may be of a single type, or a configuration in which multiple light emitting layers are directly laminated or laminated with organic layers interposed therebetween, may also be adopted.

A configuration appropriately combining these can also be adopted.

Furthermore, in the embodiment described above, the types of the luminescent dopants used for the organic EL element are described as three types such as blue, green and red; however, luminescent dopants having other luminescent colors can also be used. For example, luminescent dopants having luminescent colors that are complementary colors of blue, green and red, respectively, may also be used. Any luminescent dopant may be used in the light emitting layer.

Furthermore, in the embodiment described above, a case in which the luminescent color from the organic EL element is white luminescence is described; however, the luminescent color of the organic EL element is not limited to white color, and an arbitrary luminescent color resulting from a combination of luminescent colors of multiple light emitting layers can also be employed. Even in a case in which a luminescent color other than white color is employed, reduction of color variation caused by luminance differences, and color change from the initial luminescent color caused by the elapse of the driving time can be suppressed by adjusting the volume concentration of the luminescent dopant included in the second light emitting layer to be higher than the volume concentration of the luminescent dopant included in the first light emitting layer.

<<Illuminating Apparatus-1>>

Next, an illuminating apparatus will be described as an exemplary embodiment of an electronic device in which the organic EL element described above is used.

The organic EL element used for an illuminating apparatus may be designed to provide the organic EL element having the above-described configuration, with a resonator structure. Examples of the purpose of use of the organic EL element configured to have a resonator structure, include a light source for an optical storage medium, a light source for an electrophotographic copier, a light source for an optical communication processor, and a light source for an optical sensor; however, the examples are not limited to these. Furthermore, the organic EL element may also be used for the applications mentioned above, by subjecting the organic EL element to laser oscillation.

Meanwhile, the materials used for the organic EL element can be applied to an organic EL element which substantially causes white luminescence (also referred to as white organic EL element). For example, white luminescence may also be obtained as a result of a mixed color, by simultaneously emitting multiple luminescent colors using multiple luminescent materials. Regarding the combination of multiple luminescent colors, three maximum emission wavelengths of three primary colors, namely, red, green and blue, may be incorporated, or two maximum emission wavelengths utilizing the relationship of complementary colors, such as blue and yellow, or blue-green and orange, may also be incorporated.

The combination of the luminescent materials for obtaining multiple luminescent colors may be a combination of materials that emit multiple phosphorescent light or fluorescent light, or a combination of a luminescent material that emits fluorescent light or phosphorescent light and a coloring material that emits the light from the luminescent material as excitation light. In regard to the white organic EL element, multiple luminescent dopants may be combined and mixed.

Regarding such a white organic EL element, unlike the configuration of individually disposing in parallel organic EL elements of various luminescent colors in an array and thereby obtaining white luminescence, the organic EL element itself emits white color. Therefore, masking is not needed for the formation of the most layers constituting the element, and for example, an electroconductive layer can be formed on one surface by a vapor deposition method, a casting method, a spin coating method, an inkjet method, a printing method or the like. Thus, productivity is also increased.

Furthermore, the luminescent material used for the light emitting layer of such a white organic EL element is not particularly limited, and for example, in the case of a backlight in a liquid crystal display element, arbitrary materials may be selected and combined from the metal complexes described above and known luminescent materials so as to be suitable for the wavelength range corresponding to the CF (color filter) characteristics, and thus the luminescent color may be made white.

When the white organic EL element described above is used, an illuminating apparatus which produces substantially white luminescence can be produced.

<<Illuminating Apparatus-2>>

Furthermore, in the illuminating apparatus, for example, the area of the light emitting surface can be enlarged by using multiple organic EL elements. In this case, the area of the light emitting surface is enlarged by arranging (that is, tiling) multiple light emitting panels in which organic EL elements are provided on a substrate, on a supporting substrate. The supporting substrate may be a substrate which combines an encapsulating material, and each of the light emitting panels is tiled in a state in which organic EL elements are interposed between this supporting substrate and the substrate of the light emitting panel. The gap between the supporting substrate and the substrate is filled with an adhesive, and thereby the organic EL elements may be encapsulated. On the periphery of the light emitting panels, terminals of the anode and the cathode are exposed.

In the illuminating apparatus having such a configuration, the center of each light emitting panel becomes a light emitting region, and non-light emitting regions are generated between the light emitting panels. Therefore, a light extracting member for increasing the amount of light extraction from a non-light emitting region may be provided in the non-light emitting region of the light extraction surface. As the light extracting member, a light condensing sheet or a light diffusion sheet can be used.

### EXAMPLES

Hereinafter, the present invention will be specifically described by way of Examples; however, the present invention is not intended to be limited to these. In the Examples, the expression of “percent (%)” is used; however, this represents “mass %” unless particularly stated otherwise.

### Example 1

<<Production of Organic EL Element>>

Various samples of the organic EL element were produced such that the light emitting region area would be 5 cm×5 cm.

(1) Production of Organic EL Element 101

(1.1) Anode

A glass substrate having a thickness of 0.7 mm was prepared as a transparent supporting substrate. On this transparent supporting substrate, an ITO (indium tin oxide) film was formed to a thickness of 110 nm, and patterning was performed. Thus, an anode formed from an ITO transparent electrode was formed. Subsequently, the transparent supporting substrate having the ITO transparent electrode attached thereon was subjected to ultrasonic cleaning with isopropyl alcohol and dried with dry nitrogen gas, and UV ozone cleaning was performed for 5 minutes.

(1.2) Hole Injection/Transport Layer

Next, the transparent supporting substrate having the anode formed thereon was fixed to a substrate holder of a commercially available vacuum deposition apparatus. Then, the materials of the various layers that constitute an organic EL element were charged in optimal amounts for element production, into various crucibles for vapor deposition in the vacuum deposition apparatus. As the various crucibles for vapor deposition, crucibles for vapor deposition produced from materials for resistance heating made of molybdenum or tungsten were used.

(1.2.1) Hole Injection Layer

Pressure was reduced to a degree of vacuum of 1×10⁻⁴ Pa, and a crucible for vapor deposition containing exemplary compound HI-145 (HAT-CN) was heated by passing electricity. Vapor deposition was performed on the anode at a deposition rate of 0.1 nm/second, and thus a hole injection layer having a layer thickness of 20 nm was formed.

(1.2.2) Hole Transport Layer

Next, compound 1-A represented by the following structural formula (glass transition point (Tg)=140° C.) was vapor-deposited to obtain a layer thickness of 59 nm, and thus a hole transport layer was formed.

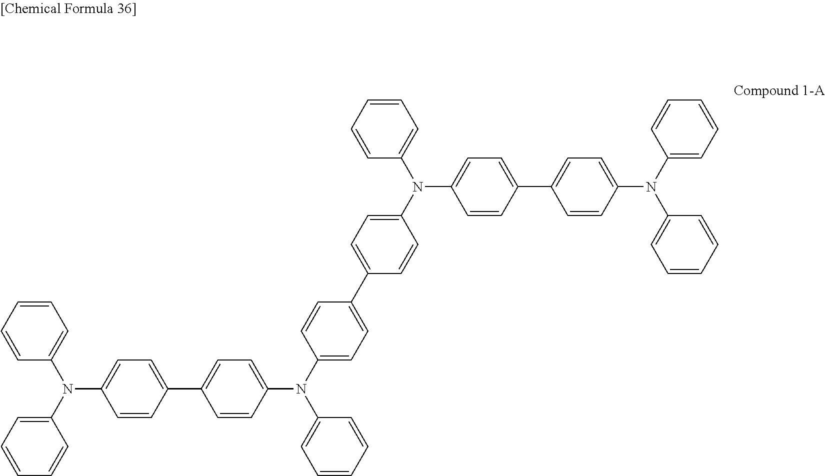 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1]

(1.2.3) Electron Blocking Layer

Next, compound 1-B represented by the following structural formula was vapor-deposited to obtain a layer thickness of 10 nm, and thus an electron blocking layer was formed.

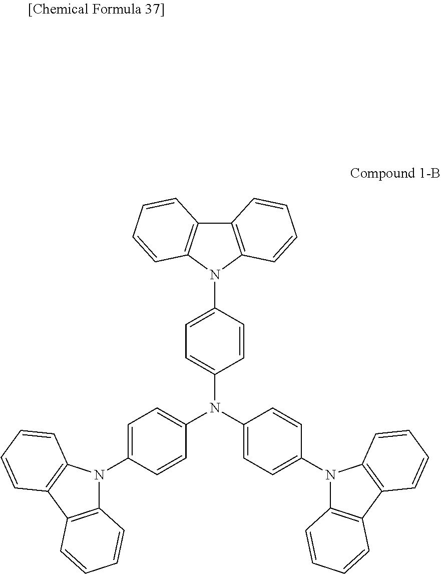 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

Through the above-described processes, a hole injection/transport layer was formed in which exemplary compound HI-145, compound 1-A, and compound 1-B were laminated from the anode side. Compound 1-B is a material having a lower LUMO (Lowest Unoccupied Molecular Orbital) and higher minimum excitation triplet energy (T₁) than compound 2-A and compound 2-B, which constitute a first light emitting layer that will be described below.

That is, in regard to the LUMO, the following relations are established: LUMO (1-B)>LUMO (2-A), and LUMO (1-B)>LUMO (2-B). Furthermore, in regard to T₁, the following relations are established: T₁ (1-B)>T₁ (2-A), and T₁ (1-B)>T₁ (2-B).

By using the compound 1-B that satisfied these relations for the layer that was in contact with the first light emitting layer, a configuration in which an electron and triplet energy blocking layer was formed on the hole injection/transport layer was adopted.

(1.3) First Light Emitting Layer

Next, vapor deposition was performed such that the proportion of compound 2-A represented by the following structural formula (Tg=189° C.) as a host compound was 98.0 vol %, and the proportion of compound 2-B represented by the following structural formula as a blue fluorescent light emitting dopant was 2.0 vol %. Thereby, a fluorescent light emitting layer having a layer thickness of 15 nm and exhibiting blue color was formed as a first light emitting layer.

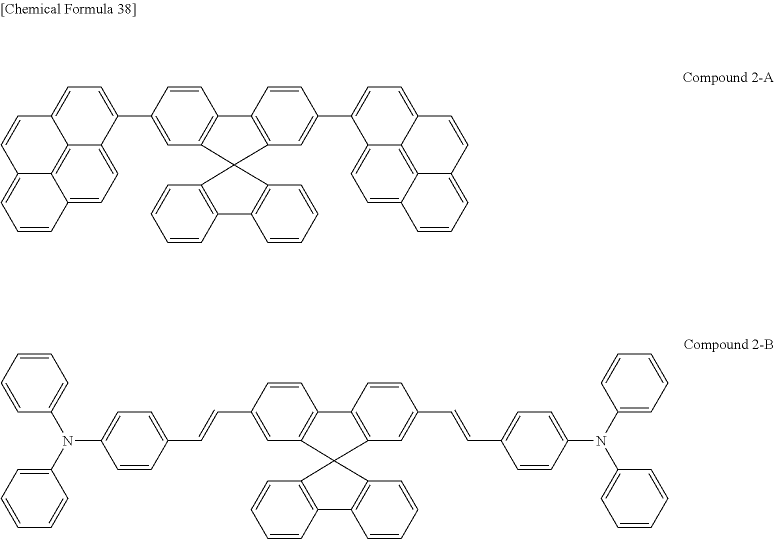

(1.4) Intermediate Layer

Next, compound 2-A was vapor-deposited to a layer thickness of 5 nm as an intermediate layer, and thus an intermediate layer was formed.

(1.5) Second Light Emitting Layer

Subsequently, vapor deposition was performed such that the proportion of compound 3-A represented by the following structural formula (Tg=143° C.) as a host compound was 85.0 vol %, and the proportion of compound 3-B represented by the following structural formula as a yellow phosphorescent light emitting dopant was 15.0 vol %. Thus, a phosphorescent light emitting layer exhibiting yellow color and having a layer thickness of 10 nm was formed.

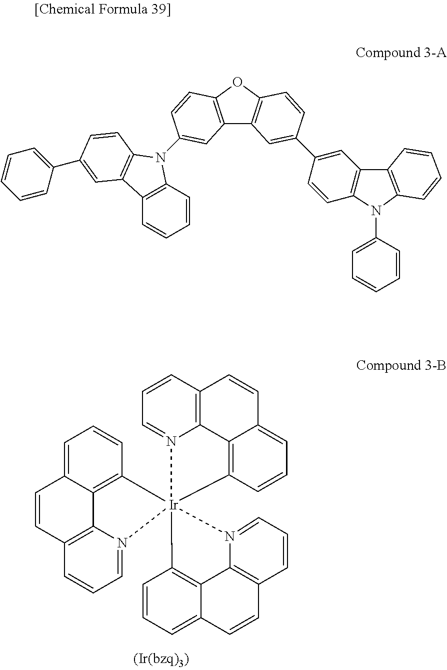

(1.6) Electron Injection/Transport Layer

Next, vapor deposition was performed such that the proportion of compound 4 represented by the following structural formula was 86.0 vol %, and the proportion of LiF was 14.0 vol %, and thus a layer having a layer thickness of 20 nm was formed. Furthermore, vapor deposition was performed such that the proportion of compound 4 was 98.0 vol %, and the proportion of Li was 2.0 vol %, and thus a layer having a layer thickness of 10 nm was formed. Thereby, an electron injection/transport layer configured to include a layer formed from compound 4 and LiF and a layer formed from compound 4 and Li was formed.

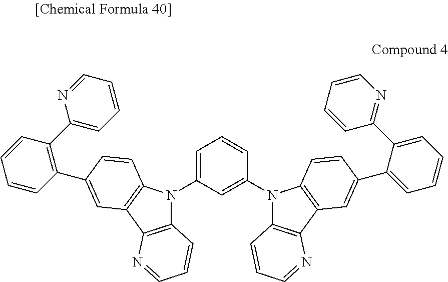 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

(1.7) Cathode and Encapsulation

Next, aluminum was vapor-deposited to a thickness of 150 nm, and thus a cathode was formed.

Next, the non-light emitting surface of the organic EL element formed up to the cathode was covered with a glass case, and a sealing material based on an epoxy-based photocurable type adhesive (LUXTRACK LC0629B manufactured by Toagosei Co., Ltd.) was provided on the periphery of the glass case covering the organic EL element, the glass case being in contact with the glass substrate on which the organic EL element had been produced. Then, this sealing material was stacked on the cathode side of the organic EL element and was closely adhered to the glass substrate. Subsequently, the assembly was irradiated with UV light through the glass case side to cure the sealing material, and thus the organic EL element was encapsulated. Thus, an organic EL element 101 was produced.

Meanwhile, the operation of encapsulating with the glass case was carried out in a glove box in a nitrogen atmosphere (in an atmosphere of high purity nitrogen gas having a purity of 99.999% or higher), without bringing the organic EL element into contact with air.

(2) Production of Organic EL Element 102

Organic EL element 102 was produced in the same manner as in the production of organic EL element 101, except that the volume concentration of the blue fluorescent light emitting dopant included in the first light emitting layer was changed to 5.0 vol %.

(3) Production of Organic EL Element 103

Organic EL element 103 was produced in the same manner as in the production of organic EL element 101, except that the volume concentration of the blue fluorescent light emitting dopant included in the first light emitting layer was changed to 10.0 vol %, and the volume concentration of the yellow phosphorescent light emitting dopant included in the second light emitting layer was changed to 10.0 vol %.

(4) Production of Organic EL Element 104

Organic EL element 104 was produced in the same manner as in the production of organic EL element 101, except that the volume concentration of the blue fluorescent light emitting dopant included in the first light emitting layer was changed to 15.0 vol %, and the volume concentration of the yellow phosphorescent light emitting dopant included in the second light emitting layer was changed to 7.0 vol %.

(5) Production of Organic EL Elements 105 to 107

Organic EL elements 105 to 107 were produced in the same manner as in the production of organic EL element 101, except that the volume concentration of the yellow phosphorescent light emitting dopant included in the second light emitting layer was changed to 17.0 vol %, 22.5 vol %, and 28.0 vol %, respectively.

(6) Production of Organic EL Elements 108 to 112

Organic EL elements 108 to 112 were produced in the same manner as in the production of organic EL element 106, except that the layer thickness of the intermediate layer was changed to 0 (no intermediate layer), 1 nm, 3 nm, 7 nm, and 10 nm, respectively.

<<Evaluation of Organic EL Elements>>

For the various organic EL elements obtained as described above, evaluation of the element characteristics was carried out as follows.

The evaluation results are presented in Table 1.

(1) Chromaticity Difference

Regarding the measurement of chromaticity of each sample, reference can be made to, for example, Noboru Ota, “Color Engineering, 2^{nd} Edition” (Tokyo Denki University Press).

Specifically, the light emission spectrum of each sample obtained when light was turned on under the conditions of a constant current density of 50 mA/cm² at room temperature (25° C.), was measured using a spectroradiometer, CS-2000 (manufactured by Konica Minolta, Inc.). Then, the spectrum obtained by this measurement was converted to the chromaticity coordinates x and y using tristimulus values X, Y and Z at the reference stimuli [X], [Y] and [Z] defined in the CIE 1931 Color System.

Similarly, the emission luminance of each sample obtained when light was turned on under the conditions of a constant current density of 50 mA/cm² at room temperature, was measured using a spectroradiometer, CS-2000 (manufactured by Konica Minolta, Inc.). Furthermore, continuous driving was implemented under the same conditions, and the time taken until the luminance decreased by 30% was determined as LT70.

The chromaticity difference ΔE_{xy} (change in luminance) concomitant to the change in luminance was calculated by the following expression, from the chromaticity coordinates at 300 cd/m², x₃₀₀ and y₃₀₀, and the chromaticity coordinates at 1500 cd/m², x₁₅₀₀ and y₁₅₀₀.

ΔE_{xy}(change in luminance)=[(x₃₀₀−x₁₅₀₀)²+(y₃₀₀−y₁₅₀₀)²]^{1/2}

The chromaticity difference ΔE_{xy} (change over time) concomitant to changes over time was calculated by the following expression, from the initial (LT100) chromaticity coordinates, x_{LT100} and y_{LT100}, and the chromaticity coordinates at the time of 30% reduction of luminance (LT70), LT70 and y_{LT70}.

ΔE_{xy}(change over time)=[(x_{LT100}−x_{LT70})²+(y_{LT100}−y_{LT70})²]^{1/2}

(2) Measurement of Driving Voltage

For each of the organic EL elements thus obtained, the emission luminance of each sample was measured at room temperature (25° C.) using a spectroradiometer, CS-2000 (manufactured by Konica Minolta, Inc.), and the initial driving voltage (V) at an emission luminance of 1,000 cd/m² was determined.

TABLE 1

| | Dope concentration | Layer | Dope concentration | | | | |
|---|---|---|---|---|---|---|---|
| Organic | of first light | thickness of | of second light | Chromaticity change | | | |
| EL | emitting layer | intermediate | emitting layer | ΔE_{xy} | ΔE_{xy} | Driving | |
| element | (fluorescence) | layer | (phosphorescence) | (change in | (change | voltage | |
| No. | (vol %) | (nm) | (vol %) | luminance) | over time) | (V) | Remarks |
| 101 | 2.0 | 5 | 15.0 | 0.08 | 0.02 | 3.2 | Invented |
| | | | | | | | Example |
| 102 | 5.0 | 5 | 15.0 | 0.09 | 0.04 | 3.2 | Invented |
| | | | | | | | Example |
| 103 | 10.0 | 5 | 10.0 | 0.15 | 0.12 | 3.2 | Comparative |
| | | | | | | | Example |
| 104 | 15.0 | 5 | 7.0 | 0.25 | 0.24 | 3.4 | Comparative |
| | | | | | | | Example |
| 105 | 2.0 | 5 | 17.0 | 0.02 | 0.02 | 3.2 | Invented |
| | | | | | | | Example |
| 106 | 2.0 | 5 | 22.5 | 0.01 | 0.01 | 3.2 | Invented |
| | | | | | | | Example |
| 107 | 2.0 | 5 | 28.0 | 0.01 | 0.02 | 3.2 | Invented |
| | | | | | | | Example |
| 108 | 2.0 | 0 | 22.5 | 0.02 | 0.06 | 3.1 | Invented |
| | | | | | | | Example |
| 109 | 2.0 | 1 | 22.5 | 0.01 | 0.02 | 3.1 | Invented |
| | | | | | | | Example |
| 110 | 2.0 | 3 | 22.5 | 0.01 | 0.01 | 3.2 | Invented |
| | | | | | | | Example |
| 111 | 2.0 | 7 | 22.5 | 0.04 | 0.02 | 3.3 | Invented |
| | | | | | | | Example |
| 112 | 2.0 | 10 | 22.5 | 0.06 | 0.05 | 3.4 | Invented |
| | | | | | | | Example |

(3) Conclusions

As is obvious from Table 1, it was confirmed that when the dope concentration of the first light emitting layer (fluorescence) was lower than the dope concentration of the second light emitting layer (phosphorescence), the chromaticity change was reduced. Above all, it was found that when the dope concentration difference was 10.0 vol % or more, and more suitably 15.0 vol % or more, chromaticity change could be suppressed to the utmost. Furthermore, the driving voltage could be controlled to be 4.0 V or lower.

Furthermore, it was found that when the layer thickness of the intermediate layer was 0 (no intermediate layer) to 7 nm, chromaticity change was reduced.

From the above results, according to the most suitable configuration, the dope concentration of the second light emitting layer is higher by 15.0 vol % or more than the dope concentration of the first light emitting layer, and the layer thickness of the intermediate layer is in the range of 0 to 7 nm. In this case, the position of light emission of the element itself is stabilized (that is, ΔE_{xy} (change in luminance) is small), and the difference in the position of light emission caused by deterioration over time is also reduced (that is, ΔE_{xy} (change over time) is small).

### Example 2

<<Production of Organic EL Element>>

(1) Production of Organic EL Element 201

Organic EL element 201 was produced in the same manner as in the production of organic EL element 106 in Example 1, except that the second light emitting layer was formed as follows.

(Second Light Emitting Layer)

Vapor deposition was performed such that the proportion of compound 2-A (Tg=189° C.) as a host compound was 77.5 vol %, and the proportion of compound 5 represented by the following structural formula as a yellow fluorescent light emitting dopant was 22.5 vol %. Thus, a fluorescent light emitting layer exhibiting yellow color and having a layer thickness of 10 nm was formed.

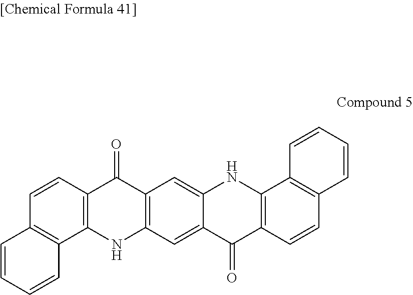 [SMILES: O=c1c2cc3[nH]c4c(ccc5ccccc54)c(=O)c3cc2[nH]c2c1ccc1ccccc12]

(2) Production of Organic EL Element 202

Organic EL element 202 was produced in the same manner as in the production of organic EL element 201, except that the intermediate layer was not formed.

<<Evaluation of Organic EL Elements>>

For the various organic EL elements thus obtained, evaluation of the element characteristics was implemented in the same manner as in Example 1.

The evaluation results are presented in Table 2.

TABLE 2

| | Dope | | Dope | | | | |
|---|---|---|---|---|---|---|---|
| | concentration | Layer | concentration of | | | | |
| | of first light | thickness of | second light | Chromaticity change | | | |
| Organic EL | emitting layer | intermediate | emitting layer | ΔE_{xy} | ΔE_{xy} | Driving | |
| element | (fluorescence) | layer | (phosphorescence) | (change in | (change | voltage | |
| No. | (vol %) | (nm) | (vol %) | luminance) | over time) | (V) | Remarks |
| 201 | 2.0 | 5 | 22.5 | 0.02 | 0.02 | 3.5 | Invented |
| | | | | | | | Example |
| 202 | 2.0 | 0 | 22.5 | 0.03 | 0.02 | 3.4 | Invented |
| | | | | | | | Example |

As is obvious from Table 2, it was confirmed that even in a case in which the first light emitting layer and the second light emitting layer were together produced as fluorescent light emitting layers, the chromaticity change was reduced.

Meanwhile, it is still acceptable even if the sequence of blue color of the first light emitting layer and yellow color of the second light emitting layer is reversed; however, it is important for stabilization of the position of light emission that the dope concentration of the second light emitting layer is higher than the dope concentration of the first light emitting layer.

### Example 3

<<Production of Organic EL Element>>

(1) Production of Organic EL Element 301

Organic EL element 301 was produced in the same manner as in the production of organic EL element 106 in Example 1, except that the first light emitting layer was formed as follows.

(First Light Emitting Layer)

Vapor deposition was performed such that the proportion of compound 6-A represented by the following structural formula (CBP) as a host compound was 77.5 vol %, and the proportion of compound 6-B represented by the following structural formula as a blue phosphorescent light emitting dopant (FIrpic) was 22.5 vol %. Thus, a phosphorescent light emitting layer exhibiting blue color and having a layer thickness of 10 nm was formed.

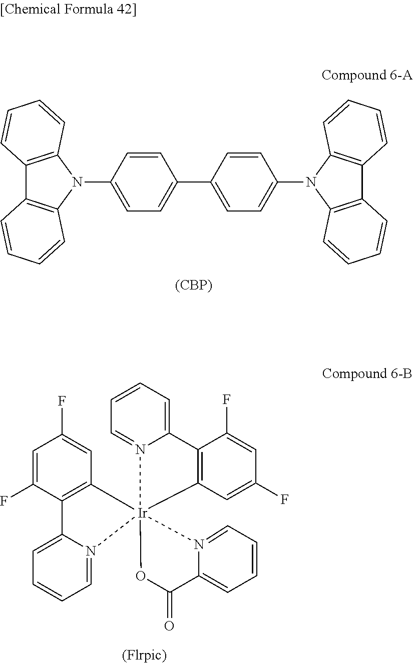

(2) Production of Organic EL Element 302

Organic EL element 302 was produced in the same manner as in the production of organic EL element 301, except that an intermediate layer was not formed.

<<Evaluation of Organic EL Element>>

For each of the organic EL elements thus obtained, evaluation of the element characteristics was implemented in the same manner as in Example 1.

The evaluation results are presented in Table 3.

TABLE 3

| | Dope | | Dope | | | | |
|---|---|---|---|---|---|---|---|
| | concentration | Layer | concentration of | | | | |
| | of first light | thickness of | second light | Chromaticity change | | | |
| Organic EL | emitting layer | intermediate | emitting layer | ΔE_{xy} | ΔE_{xy} | Driving | |
| element | (fluorescence) | layer | (phosphorescence) | (change in | (change | voltage | |
| No. | (vol %) | (nm) | (vol %) | luminance) | over time) | (V) | Remarks |
| 301 | 2.0 | 5 | 22.5 | 0.03 | 0.03 | 3.0 | Invented |
| | | | | | | | Example |
| 302 | 2.0 | 0 | 22.5 | 0.04 | 0.03 | 2.9 | Invented |
| | | | | | | | Example |

As is obvious from Table 3, it was confirmed that even in a case in which the first light emitting layer and the second light emitting layer were together produced as phosphorescent light emitting layers, the chromaticity change was reduced.

Meanwhile, it is still acceptable even if the sequence of blue color of the first light emitting layer and yellow color of the second light emitting layer is reversed; however, it is important for stabilization of the position of light emission that the dope concentration of the second light emitting layer is higher than the dope concentration of the first light emitting layer.

### Example 4

<<Production of Organic EL Elements>>

Organic EL elements 401 to 420 were produced in the same manner as in the production of organic EL element 102 in Example 1, except that the layer thicknesses of the hole injection layer and the hole transport layer were changed as indicated in Table 4.

<<Evaluation of Organic EL Elements>>

For each of the organic EL elements obtained as described above, evaluation of the element characteristics was implemented as follows.

The evaluation results are presented in Table 4.

(1) Change in Voltage

For each of the organic EL elements thus produced, the front luminance was measured using a spectroradiometer, CS-1000 (manufactured by Konica Minolta, Inc.), and the driving voltage at a front luminance of 1,000 cd/m² was determined. More specifically, the organic EL element itself was introduced into a constant-temperature layer, and 10 minutes after the monitor temperature of the constant-temperature layer reached −30° C. or 60° C., the driving voltage was measured. Thus, the voltage difference ΔV (V) was calculated.

ΔV=V(−30° C.)−V(60° C.)

(2) Measurement of Chromaticity Difference Concomitant to Temperature Change

For the measurement of chromaticity of each sample, reference can be made to, for example, Noboru Ota, “Color Engineering, 2^{nd} Edition” (Tokyo Denki University Press).

Specifically, the light emission spectrum of each sample obtained when light was turned on under the conditions of a constant current density of 2.5 mA/cm² at a predetermined temperature (−30° C. and 60° C.), was measured using a spectroradiometer, CS-2000 (manufactured by Konica Minolta, Inc.). Then, the spectrum obtained by this measurement was converted to the chromaticity coordinates x and y using tristimulus values X, Y and Z at the reference stimuli [X], [Y] and [Z] defined in the CIE 1931 Color System.

Regarding the chromaticity difference ΔE_{xy} concomitant to the change in temperature, the chromaticity difference ΔE_{xy} was calculated by the following expression, from the chromaticity coordinates x and y at 1,000 cd/m².

ΔE_{xy}=[(x_{-30° C.}−x_{60° C.})²+(y_{-30° C.}−y_{60° C.})²]^{1/2}

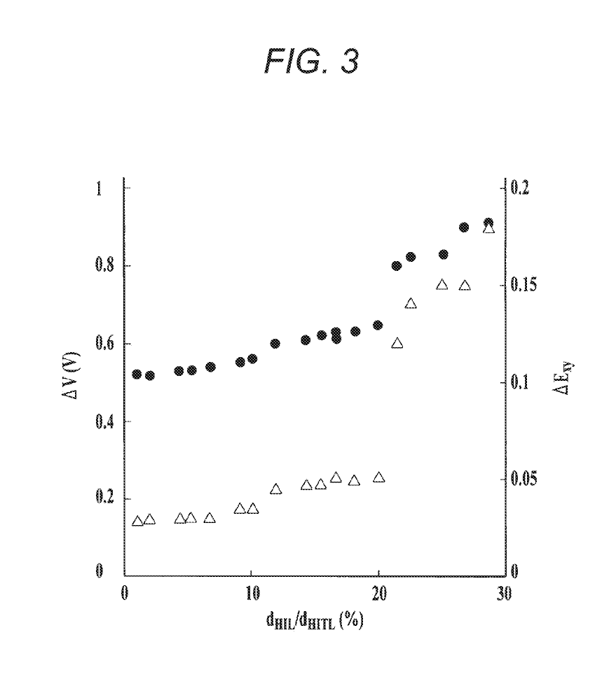

Furthermore, a graph illustrating the correlation between d_{HIL}/d_{HITL} and the change in voltage as well as the change in chromaticity is shown in FIG. 3. In FIG. 3, the symbol represents the correlation between d_{HIL}/d_{HITL} and the change in voltage ΔV, and the symbol Δ represents the correlation between d_{HIL}/d_{HITL} and the change in chromaticity ΔE_{xy}.

(3) Measurement of Driving Voltage

For each of the organic EL elements thus obtained, the initial driving voltage (V) was measured in the same manner as in Example 1.

TABLE 4

| | Hole injection/transport layer | | | | | | | | |
|---|---|---|---|---|---|---|---|---|---|
| | Layer | Layer | Layer | | | | | | |
| | thickness of | thickness of | thickness of | Layer thickness of | | | | | |
| Organic | hole | hole | electron | hole | | | | | |
| EL | injection | transport | blocking | injection/transport | | | ΔE_{xy} | Driving | |
| element | layer | layer | layer | layer | | ΔV | (change in | voltage | |
| No. | (d_{HIL} (nm)) | (nm) | (nm) | (d_{HITL} (nm)) | d_{HIL}/d_{HITL} | (V) | temperature) | (V) | Remarks |
| 401 | 5 | 40 | 10 | 55 | 0.09 | 0.60 | 0.045 | 3.2 | Invented Example |
| 402 | 5 | 59 | 10 | 74 | 0.07 | 0.54 | 0.030 | 3.2 | Invented Example |
| 403 | 5 | 80 | 10 | 95 | 0.05 | 0.58 | 0.030 | 3.3 | Invented Example |
| 404 | 10 | 40 | 10 | 60 | 0.17 | 0.62 | 0.060 | 3.2 | Invented Example |
| 405 | 10 | 64 | 10 | 84 | 0.12 | 0.60 | 0.050 | 3.2 | Invented Example |
| 406 | 10 | 80 | 10 | 100 | 0.10 | 0.62 | 0.050 | 3.3 | Invented Example |
| 407 | 15 | 65 | 10 | 90 | 0.17 | 0.63 | 0.070 | 3.2 | Invented Example |
| 408 | 15 | 50 | 10 | 75 | 0.20 | 0.65 | 0.080 | 3.2 | Invented Example |
| 409 | 15 | 80 | 10 | 105 | 0.14 | 0.61 | 0.050 | 3.3 | Invented Example |
| 410 | 20 | 40 | 10 | 70 | 0.29 | 0.91 | 0.180 | 3.2 | Invented Example |
| 102 | 20 | 59 | 10 | 89 | 0.22 | 0.82 | 0.140 | 3.2 | Invented Example |
| 411 | 20 | 80 | 10 | 110 | 0.18 | 0.63 | 0.070 | 3.3 | Invented Example |
| 412 | 20 | 100 | 10 | 130 | 0.15 | 0.62 | 0.055 | 3.3 | Invented Example |
| 413 | 30 | 100 | 10 | 140 | 0.21 | 1.23 | 0.250 | 3.4 | Invented Example |
| 414 | 30 | 59 | 10 | 99 | 0.30 | 0.95 | 0.180 | 3.3 | Invented Example |
| 415 | 30 | 80 | 10 | 120 | 0.25 | 0.83 | 0.150 | 3.2 | Invented Example |
| 416 | 30 | 100 | 10 | 140 | 0.21 | 0.80 | 0.120 | 3.3 | Invented Example |
| 417 | 5 | 100 | 10 | 115 | 0.04 | 0.53 | 0.030 | 3.3 | Invented Example |
| 418 | 2 | 90 | 10 | 102 | 0.02 | 0.52 | 0.029 | 3.3 | Invented Example |
| 419 | 1 | 90 | 10 | 101 | 0.01 | 0.52 | 0.028 | 3.3 | Invented Example |
| 420 | 40 | 100 | 10 | 150 | 0.27 | 0.90 | 0.150 | 3.4 | Invented Example |

(4) Conclusions

As is obvious from Table 4 and FIG. 3, it is understood that in a case in which the relation: d_{HIL}/d_{HITL}≦0.20 (20%) is satisfied, and in a case in which the relation: d_{HIL}/d_{HITL}≦0.10 (10%) is satisfied, the voltage variation and color variation caused by changes in the environmental temperature are reduced.

Furthermore, it is understood that in a case in which the layer thickness of the hole injection layer is in the range of 1 to 15 nm, and more particularly in the range of 1 to 10 nm, the voltage variation and color variation caused by changes in the environmental temperature are reduced.

### INDUSTRIAL APPLICABILITY

The present invention can be particularly suitably utilized in providing an organic EL element having less color variation.

### REFERENCE SIGNS LIST

1 ORGANIC EL ELEMENT
2 SUBSTRATE
4 ANODE
6 HOLE INJECTION/TRANSPORT LAYER
6a HOLE INJECTION LAYER
6b OTHER LAYER
8 FIRST LIGHT EMITTING LAYER
10 SECOND LIGHT EMITTING LAYER
12 ELECTRON INJECTION/TRANSPORT LAYER
14 CATHODE
16 INTERMEDIATE LAYER

1. An organic electroluminescent element comprising, between a pair of an anode and a cathode, a first light emitting layer composed of at least one layer and a second light emitting layer composed of at least one layer, the light emitting layers being laminated in this order from the anode side,
wherein the volume concentration of the luminescent dopant included in the second light emitting layer is higher than the volume concentration of the luminescent dopant included in the first light emitting layer.

2. The organic electroluminescent element according to claim 1, wherein the volume concentration of the luminescent dopant included in the second light emitting layer is 10.0 vol % or higher.

3. The organic electroluminescent element according to claim 1, wherein the volume concentration of the luminescent dopant included in the first light emitting layer is 3.0 vol % or less.

4. The organic electroluminescent element according to claim 1, wherein the light emitted by the second light emitting layer is phosphorescent light.

5. The organic electroluminescent element according to claim 1, wherein an intermediate layer is formed between the first light emitting layer and the second light emitting layer.

6. The organic electroluminescent element according to claim 5, wherein the layer thickness of the intermediate layer is in the range of 1 to 7 nm.

7. The organic electroluminescent element according to claim 5, wherein the intermediate layer is formed from a single kind of compound.

8. The organic electroluminescent element according to claim 7, wherein a host compound is included in at least one of the first light emitting layer and the second light emitting layer, and the host compound and the single kind of compound in the intermediate layer are the same.

9. The organic electroluminescent element according to claim 1, wherein the organic electroluminescent element comprises, between the anode and the first light emitting layer, a hole injection/transport layer including at least a hole injection layer in the interior, and the layer thickness of the hole injection/transport layer (d_{HITL}) and the layer thickness of the hole injection layer (d_{HIL}) satisfy the following conditional expression:
d_{HIL}/d_{HITL}≦0.20

10. The organic electroluminescent element according to claim 9, wherein the layer thickness of the hole injection/transport layer (d_{HITL}) and the layer thickness of the hole injection layer (d_{HIL}) satisfy the following conditional expression:
d_{HIL}/d_{HITL}≦0.10

11. The organic electroluminescent element according to claim 9, wherein the layer thickness of the hole injection layer is in the range of 1 to 15 nm.

12. The organic electroluminescent element according to claim 11, wherein the layer thickness of the hole injection layer is in the range of 1 to 10 nm.

13. The organic electroluminescent element according to claim 9, wherein the hole injection layer is formed from a single kind of compound.

14. The organic electroluminescent element according to claim 9, wherein the hole injection layer contains a compound having a structure represented by the following General Formula (1): 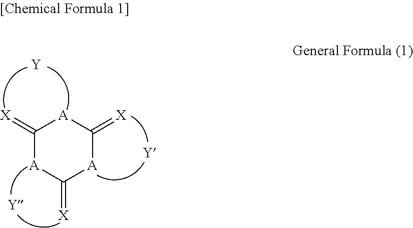
in General Formula (1), A represents a carbon atom (C) or a nitrogen atom (N); X represents a nitrogen atom (N) or a carbon atom (CR⁰); R⁰ represents any one group selected from a hydrogen atom, a halogen atom, a cyano group, a nitro group, a formyl group, an acetyl group, a benzoyl group, an amide group (—CONHR¹ or —CONR¹R²), a styryl group, an ethynyl group, a quinolyl group, a quinazolyl group, a phenanthrolyl group, a biquinolyl group, an anthraquinonyl group, a benzoquinonyl group, a quinonyl group, an acridinyl group, and a group, being substituted or unsubstituted, selected from an alkyl group, an aryl group, an aralkyl group, an alkylamino group, an arylamino group, an aralkylamino group and a heterocyclic group; R¹ and R² each independently represent an alkyl group having 1 to 60 carbon atoms, an aryl group, or a 5-membered to 7-membered heterocyclic group, all of these groups being substituted or unsubstituted; Y, Y′ and Y″ each represent a 5-membered aromatic heterocyclic ring containing A and X as ring members, or a 6-membered aromatic heterocyclic ring containing A and X as ring members, all of these heterocyclic rings being substituted or unsubstituted; and Y, Y′ and Y″ may be identical or different from each other.

15. The organic electroluminescent element according to claim 14, wherein the compound having a structure represented by General Formula (1) is a compound having a structure represented by the following General Formula (2): 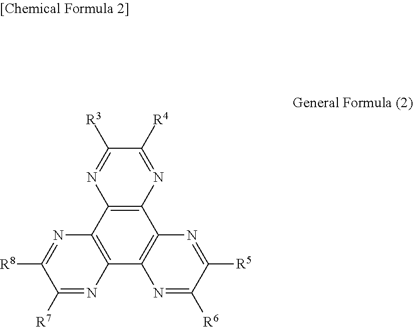
in General Formula (2), R³ to R⁸ each independently represent a hydrogen atom, a halogen atom, a cyano group, a nitro group, a sulfonyl group (—SO₂R⁹), a sulfinyl group (—SOR⁹), a sulfonamide group (—SO₂NR⁹R¹⁰), a sulfonato group (—SO₃R⁹), a trifluoromethyl group, an ester group (—COOR⁹), an amide group (—CONHR⁹ or —CONR⁹R¹⁰), and a group, being substituted or unsubstituted, selected from a linear or branched alkyl group having 1 to 12 carbon atoms, a linear or branched alkoxy group having 1 to 12 carbon atoms, an aromatic hydrocarbon ring group, an arylamino group, a non-aromatic heterocyclic group, an aromatic heterocyclic group, and an aralkylamino group; and R⁹ and R¹⁰ each independently represent an alkyl group having 1 to 60 carbon atoms, an aryl group, or a 5-membered to 7-membered heterocyclic group, all of these groups being substituted or unsubstituted.

16. The organic electroluminescent element according to claim 14, wherein the compound having a structure represented by General Formula (1) is a compound having a structure represented by the following General Formula (3): 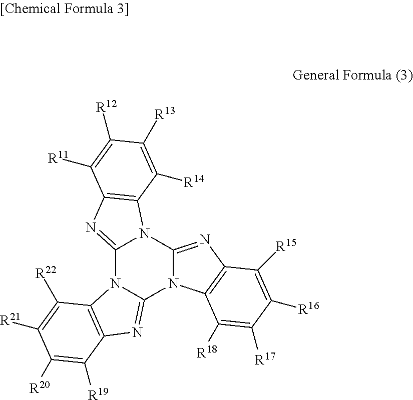
in General Formula (3), R¹¹ to R²² each independently represent any one group selected from a halogen atom, an amino group, a cyano group, a nitro group, an alkoxy group, an aryloxy group, an alkylthio group, an arylthio group, an acyl group, an alkoxycarbonyl group, an aryloxycarbonyl group, an alkylsulfonyl group, an arylsulfonyl group, and a group, being substituted or unsubstituted, selected from an aliphatic hydrocarbon group, an aromatic hydrocarbon ring group, an aliphatic heterocyclic group and an aromatic heterocyclic group; and R¹¹ to R²² may respectively form a ring together with adjacent substituents.

17. The organic electroluminescent element according to claim 9, wherein the hole injection layer contains a compound having a structure represented by the following General Formula (4): 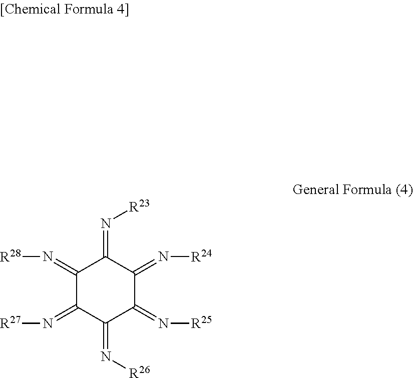
in General Formula (4), R²³ to R²⁸ each independently represent an alkyl group, an aryl group, an aralkyl group, or a heterocyclic group, all of these groups being substituted or unsubstituted; R²³ to R²⁸ may be identical or different; and R²³ with R²⁴, R²⁵ with R²⁶, and R²⁷ with R²⁸, or R²³ with R²⁸, R²⁴ with R²⁵, and R²⁶ with R²⁷ may form a fused ring.

18. The organic electroluminescent element according to claim 1, wherein the driving voltage is 4.0 V or less under the conditions of a temperature of 25° C. and an emission luminance of 1,000 cd/m².

19. The organic electroluminescent element according to claim 2, wherein the volume concentration of the luminescent dopant included in the first light emitting layer is 3.0 vol % or less.

20. The organic electroluminescent element according to claim 2, wherein the light emitted by the second light emitting layer is phosphorescent light.
